(19) United States
(12) Patent Application Publication
(10) Pub. No.: US 2024/0321853 A1
(43) Pub. Date: Sep. 26, 2024

(54) PACKAGING METHOD AND PACKAGING STRUCTURE OF MULTI-LAYER STACKED HIGH-BANDWIDTH MEMORY

(71) Applicant: TONGFU MICROELECTRONICS CO., LTD., Nantong (CN)

(72) Inventor: Maohua DU, Nantong (CN)

(21) Appl. No.: 18/680,321

(22) Filed: May 31, 2024

Related U.S. Application Data
(63) Continuation of application No. PCT/CN2022/137244, filed on Dec. 7, 2022.

(30) Foreign Application Priority Data
Dec. 8, 2021 (CN) 202111496033.6
Dec. 8, 2021 (CN) 202111496045.9
Dec. 8, 2021 (CN) 202111496879.X
Dec. 8, 2021 (CN) 202111496903.X
Dec. 8, 2021 (CN) 202111496912.9
Dec. 8, 2021 (CN) 202111496915.2

(51) Int. Cl. H01L 25/18; H01L 21/56; H01L 23/00; H01L 23/29; H01L 23/31; H01L 23/48

(52) U.S. Cl. CPC H01L 25/18; H01L 21/56; H01L 23/293; H01L 23/3135; H01L 23/481; H01L 24/08; H01L 24/13; H01L 24/14; H01L 24/16; H01L 24/81; H01L 2224/08145; H01L 2224/08225; H01L 2224/13111; H01L 2224/14051; H01L 2224/16145; H01L 2224/16225; H01L 2224/81012; H01L 2224/81203; H01L 2224/81815; H01L 2225/06513; H01L 2225/06517; H01L 2225/06544; H01L 2225/06548; H01L 2924/1434; H01L 2924/1436

(57) ABSTRACT

A packaging method and a packaging structure of a multi-layer stacked high-bandwidth memory are provided. The packaging method includes respectively providing a substrate and a plurality of memory chips. The packaging method also includes sequentially forming a plurality of first conductive bumps and a plurality of second conductive bumps on a first surface of the memory chip; and forming a plurality of pads on a second surface of the memory chip. In addition, the packaging method includes nesting a second conductive bump and a pad on every adjacent two memory chips through a thermal compression bonding process, to insulate and sequentially stack the plurality of memory chips over the substrate. Further, the method includes performing a reflow soldering process on the plurality of stacked memory chips and the substrate; and forming a plastic encapsulation layer to wrap the plurality of memory chips and the substrate.

### CROSS-REFERENCE TO RELATED APPLICATION

This application is a continuation of International Application No. PCT/CN2022/137244, filed on Dec. 7, 2022, which claims the priority of Chinese patent applications No. 202111496045.9, No. 202111496033.6, No. 202111496903.X, No. 202111496912.9, No. 202111496879.X, No. 202111496915.2, each filed on Dec. 8, 2021, the entirety of all of which is incorporated herein by reference.

### FIELD

The present disclosure generally relates to the field of semiconductor packaging technology and, more particularly, relates to a packaging method and a packaging structure of a multi-layer stacked high-bandwidth memory.

### BACKGROUND

With the development of cloud computing and mobile interconnection, the demand for servers such as data centers has surged. High-end servers require high capacity, large bandwidth and low power consumption for storage devices. In response to such demand, companies have successively launched multi-layer stacked memory packaging products based on three-dimensional stacking technology. The packaging stacked structure of the multi-layer stacked memory uses silicon vias to vertically interconnect a plurality of memory chips. The plurality of memory chips are soldered together through bumps, and the memory chips are stacked over a substrate. A non-conductive glue is disposed between the chips, the entire memory chip structure is protected by a plastic encapsulation layer, and the ultimately packaged structure is connected to external by solder balls. Because the silicon vias have advantages of high density and short vertical-interconnection distance, data transfer speed is greatly improved.

At present, the multi-layer chips of the multi-layer stacked memory are stacked by a thermal compression bond (TCB) process. Through rapid heating, a bump is connected to a pad on the back of the chip, and the pad on the back of the chip is connected to the through-silicon via of the chip. The bump is mainly made of a copper-tin structure, while the pad on the back of the chip is mainly made of a nickel-gold structure. The final stacked structure is protected by a plastic encapsulation layer.

In the case of using the copper-tin bump, due to the deformability of tin during reflow, to prevent short circuit between bumps, the spacing between bumps and the height of tin need to be strictly controlled. At present, the spacing is greater than 40 μm. When the spacing is reduced to less than 25 μm, due to the too small amount of tin, the tin will be fully converted into intermetallic compound under thermal load conditions, leading to reliability failure.

To increase storage capacity and data throughput speed, the number of stacked layers of the chip and the number of pins need to increase. However, in the current micro-bump structure, due to the limitations of spacing and height of the bump, there is limited room for continuous improvement.

In view of the above problems, a packaging method and a packaging structure of the multi-layer stacked high-bandwidth memory with reasonable design and capable of effectively solving the above problems need to be proposed.

### SUMMARY

One aspect of the present disclosure provides a packaging method of a multi-layer stacked high-bandwidth memory. The packaging method includes respectively providing a buffer chip and a plurality of groups of memory chips. Each group of the memory chips includes a first memory chip and a second memory chip. The buffer chip is provided with a plurality of first conductive vias, and both the first memory chip and the second memory chip are provided with a plurality of second conductive vias corresponding to the plurality of first conductive vias. The packaging method also includes forming a plurality of memory micro-modules by respectively performing a mixed-bonding on the first memory chip and the second memory chip in each group of the memory chips. In addition, the packaging method includes sequentially insulating and stacking the plurality of memory micro-modules over the buffer chip. Further, the packaging method includes forming a plastic encapsulation layer to wrap the plurality of memory micro-modules and the buffer chip.

Another aspect of the present disclosure provides a packaging structure of a multi-layer stacked high-bandwidth memory. The packaging structure includes a buffer chip, and the buffer chip is provided with a plurality of first conductive vias. The packaging structure also includes a plurality of memory micro-modules, and the plurality of memory micro-modules are insulated and stacked over the buffer chip. Each memory micro-module includes a first memory chip and a second memory chip. Both the first memory chip and the second memory chip are provided with a plurality of second conductive vias corresponding to and electrically connected to the plurality of first conductive vias. Every first memory chip is connected to the corresponding second memory chip by mixed-bonding through a mixed-bonding structure. Further, the packaging structure includes a plastic encapsulation layer. The plastic encapsulation layer wraps the plurality of memory micro-modules and the buffer chip.

Another aspect of the present disclosure provides a packaging method of a multi-layer stacked high-bandwidth memory. The packaging method includes respectively providing a substrate and a plurality of groups of memory chips. Each group of the memory chips includes a first memory chip and a second memory chip, and both the first memory chip and the second memory chip are provided with a plurality of conductive vias. The packaging method also includes forming a plurality of memory micro-modules by respectively performing a mixed-bonding on the first memory chip and the second memory chip in each group of the memory chips. In addition, the packaging method includes sequentially forming a plurality of first conductive bumps and a plurality of second conductive bumps at positions of a surface of the first memory chip facing towards the substrate and corresponding to the plurality of conductive vias. Moreover, the packaging method includes forming a plurality of pads at positions of a surface of the second memory chip facing away from the substrate and corresponding to the plurality of conductive vias. Further, the packaging method includes nesting the plurality of second conductive bumps and the plurality of pads through a thermal compression bonding process, to insulate and sequentially stack the plurality of memory micro-modules over the substrate. Furthermore, the packaging method includes performing a reflow soldering process on the plurality of stacked memory micro-modules and the substrate, and forming a plastic encapsulation layer to wrap the plurality of memory micro-modules and the substrate.

Another aspect of the present disclosure provides a packaging structure of a multi-layer stacked high-bandwidth memory. The packaging structure includes a substrate, a plurality of memory micro-modules, and a plastic encapsulation layer. The plurality of memory micro-modules are insulated and stacked over the substrate. Each memory micro-module includes a first memory chip and a second memory chip. Each first memory chip is connected to the corresponding second memory chip by mixed-bonding through a mixed-bonding structure. A plurality of conductive vias are disposed on both the first memory chip and the second memory chip. A plurality of first conductive bumps and a plurality of second conductive bumps are sequentially formed at positions corresponding to the plurality of conductive vias on the surface of the first memory chip facing towards the substrate, and a plurality of pads are formed at positions corresponding to the plurality of conductive vias on the surface of the second memory chip facing away from the substrate. The plurality of second conductive bumps and the plurality of pads are nested. The plastic encapsulation layer wraps the plurality of memory micro-modules and the substrate.

Another aspect of the present disclosure provides a packaging method of a multi-layer stacked high-bandwidth memory. The packaging method includes respectively providing a buffer chip and a plurality of first memory chips. Both the buffer chip and a first memory chip of the plurality of first memory chips are provided with a plurality of conductive vias. The packaging method also includes sequentially forming a plurality of first conductive bumps and a plurality of second conductive bumps at positions of the surface of the first memory chip facing towards the substrate and corresponding to the plurality of conductive vias. In addition, the packaging method includes forming a plurality of first pads at positions of a surface of the first memory chip facing away from the buffer chip and corresponding to the plurality of conductive vias. Moreover, the packaging method includes nesting the plurality of second conductive bumps and the plurality of first pads on adjacent two first memory chips through a thermal compression bonding process, to insulate and sequentially stack the plurality of first memory chips over the buffer chip. Further, the packaging method includes performing a reflow soldering process on the plurality of stacked first memory chips and the buffer chip. Furthermore, the packaging method includes forming a plastic encapsulation layer to wrap the plurality of first memory chips and the buffer chip. Various embodiments further include a packaging structure of a multi-layer stacked high-bandwidth memory, at least corresponding to the disclosed method(s).

Another aspect of the present disclosure provides a packaging structure of a multi-layer stacked high-bandwidth memory. The packaging structure includes a substrate, a plurality of first memory chips, and a plastic encapsulation layer. The substrate is provided with a plurality of first conductive vias. A first memory chip of the plurality of first memory chips is provided with a plurality of second conductive vias. A plurality of first conductive bumps and a plurality of second conductive bumps are sequentially formed at positions of a surface of the first memory chip facing towards the substrate and corresponding to the plurality of second conductive vias, and a plurality of first pads are formed at positions of a surface of the first memory chip facing away from the substrate corresponding to the plurality of second conductive vias. The plurality of second conductive bumps and the plurality of first pads on the adjacent two first memory chips are nested, such that the plurality of first memory chips are insulated and sequentially stacked over the substrate. The plastic encapsulation layer wraps the plurality of first memory chips and the substrate.

Another aspect of the present disclosure provides a packaging method of a multi-layer stacked high-bandwidth memory. The packaging method includes respectively providing a substrate and a plurality of first memory chips. The substrate is provided with a plurality of first conductive vias, and a first memory chip of the plurality of first memory chips is provided with a plurality of second conductive vias electrically connected with the plurality of first conductive vias. The packaging method also includes sequentially forming a plurality of first conductive bumps and a plurality of second conductive bumps at positions of a surface of the first memory chip facing towards the substrate and corresponding to the plurality of second conductive vias. In addition, the packaging method includes forming a plurality of first pads at positions of a surface of the first memory chip facing away from the substrate and corresponding to the plurality of second conductive vias. Moreover, the packaging method includes nesting the plurality of second conductive bumps and the plurality of first pads on adjacent two first memory chips through a thermal compression bonding process, to insulate and sequentially stack the plurality of first memory chips over the substrate. Further, the packaging method includes performing a reflow soldering process on the plurality of stacked first memory chips and the substrate. Furthermore, the packaging method includes forming a plastic encapsulation layer to wrap the plurality of first memory chips and the substrate.

Another aspect of the present disclosure provides a packaging method of a multi-layer stacked high-bandwidth memory. The packaging method includes forming a plurality of cutting marks at preset positions in a first memory chip, and between two adjacent cutting marks, sequentially stacking and arranging a plurality of second memory chips including a plurality of first conductive vias over the first memory chip by mixed-bonding. The packaging method also includes plastic-encapsulating the first memory chip and the plurality of second memory chips to form a first plastic-encapsulation layer. In addition, the packaging method includes attaching the plastic-encapsulated first memory chip on a patch film, and cutting the first plastic-encapsulation layer at positions corresponding to the plurality of cutting marks to form a plurality of independent second memory chip groups. Moreover, the packaging method includes cutting the first memory chip along the plurality of cutting marks to form a plurality of independent memory stack modules. Further, the packaging method includes performing a thermal compression bonding process on the plurality of memory stack modules and the buffer chip, where the buffer chip is provided with a plurality of second conductive vias. Furthermore, the packaging method includes plastic-encapsulating the buffer chip and the memory stack modules to form a second plastic-encapsulation layer, and cutting the second plastic encapsulation layer and the buffer chip to form a plurality of independent memory packaging structures. Various embodiments further include a packaging structure of a multi-layer stacked high-bandwidth memory, at least corresponding to the disclosed method(s).

Another aspect of the present disclosure provides a packaging structure of a multi-layer stacked high-bandwidth memory. The packaging structure includes a first memory chip, a plurality of second memory chips, a substrate, and a plastic encapsulation layer. A second memory chip of the plurality of second memory chips is provided with a plurality of first conductive vias. The substrate is provided with a plurality of second conductive vias electrically connected to the plurality of first conductive vias. The plurality of second memory chips are sequentially stacked over the substrate. Every adjacent second memory chips are connected by mixed-bonding, and the substrate is bonded to the second memory chip by a thermal compression bonding process. The first memory chip is disposed on a side of the plurality of second memory chips facing away from the substrate. The first memory chip is connected to the second memory chip by mixed-bonding. The plastic encapsulation layer warps the first memory chip, the plurality of second memory chips, and the substrate.

Another aspect of the present disclosure provides a packaging method of a multi-layer stacked high-bandwidth memory. The packaging method includes forming a plurality of cutting marks at preset positions in a first memory chip, and between two adjacent cutting marks, sequentially stacking and arranging a plurality of second memory chips including a plurality of first conductive vias over the first memory chip by mixed-bonding. The packaging method also includes plastic-encapsulating the first memory chip and the plurality of second memory chips to form a first plastic-encapsulation layer. In addition, the packaging method includes attaching the plastic-encapsulated first memory chip on a patch film, and cutting the first plastic-encapsulation layer at positions corresponding to the plurality of cutting marks to form a plurality of independent second memory chip groups. Moreover, the packaging method includes cutting the first memory chip along the plurality of cutting marks to form a plurality of independent memory stack modules. Further, the packaging method includes performing a thermal compression bonding process on the plurality of memory stack modules and the substrate, where the substrate is provided with a plurality of second conductive vias. Furthermore, the packaging method includes plastic-encapsulating the substrate and the plurality of memory stack modules to form a second plastic-encapsulation layer, and cutting the second plastic encapsulation layer and the substrate to form a plurality of independent memory packaging structures.

Other aspects of the present disclosure can be understood by those skilled in the art in light of the description, the claims, and the drawings of the present disclosure.

### BRIEF DESCRIPTION OF THE DRAWINGS

To more clearly illustrate the embodiments of the present disclosure, the drawings will be briefly described below. The drawings in the following description are certain embodiments of the present disclosure, and other drawings may be obtained by a person of ordinary skill in the art in view of the drawings provided without creative efforts.

FIG. 1 illustrates a schematic diagram of a packaging process of a multi-layer chip;

FIG. 2 illustrates a schematic flowchart of an exemplary packaging method of a multi-layer stacked high-bandwidth memory consistent with disclosed embodiments of the present disclosure;

FIGS. 3-11 illustrate semiconductor structures corresponding to certain stages of an exemplary packaging method of a multi-layer stacked high-bandwidth memory consistent with disclosed embodiments of the present disclosure;

FIG. 12 illustrates a schematic diagram of locations of defective chips in a wafer of an exemplary multi-layer stacked high-bandwidth memory consistent with disclosed embodiments of the present disclosure;

FIG. 13 illustrates a schematic diagram of locations of defective chips in another wafer of an exemplary multi-layer stacked high-bandwidth memory consistent with disclosed embodiments of the present disclosure;

FIG. 14 illustrates a schematic diagram of locations of defective chips after stacking two wafers of an exemplary multi-layer stacked high-bandwidth memory consistent with disclosed embodiments of the present disclosure;

FIG. 15 illustrates a schematic diagram of a packaging process of a multi-layer chip;

FIG. 16 illustrates a schematic flowchart of an exemplary packaging method of a multi-layer stacked high-bandwidth memory consistent with disclosed embodiments of the present disclosure;

FIG. 17 illustrates a schematic diagram of a second conductive bump and a first pad that are nested in an exemplary multi-layer stacked high-bandwidth memory consistent with disclosed embodiments of the present disclosure;

FIG. 18 illustrates a schematic diagram of a first pad in an exemplary multi-layer stacked high-bandwidth memory consistent with disclosed embodiments of the present disclosure;

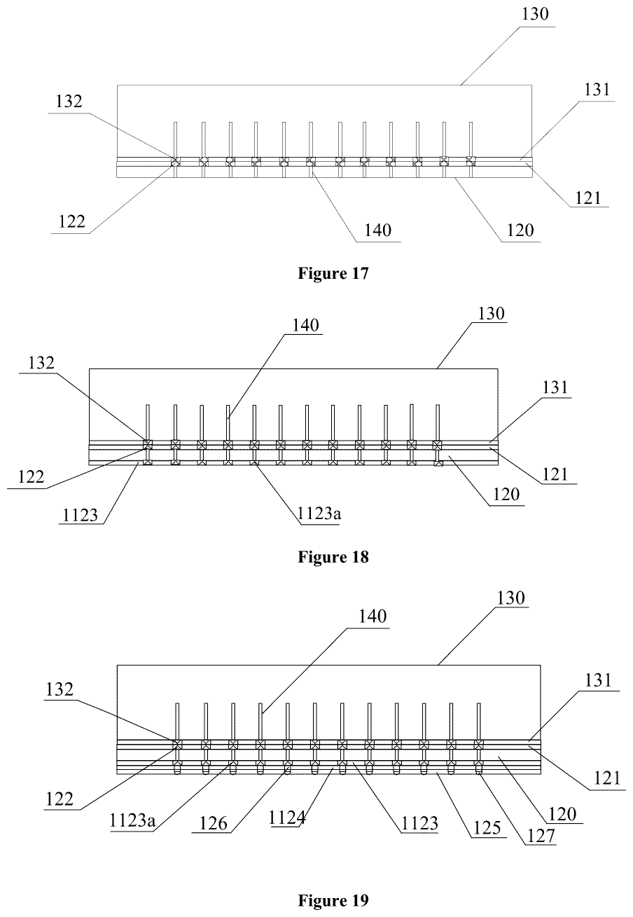

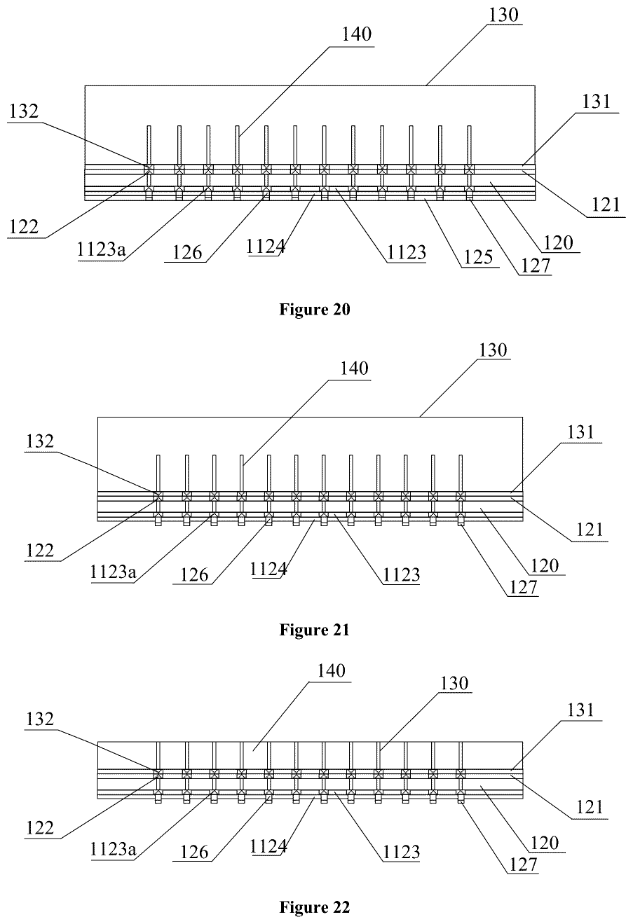

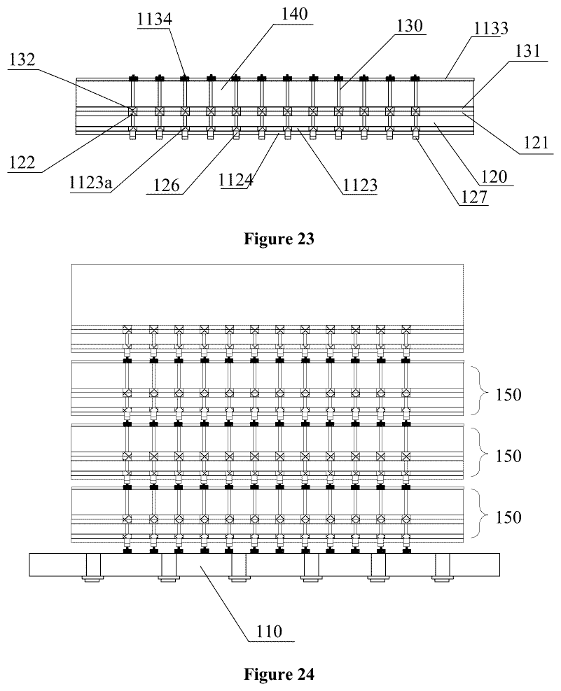

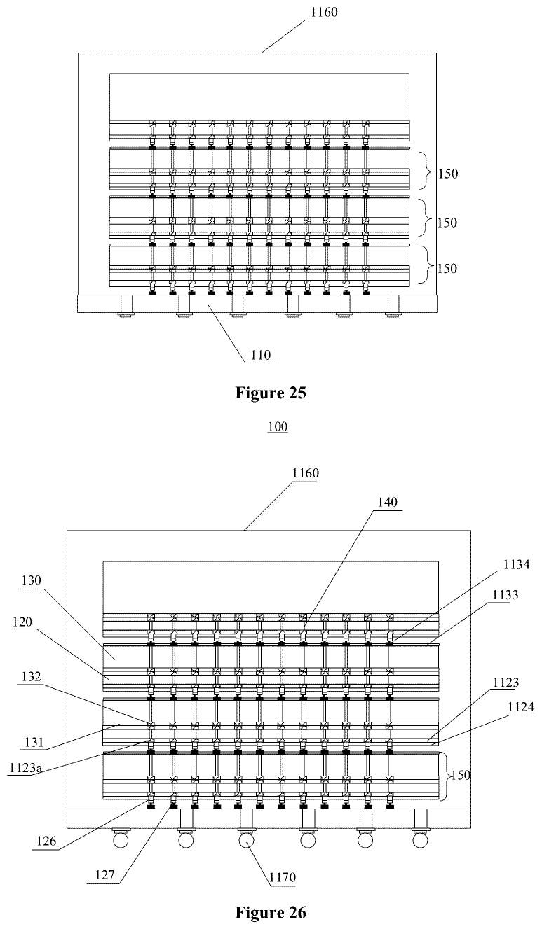

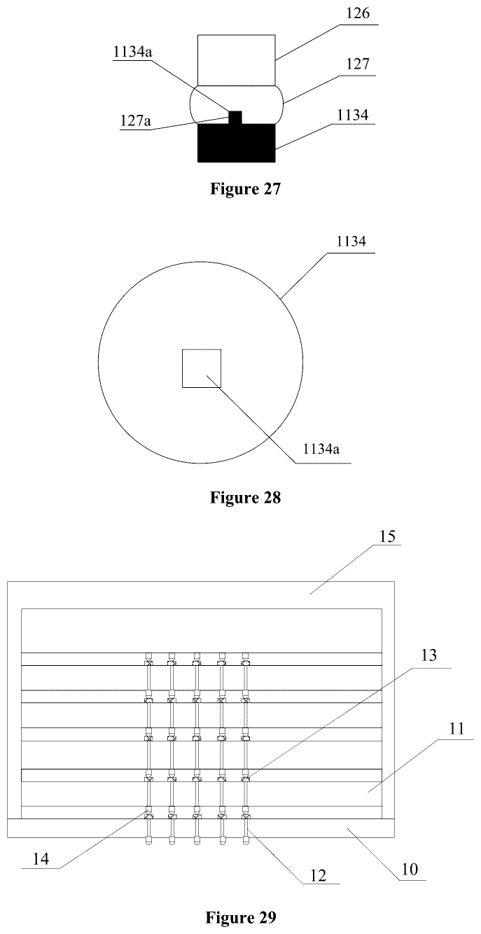

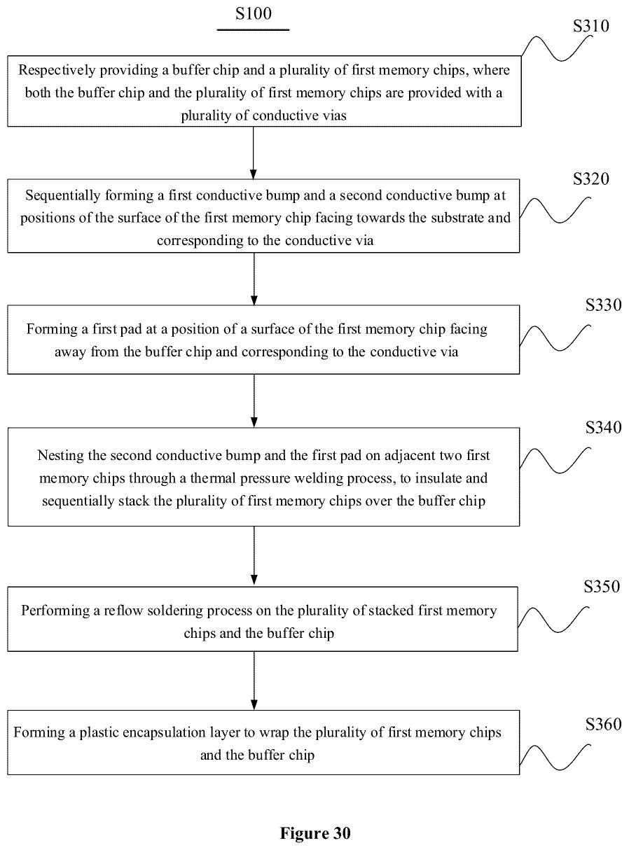

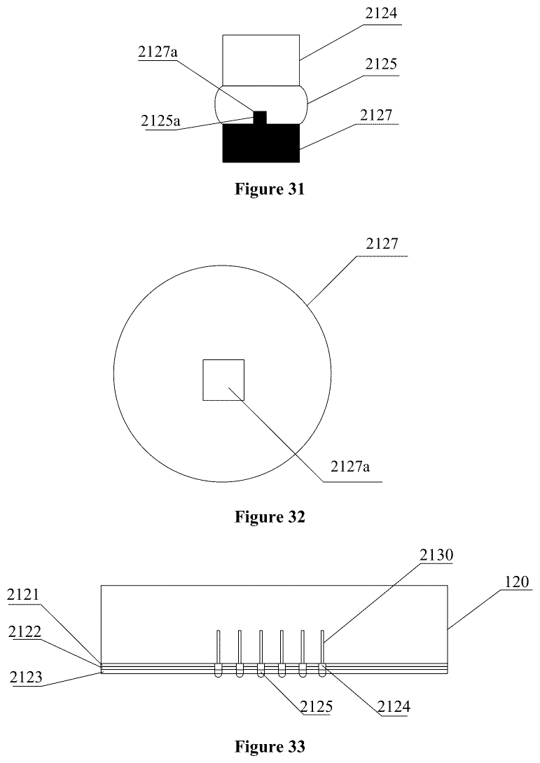

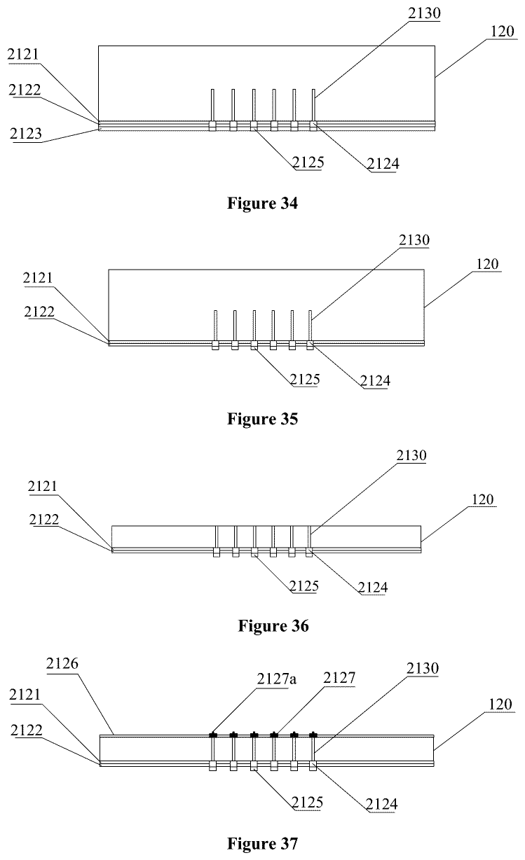

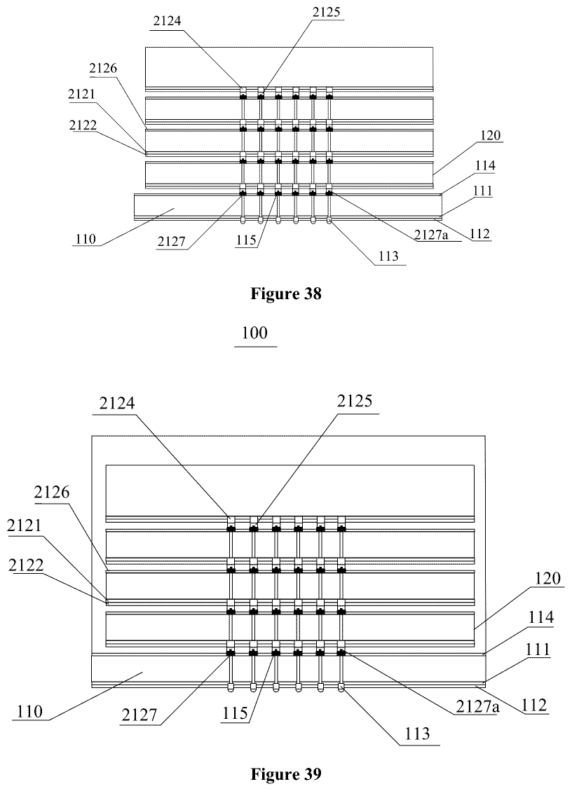

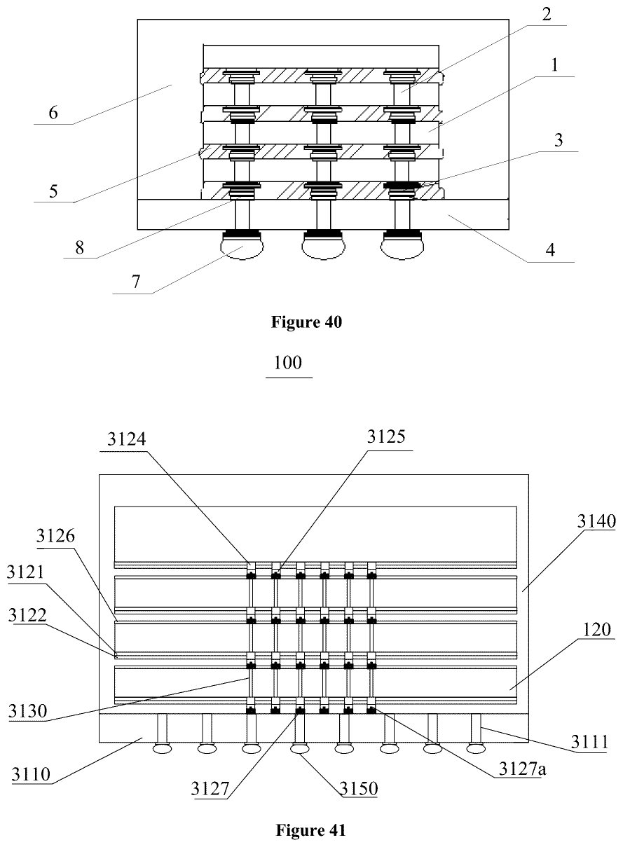

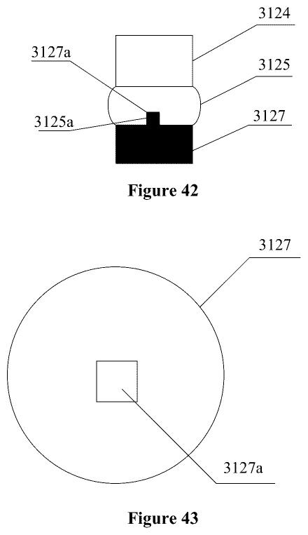

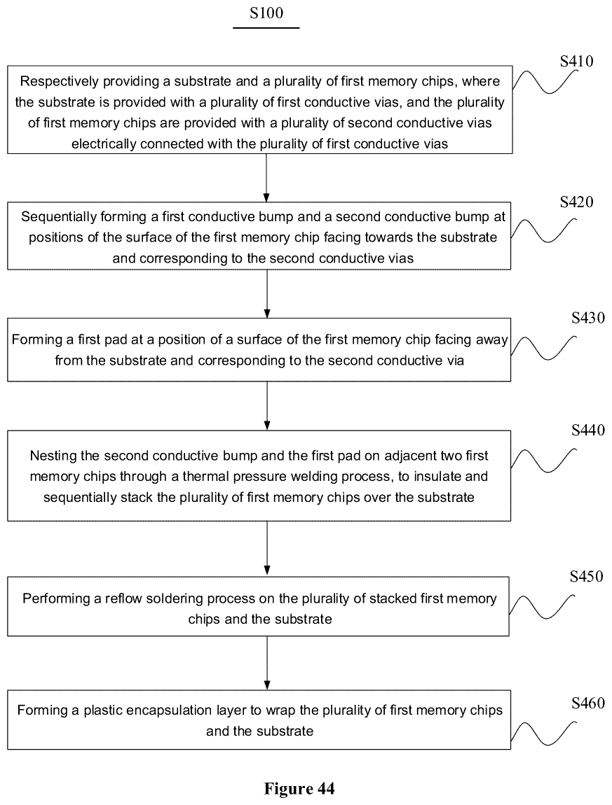

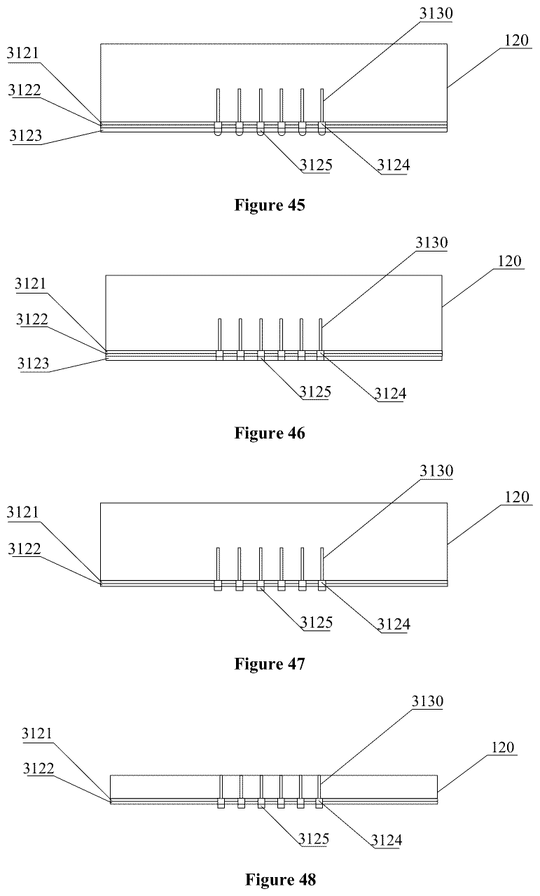

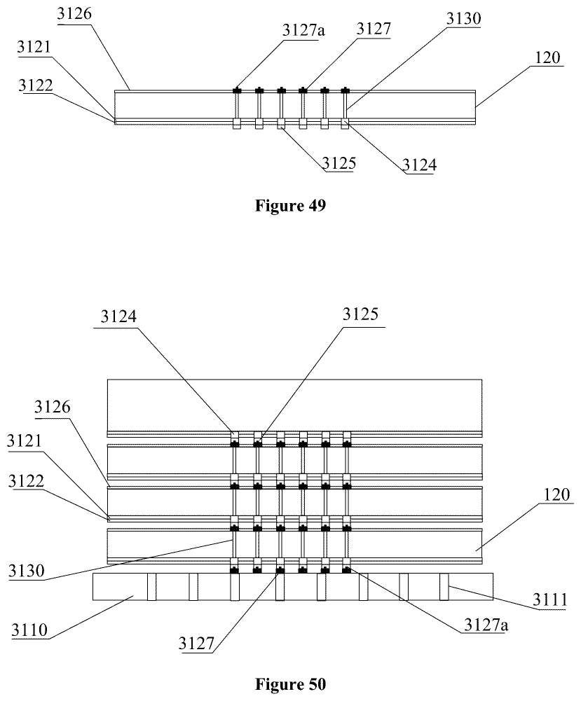

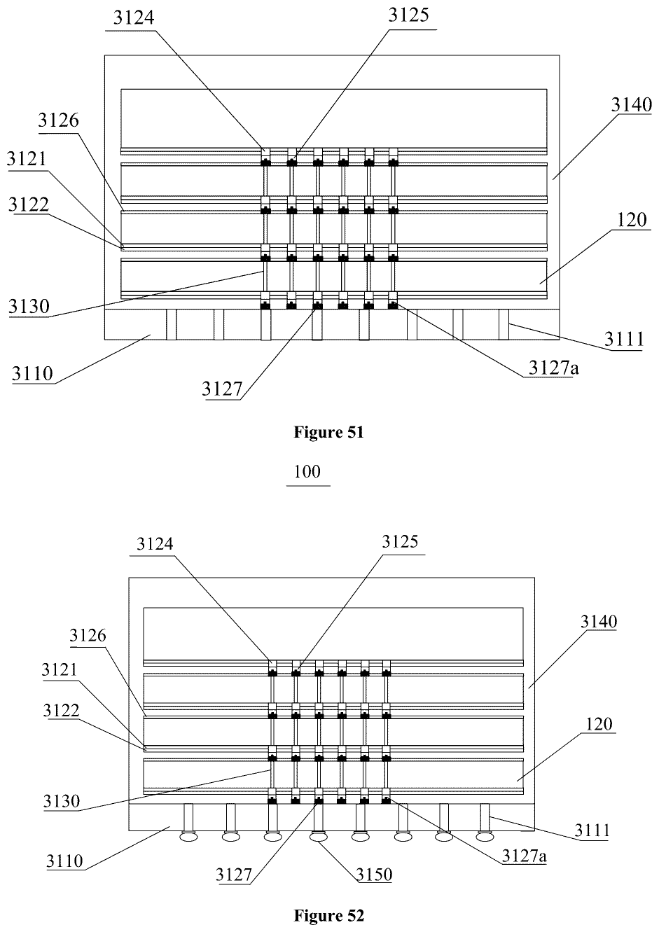

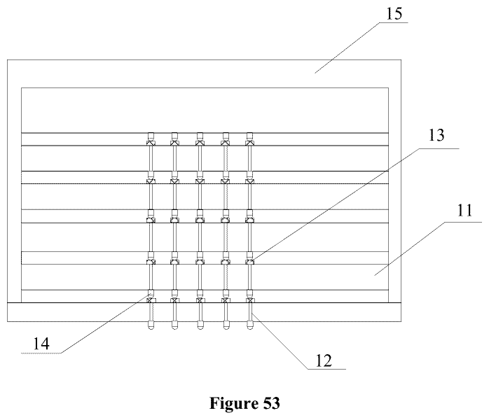

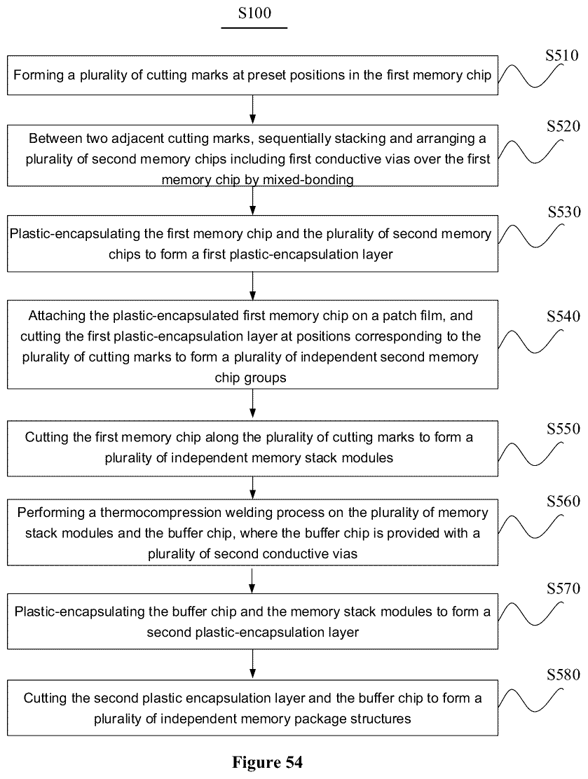

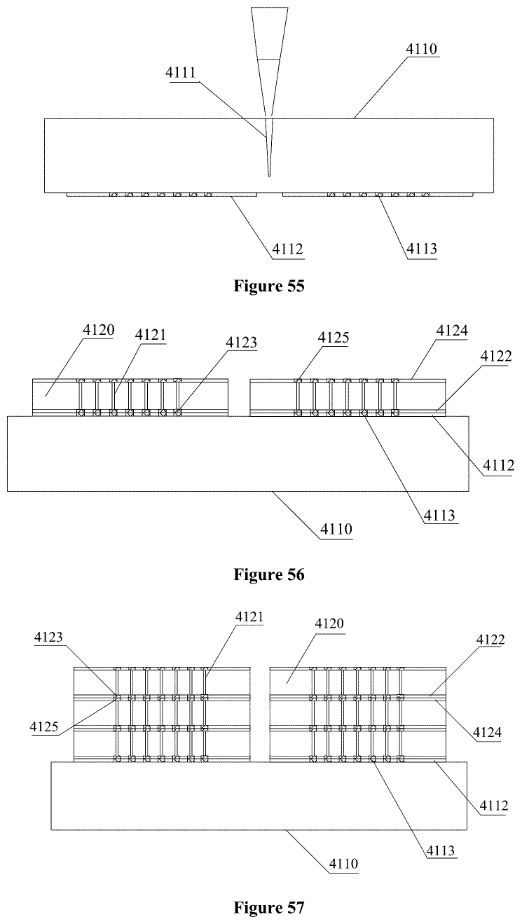

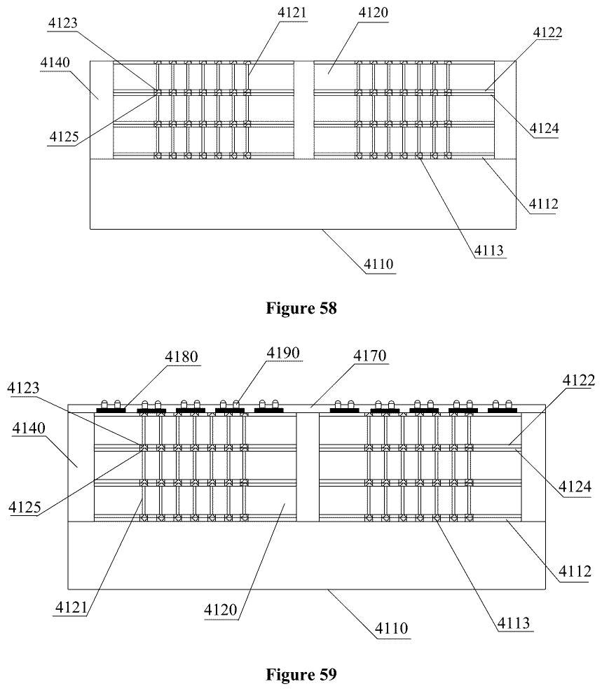

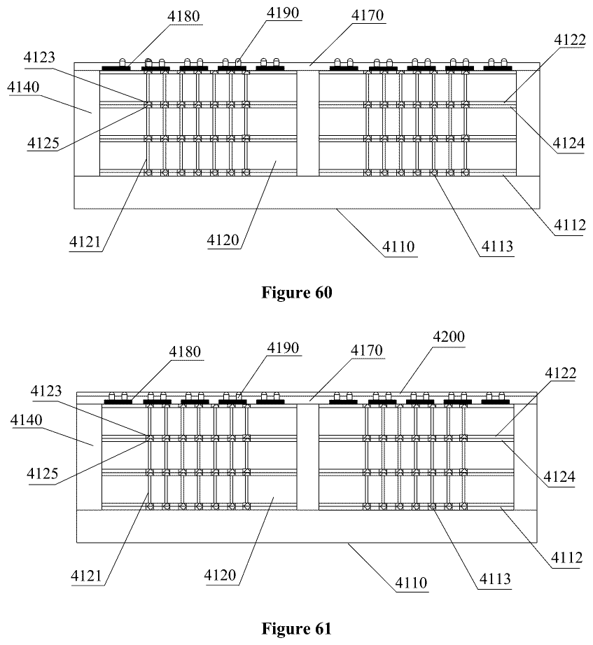

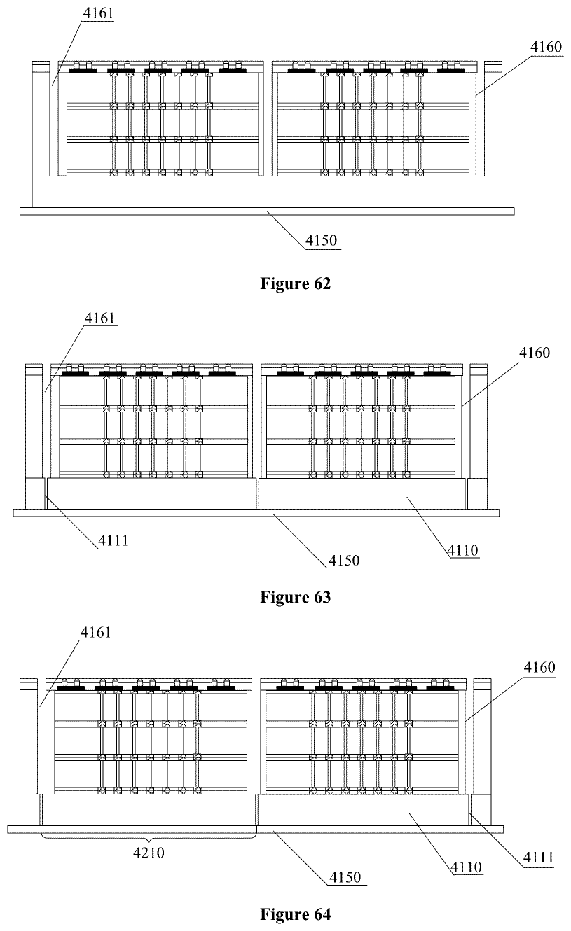

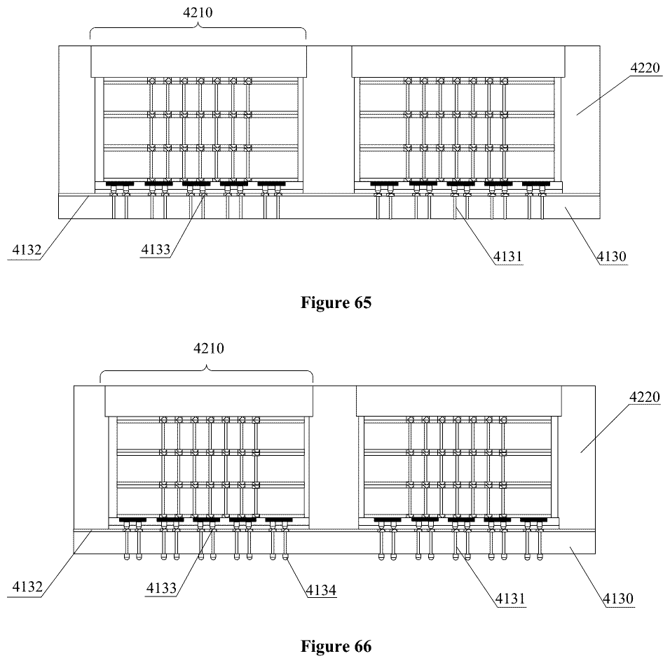

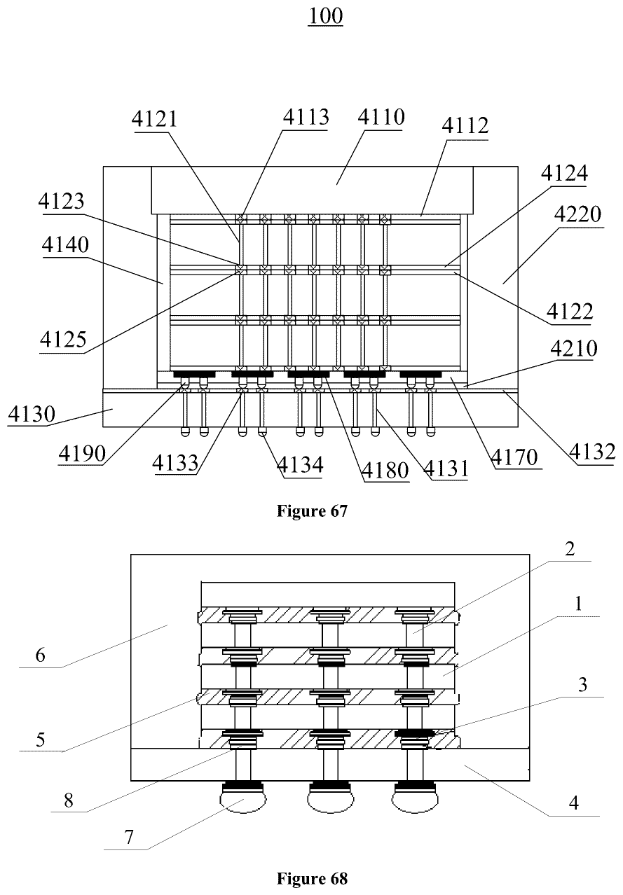

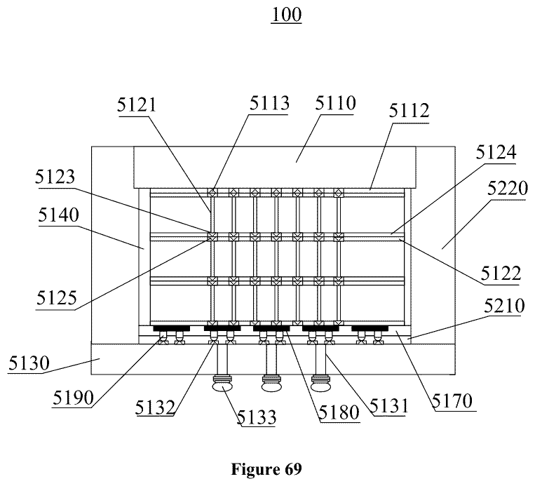

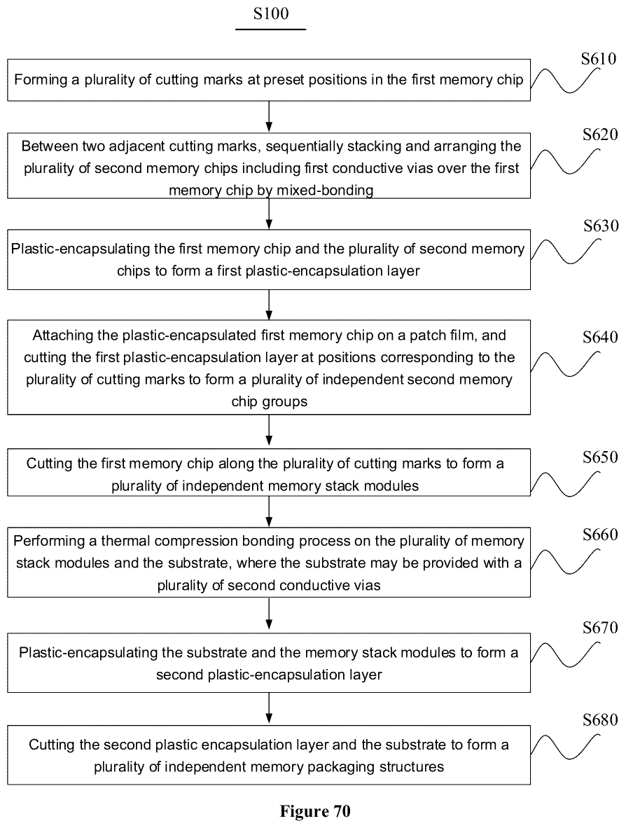

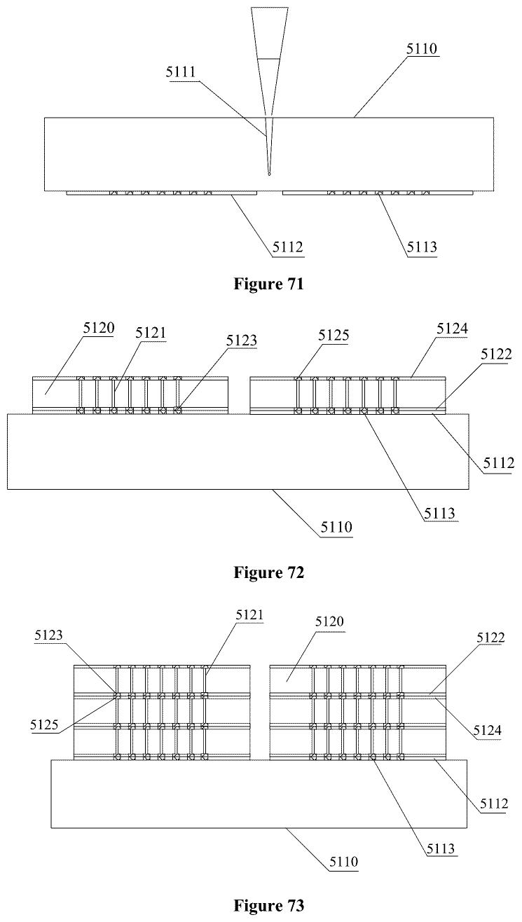

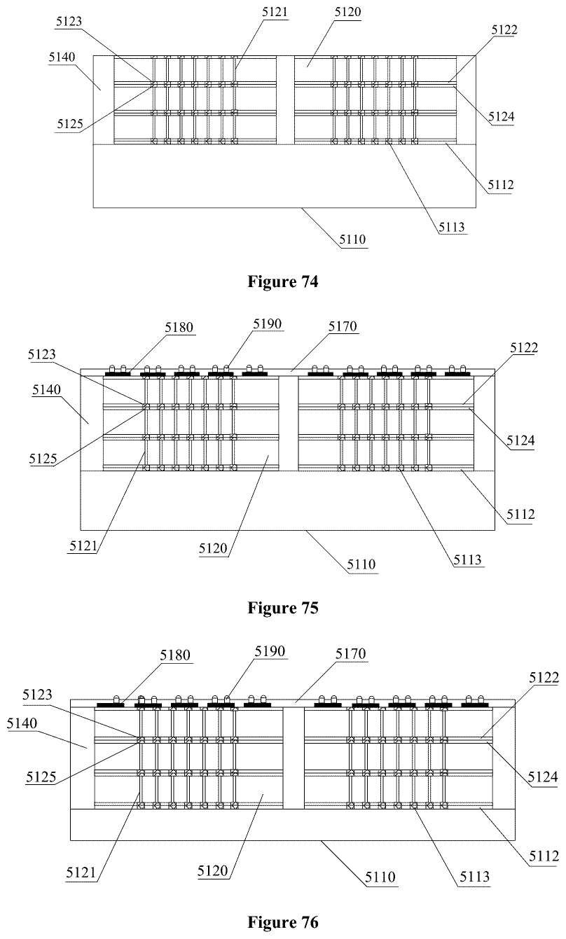

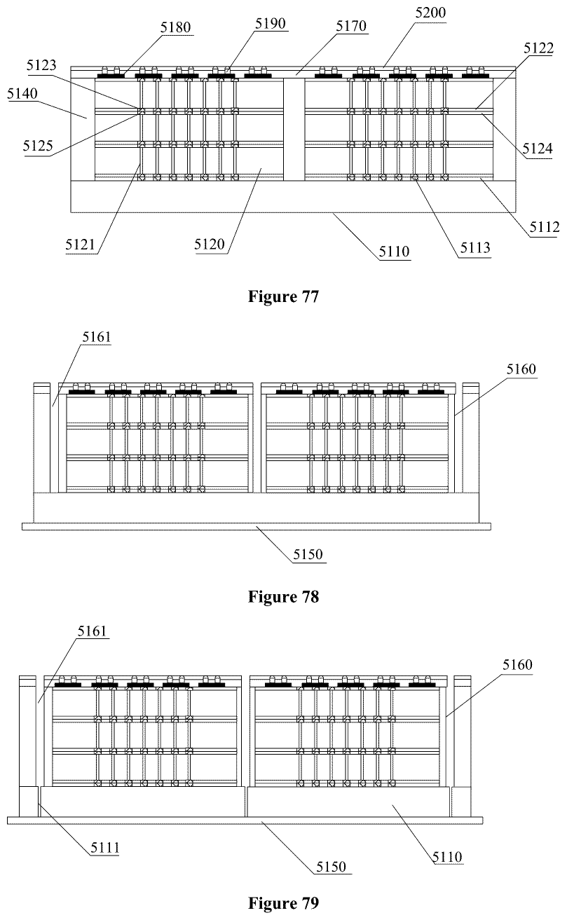

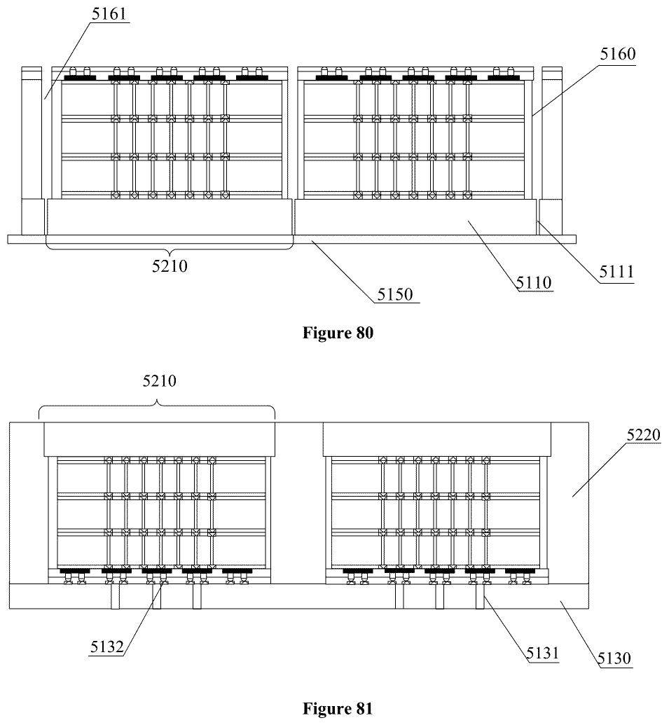

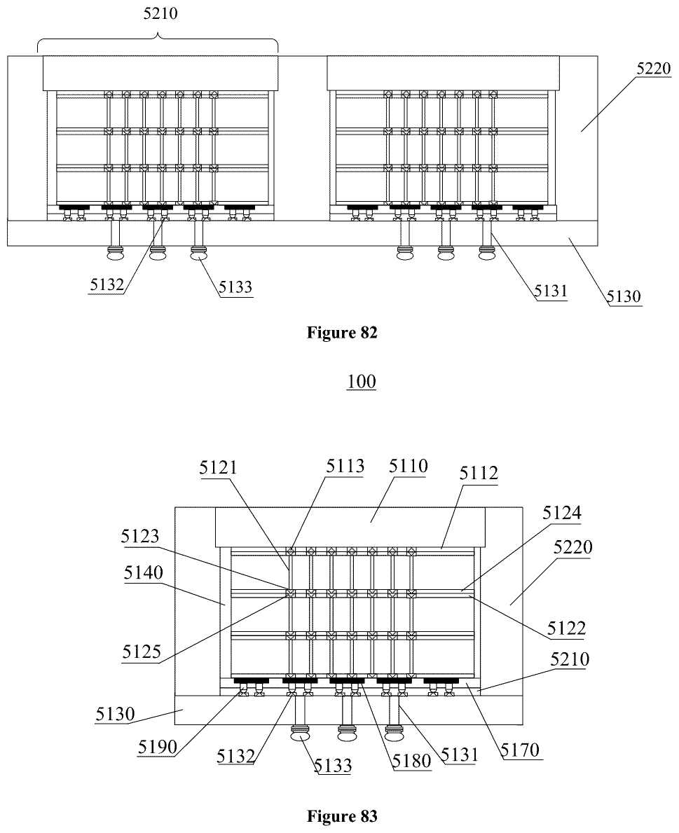

FIGS. 17-26 illustrate semiconductor structures corresponding to certain stages of an exemplary packaging method of a multi-layer stacked high-bandwidth memory consistent with disclosed embodiments of the present disclosure;

FIG. 27 illustrates a schematic diagram of a second conductive bump and a first pad that are nested in another exemplary multi-layer stacked high-bandwidth memory consistent with disclosed embodiments of the present disclosure;

FIG. 28 illustrates a schematic diagram of a first pad in another exemplary multi-layer stacked high-bandwidth memory consistent with disclosed embodiments of the present disclosure;

FIG. 29 illustrates a schematic diagram of a packaging structure of a multi-layer stacked high-bandwidth memory;

FIG. 30 illustrates a schematic flowchart of an exemplary packaging method of a multi-layer stacked high-bandwidth memory consistent with disclosed embodiments of the present disclosure;

FIG. 31 illustrates a schematic diagram of a second conductive bump and a first pad that are nested in an exemplary multi-layer stacked high-bandwidth memory consistent with disclosed embodiments of the present disclosure;

FIG. 32 illustrates a schematic diagram of a first pad in an exemplary multi-layer stacked high-bandwidth memory consistent with disclosed embodiments of the present disclosure;

FIGS. 33-39 illustrate semiconductor structures corresponding to certain stages of an exemplary packaging method of a multi-layer stacked high-bandwidth memory consistent with disclosed embodiments of the present disclosure;

FIG. 40 illustrates a schematic diagram of a packaging structure of a multi-layer stacked high-bandwidth memory;

FIG. 41 illustrates a schematic diagram of a packaging structure of a multi-layer stacked high-bandwidth memory consistent with disclosed embodiments of the present disclosure;

FIG. 42 illustrates a schematic diagram of a second conductive bump and a first pad that are nested in an exemplary multi-layer stacked high-bandwidth memory consistent with disclosed embodiments of the present disclosure;

FIG. 43 illustrates a schematic diagram of a first pad in an exemplary multi-layer stacked high-bandwidth memory consistent with disclosed embodiments of the present disclosure;

FIG. 44 illustrates a schematic flowchart of an exemplary packaging method of a multi-layer stacked high-bandwidth memory consistent with disclosed embodiments of the present disclosure;

FIGS. 45-52 illustrate semiconductor structures corresponding to certain stages of an exemplary packaging method of a multi-layer stacked high-bandwidth memory consistent with disclosed embodiments of the present disclosure;

FIG. 53 illustrates a schematic diagram of a packaging structure of a multi-layer stacked high-bandwidth memory;

FIG. 54 illustrates a schematic flowchart of an exemplary packaging method of a multi-layer stacked high-bandwidth memory consistent with disclosed embodiments of the present disclosure;

FIGS. 55-67 illustrate semiconductor structures corresponding to certain stages of an exemplary packaging method of a multi-layer stacked high-bandwidth memory consistent with disclosed embodiments of the present disclosure;

FIG. 68 illustrates a schematic diagram of a packaging structure of a multi-layer stacked high-bandwidth memory;

FIG. 69 illustrates a schematic diagram of an exemplary packaging structure of a multi-layer stacked high-bandwidth memory consistent with disclosed embodiments of the present disclosure;

FIG. 70 illustrates a schematic flowchart of an exemplary packaging method of a multi-layer stacked high-bandwidth memory consistent with disclosed embodiments of the present disclosure; and

FIGS. 71-83 illustrate semiconductor structures corresponding to certain stages of an exemplary packaging method of a multi-layer stacked high-bandwidth memory consistent with disclosed embodiments of the present disclosure.

### DETAILED DESCRIPTION OF THE DISCLOSURE

Reference will now be made in detail to exemplary embodiments of the disclosure, which are illustrated in the accompanying drawings. Wherever possible, the same reference numbers will be used throughout the drawings to refer to the same or the alike parts. The described embodiments are some but not all of the embodiments of the present disclosure. Based on the disclosed embodiments, persons of ordinary skill in the art may derive other embodiments consistent with the present disclosure, all of which are within the scope of the present disclosure.

Similar reference numbers and letters represent similar terms in the following Figures, such that once an item is defined in one Figure, it does not need to be further discussed in subsequent Figures.

### Embodiment 1

For enterprise-level applications such as data centers, large-capacity high-speed storage becomes a necessity. In response to such demand, high-bandwidth memory (HBM) came into being. As shown in FIG. 1, the existing HBM uses through-silicon vias to vertically interconnect a plurality of memory chips 11, and exchanges data with external through a buffer chip 10 at the bottom layer. Because the through-silicon vias have advantages of high density and short vertical-interconnection distance, data transfer speed is greatly improved.

At present, the multi-layer chips of the HBM are stacked by a thermal compression bond (TCB) process. Through rapid heating, a micro-bump 14 is connected to a pad 13 on the back of the chip, and the pad on the back of the chip is connected to the through-silicon via 12 of the chip. The micro-bump is mainly made of a copper-tin structure, while the pad on the back of the chip is mainly made of a nickel-gold structure. The final stacked structure is protected by a plastic encapsulation layer 15.

In the case of using the copper-tin micro-bump, due to the deformability of tin during reflow, to prevent short circuit between micro-bumps, the spacing between micro-bumps and the height of tin need to be strictly controlled. At present, the spacing is greater than 40 μm. When the spacing is reduced to less than 25 μm, due to the too small amount of tin, the tin will be fully converted into intermetallic compound under thermal load conditions, leading to reliability failure.

To increase storage capacity and data throughput speed, the number of stacked layers of the chip and the number of pins need to increase. However, in the current micro-bump structure, due to the limitations of spacing and height of the micro-bump, there is limited room for continuous improvement.

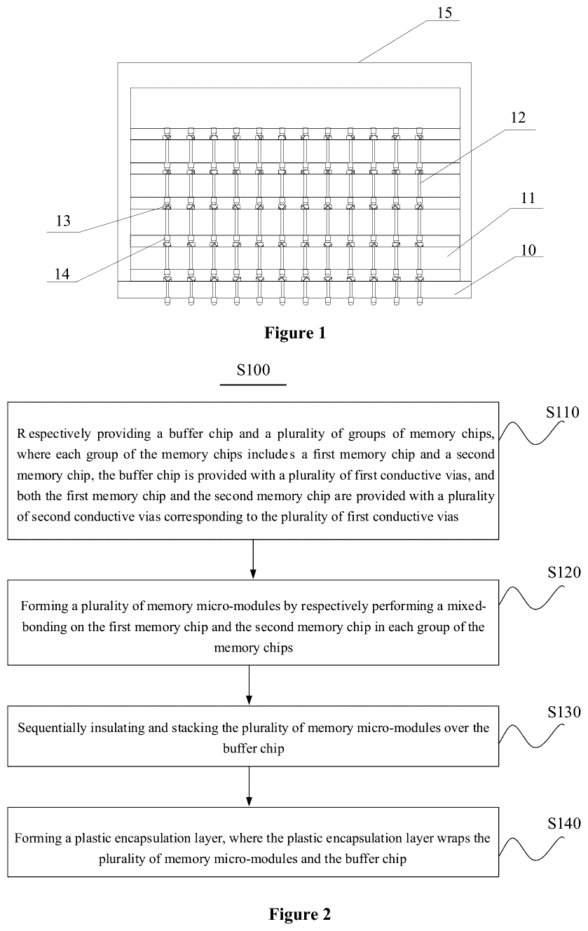

The present disclosure provides a packaging method of a multi-layer stacked high-bandwidth memory. FIG. 2 illustrates a schematic flowchart of the packaging method. Referring to FIG. 2, the packaging method S100 may include following.

S110: respectively providing a buffer chip and a plurality of groups of memory chips, where each group of the memory chips may include a first memory chip and a second memory chip. The buffer chip may be provided with a plurality of first conductive vias, and both the first memory chip and the second memory chip may be provided with a plurality of second conductive vias corresponding to the plurality of first conductive vias.

In one embodiment, referring to FIG. 11, the buffer chip 110 and the plurality of groups of the memory chips may be provided, respectively. Each group of the memory chips may include the first memory chip 120 and the second memory chip 130. The buffer chip 110 may be provided with the plurality of first conductive vias 140a, and both the first memory chip 120 and the second memory chip 130 may be provided with the plurality of second conductive vias 140b corresponding to the plurality of first conductive vias 140a. In other words, the buffer chip 110 may be electrically connected to the first memory chip 120 and the second memory chip 130 through the corresponding plurality of first conductive vias 140a and plurality of second conductive vias 140b. Further, the plurality of conductive vias 140 (including the plurality of first conductive vias 140a and the plurality of second conductive vias 140b) may include through-silicon vias.

S120: forming a plurality of memory micro-modules by respectively performing a mixed-bonding on the first memory chip and the second memory chip in each group of the memory chips.

In one embodiment, the first memory chip 120 and the second memory chip 130 in each group of the memory chips may be mixed-bonded to form the plurality of memory micro-modules 150.

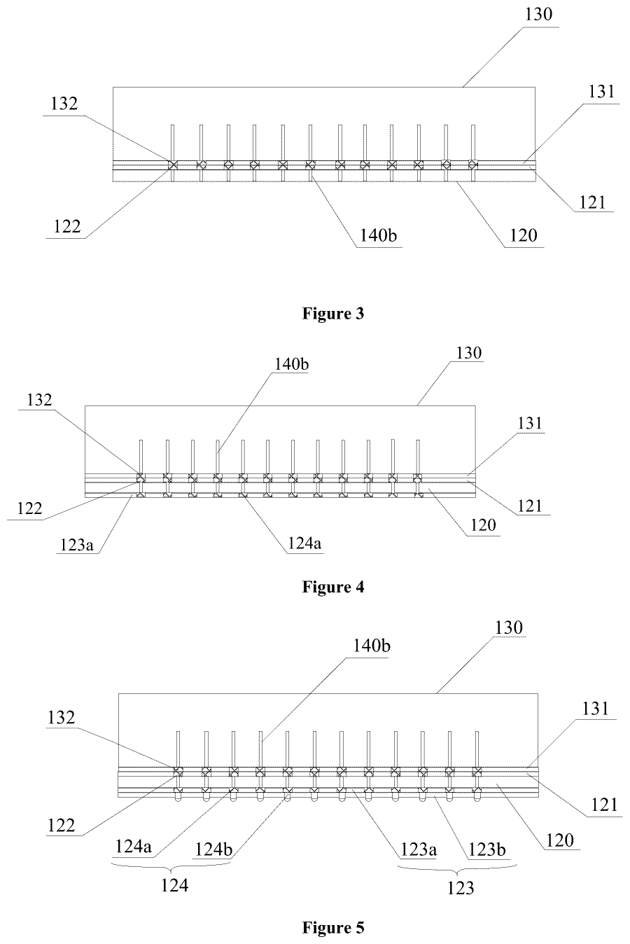

In one embodiment, referring to FIG. 3, a first passivation layer 121 and a first metal pad 122 may be disposed on a surface of the first memory chip 120 facing towards the second memory chip 130, and a second passivation layer 131 and a second metal pad 132 may be disposed on a surface of the second memory chip 130 facing towards the first memory chip 120. A chemical mechanical polishing process may be performed on the surface of the first memory chip 120 with the first passivation layer 121 and the first metal pad 122, and similarly, a chemical mechanical polishing process may be performed on the surface of the second memory chip 130 with the second passivation layer 131 and the second metal pad 132.

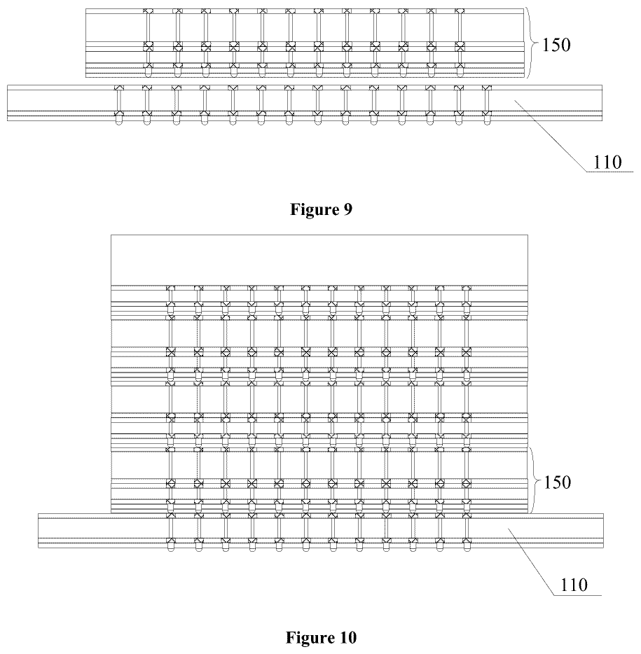

Forming the plurality of memory micro-modules 150 shown in FIG. 9 by respectively performing the mixed-bonding on the first memory chip 120 and the second memory chip 130 in each group of the memory chips may include following.

First, as shown in FIG. 3, the first passivation layer 121 on the first memory chip 120 may be bonded to the second passivation layer 131 on the corresponding second memory chip 130. Both the first passivation layer 121 and the second passivation layer 131 may include silicon dioxide passivation layer. The circuit layers of the first memory chip 120 and the second memory chip 130 may be stacked on each other, such that the first passivation layer 121 and the second passivation layer 131, in other words, the silicon dioxide passivation layers may be bonded.

Next, as shown in FIG. 3, the first metal pad 122 on the first memory chip 120 may be bonded to the corresponding second metal pad 132 on the second memory chip 130. In one embodiment, both the first metal pad 122 and the second metal pad 132 may include copper pad. After the first passivation layer 121 and the second passivation layer 131 are bonded, a high temperature pressing may be performed at a temperature greater than 200° C., such that the first metal pad 122 and the second metal pad 132 may be bonded due to thermal expansion of copper.

It should be noted that when the thickness of the first memory chip 120 is very thin and the plurality of second conductive vias 140b are capable of being exposed, the first memory chip 120 may not need to be thinned. Similarly, when the thickness of the second memory chip 130 is very thin and the plurality of second conductive vias 140b are capable of being exposed, the second memory chip 130 may not need to be thinned. However, when the thickness of the first memory chip 120 is very thick and the plurality of second conductive vias 140b cannot be exposed, and the thickness of the second memory chip 130 is also very thick and the plurality of second conductive vias 140b cannot be exposed, the first memory chip 120 and the second memory chip 130 may need to be thinned first. In one embodiment, both the first memory chip 120 and the second memory chip 130 may need to be thinned.

In one embodiment, before the plurality of memory micro-modules are insulated and sequentially disposed over the buffer chip, the method may further include following.

First, a thinning process may be performed on the surface of the first memory chip away from the second memory chip, to expose the plurality of second conductive vias. In one embodiment, as shown in FIG. 4, a thinning process may be performed on the backside of the first memory chip 120, and then an etching process may be performed to expose the plurality of second conductive vias 140b. The first memory chip 120 may be thinned to merely keep the circuit layer.

Next, a first insulating layer may be formed on the surface of the first memory chip away from the second memory chip after performing the mixed-bonding. In one embodiment, the first insulating layer 123 may be formed on the backside of the first memory chip 120, and the first insulating layer 123 may include a first passivation sublayer 123a and a dielectric layer 123b that are formed in sequence.

Third, the first insulating layer may be patterned to form a plurality of first openings. In one embodiment, the first insulating layer 123 may be patterned using a photolithography process, to form the plurality of first openings (not shown in the Figure).

Ultimately, a plurality of first conductive connection structures may be formed in the plurality of first openings, and the first conductive connection structure may be electrically connected to the second conductive via in the first memory chip. In one embodiment, the plurality of first conductive connection structures 124 may be formed in the plurality of first openings, and each first conductive connection structure 124 may include a first connection metal pad 124a and a first bump 124b that are formed in sequence.

In one embodiment, a back opening process may be performed on the back surface of the mixed-bonded first memory chip 120 to form the first insulating layer 123. In one embodiment, as shown in FIG. 4, the first passivation sublayer 123a may be first formed on the back surface of the first memory chip 120, where the first passivation sublayer 123a may include a silicon dioxide passivation layer. The first passivation sublayer 123a may be patterned using the photolithography process, and the first connection metal pad 124a shown in FIG. 4 may be formed on the patterned first passivation sublayer 123a. In one embodiment, the first connection metal pad 124a may include a nickel-gold pad. As shown in FIG. 5, the dielectric layer 123b may be formed on the first connection metal pad 124a. The dielectric layer 123b may be made of a material including polyimide (PI), polybenzoate oxazole (PBO), etc. In one embodiment, the dielectric layer 123b may be made of polyimide (PI), and the dielectric layer 123b may often be formed by a wafer spin coating. The dielectric layer 123b may be patterned using a photolithography process, and the first bump 124b shown in FIG. 5 may be formed on the patterned dielectric layer 123b. In one embodiment, the first bump 124b may include a copper-tin bump. In other words, as shown in FIG. 5, the first passivation sublayer 123a, the first connection metal pad 124a, the dielectric layer 123b, and the first bump 124b may be sequentially formed on the backside of the thinned and mixed-bonded first memory chip 120.

In one embodiment, before the plurality of memory micro-modules are insulated and sequentially disposed over the buffer chip, the method may further include following.

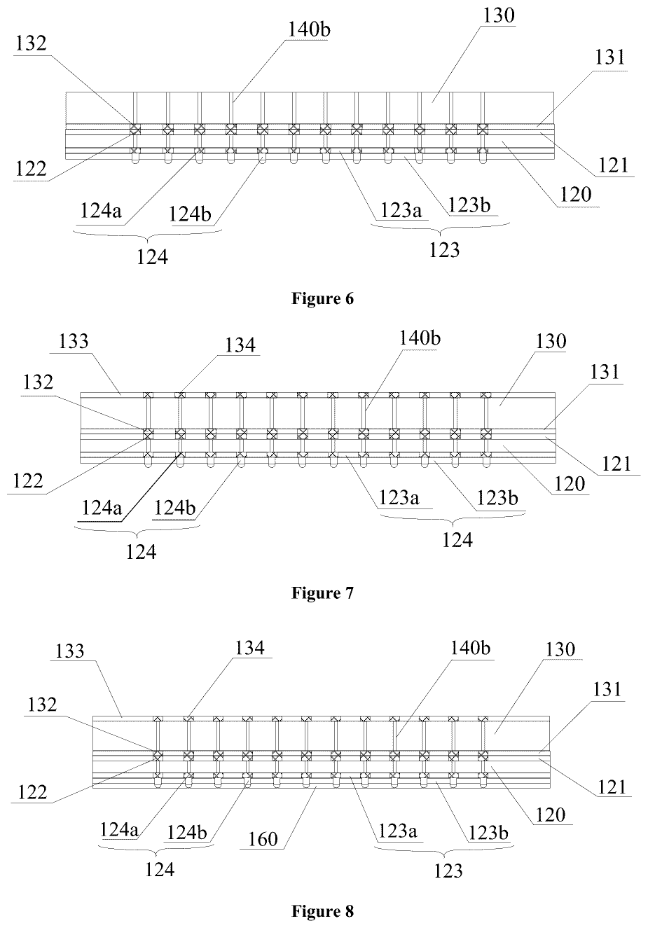

First, a thinning process may be performed on the surface of the second memory chip away from the first memory chip, to expose the plurality of second conductive vias. In one embodiment, as shown in FIG. 6, the thinning process may be performed on the backside of the second memory chip 130, and then an etching process may be performed to expose the plurality of second conductive vias 140b.

Next, a second insulating layer may be formed on the surface of the mixed-bonded second memory chip away from the first memory chip. In one embodiment, as shown in FIG. 7, a backside opening process may be performed on the backside of the second memory chip 130 to form the second insulating layer 133. In one embodiment, the second insulating layer 133 may include a second passivation sublayer, and the second passivation sublayer may include a silicon dioxide passivation layer.

Third, the second insulating layer may be patterned to form a plurality of second openings. In one embodiment, the second insulating layer 133 may be patterned through a photolithography process to form a plurality of second openings (not shown in the Figure).

Ultimately, a plurality of second conductive connection structures may be formed in the plurality of second openings, and the second conductive connection structure may be electrically connected to the second conductive via in the second memory chip. In one embodiment, as shown in FIG. 7, the plurality of second conductive connection structures 134 may be formed in the plurality of second openings. The second conductive connection structure 134 may be electrically connected to the second conductive via 140b in the second memory chip 130. In one embodiment, the second conductive connection structure 134 may include a second connection metal pad, and the second connection metal pad may include a nickel-gold pad.

S130: sequentially insulating and stacking the plurality of memory micro-modules over the buffer chip.

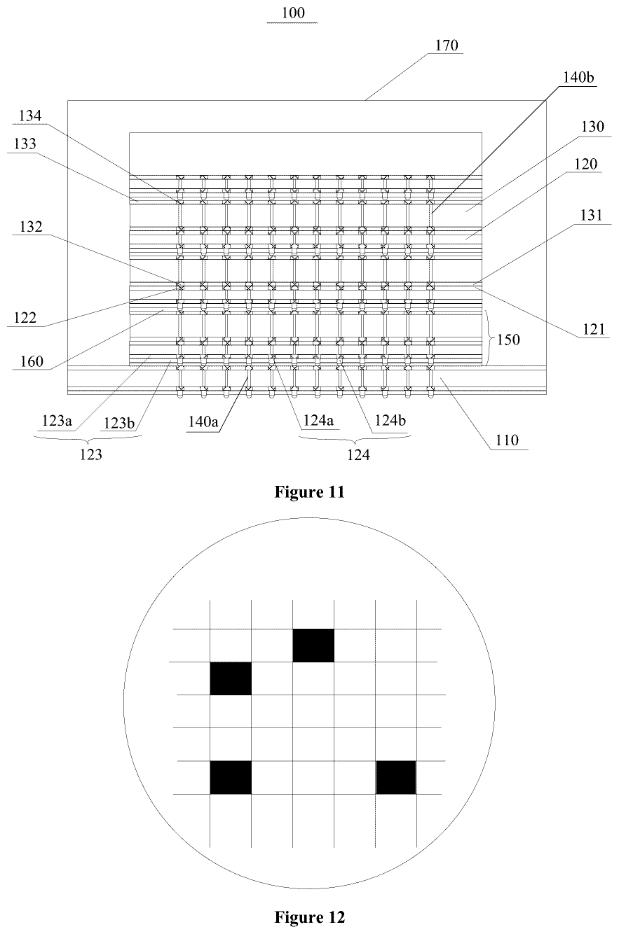

In one embodiment, as shown in FIG. 9, the plurality of memory micro-modules 150 may be fixed on the backside of the buffer chip 110, and then a plurality of independent memory micro-module assemblies may be formed by cutting. Each independent memory micro-module assembly may include the bottom buffer chip 110 and the memory micro-module 150 disposed over the buffer chip 110. As shown in FIG. 10, the plurality of memory micro-modules 150 may be insulated from each other and stacked over the independent memory micro-module assembly by the same process. In other words, the plurality of memory micro-modules 150 may be insulated and sequentially stacked over the buffer chip 110.

As shown in FIG. 9, the passivation layer and the metal pad may be disposed over the backside of the buffer chip 110, and the passivation layer, the metal pad, the dielectric layer and the plurality of bumps may be sequentially disposed over the front side of the buffer chip 110.

In one embodiment, as shown in FIG. 8, a non-conductive adhesive film 160 may be disposed between two adjacent memory micro-modules 150.

In one embodiment, as shown in FIG. 8, when the first bump is disposed over the first memory chip, disposing the non-conductive adhesive film between the two adjacent memory micro-modules may include disposing the non-conductive adhesive film on a side of the first bump away from the first memory chip.

In one embodiment, as shown in FIG. 8, when the first bump 124b is disposed on the first memory chip 120, the non-conductive adhesive film 160 may be disposed between two adjacent memory micro-modules 150. The non-conductive adhesive film 160 may be disposed on the side of the first bump 124a away from the first memory chip 120.

S140: forming a plastic encapsulation layer, where the plastic encapsulation layer may wrap the plurality of memory micro-modules and the buffer chip.

In one embodiment, as shown in FIG. 11, the plurality of memory micro-modules 150 and the buffer chip 110 may be plastic-encapsulated with a plastic encapsulation compound to form the plastic-encapsulation layer 170. The plastic encapsulation method may include vacuum lamination of film layers or traditional plastic encapsulation process, which may not be specifically limited by the present disclosure. After performing the plastic encapsulation process, a cutting process may be performed to form the final independent packaging structure of the multi-layer stacked high-bandwidth memory.

In one embodiment, as shown in FIG. 11, in each group of memory chips, the first memory chip 120 may be disposed close to the buffer chip 110, and the second memory chip 130 may be disposed away from the buffer chip 110. The thickness of the first memory chip 120 may be smaller than the thickness of the second memory chip 130. Further, the thickness of the first memory chip 120 may be in a range approximately between 10 μm-20 μm, and the thickness of the second memory chip 130 may be in a range approximately between 40 μm-50 μm. The backside of the first memory chip 120 may be thinned to the limit, in other words, may be thinned to merely keep the circuit layer.

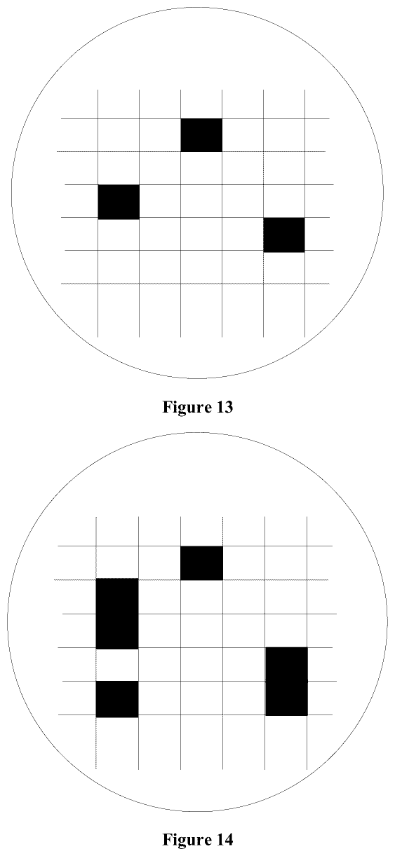

The wafer-level mixed-bonding of the first memory chip and the second memory chip may utilize the production efficiency of the wafer-level mixed-bonding, and at the same time, may reduce the problem of yield loss during multi-layer wafer-level mixed-bonding. As shown in FIG. 12 and FIG. 13, the locations of defective chips of the two wafers in the wafer may be different. As shown in FIG. 14, when the two wafers are stacked on each other, additional loss may be generated. In view of this, the greater the number of layers stacked at the wafer level, the greater the yield loss. The two-layer stacking may preferably select similar wafers, to minimize such yield loss. In one embodiment, to minimize the yield loss during the wafer-level stacking process, the first memory chip 120 and the second memory chip 130 may be of the same type.

The first memory chip and the second memory chip may be electrically connected by wafer-level mixed-bonding, which may achieve a substantially small spacing (less than 10 μm). At the same time, as a memory micro-module, the backside of the first memory chip may be thinned to the limit. Compared with the same through-silicon via chip of the current conventional high-bandwidth memory, a thickness of such a two-chip combination may be greatly reduced, the quantity and height of bumps may also be reduced, the number of chip layers may be greatly increased, and the capacity may be increased.

In the packaging method of the multi-layer stacked high-bandwidth memory of the present disclosure, the two-chip electrical connection may be achieved by using the wafer-level mixed-bonding, to form the memory micro-module. Therefore, the bonding height may be reduced, the number of chip layers may be greatly increased, the capacity may be increased, and super multi-layer chip stacking may be achieved. At the same time, production efficiency may be improved, and the yield loss of wafer-level stacking may be minimized.

The present disclosure also provides a packaging structure of a multi-layer stacked high-bandwidth memory. As shown in FIG. 11, the packaging structure 100 may include a buffer chip 110. The buffer chip 110 may be provided with a plurality of first conductive vias 140a. The packaging structure 100 may also include a plurality of memory micro-modules 150. The plurality of memory micro-modules 150 may be insulated and stacked over the buffer chip 110. Each memory micro-module 150 may include a first memory chip 120 and a second memory chip 130. Both the first memory chip and the second memory chip may be provided with a plurality of second conductive vias 140b corresponding to and electrically connected to the plurality of first conductive vias 140a. Each first memory chip 120 may be connected to the corresponding second memory chip 130 by mixed-bonding through a mixed-bonding structure. A non-conductive adhesive film 160 may be disposed between two adjacent memory micro-modules 150. In addition, the packaging structure 100 may include a plastic encapsulation layer 170. The plastic encapsulation layer 170 may wrap the plurality of memory micro-modules 150 and the buffer chip 110.

In one embodiment, as shown in FIG. 11, the mixed-bonding structure may include a first passivation layer 121 and a first metal pad 122 disposed on the surface of the first memory chip 120 facing towards the second memory chip 130, and a second passivation layer 131 and a second metal pad 132 disposed on the surface of the second memory chip 130 facing towards the first memory chip 120. In one embodiment, both the first passivation layer 121 and the second passivation layer 131 may include a silicon dioxide passivation layer, and both the first metal pad 122 and the second metal pad 132 may include a copper pad.

The first passivation layer 121 on the first memory chip 120 may be bonded to the corresponding second passivation layer 131 on the second memory chip 130, and the first metal pad 122 on the first memory chip 120 may be bonded to the corresponding second metal pad 132 on the second memory chip 130.

In one embodiment, as shown in FIG. 11, a first insulating layer 123 may be disposed on the surface of the first memory chip 120 facing away from the second memory chip 130. The first insulating layer 123 may be provided with a plurality of first openings (not illustrated in the Figure). A first conductive connection structure 124 may be formed in a first opening of the plurality of first openings, and the first conductive connection structure 124 may be electrically connected to the second conductive via 140b in the first memory chip 120.

In one embodiment, as shown in FIG. 11, the first insulating layer 123 may include a first passivation sublayer 123a and a dielectric layer 123b disposed over the first passivation sublayer 123a. The first passivation sublayer 123a may include a silicon dioxide passivation layer, and the dielectric layer 123b may be made of a material including polyimide (PI), polybenzoxazole (PBO), etc. In one embodiment, the dielectric layer 123b may be made of polyimide (PI).

The first conductive connection structure 124 may include a first connection metal pad 124a and a plurality of first bumps 124b disposed over the first connection metal pad 124a. In one embodiment, the first connection metal pad 124a may include a nickel-gold pad, and the first bump 124b may include a copper-tin bump.

In one embodiment, as shown in FIG. 11, a second insulating layer 133 may be disposed on the surface of the second memory chip 130 facing away from the first memory chip 120. In one embodiment, the second insulating layer 133 may include a second passivation sublayer, and the second passivation sublayer may include a silicon dioxide passivation layer.

The second insulating layer 133 may be provided with a plurality of second openings (not illustrated in the Figure). A second conductive connection structure 134 may be disposed in a second opening of the plurality of second openings. The second conductive connection structure 134 may be electrically connected to the second conductive via 140b in the second memory chip 130. In one embodiment, the second conductive connection structure 134 may include a second connection metal pad, and the second connection metal pad may include a nickel-gold pad.

In one embodiment, as shown in FIG. 11, the first memory chip 120 may be disposed close to the buffer chip 110, and the second memory chip 130 may be disposed away from the buffer chip 110. The thickness of the first memory chip 120 may be smaller than the thickness of the second memory chip 130. Further, the thickness of the first memory chip 120 may be in a range approximately between 10 μm-20 μm, and the thickness of the second memory chip 130 may be in a range approximately between 40 μm-50 μm. The backside of the first memory chip 120 may be thinned to the limit, in other words, may be thinned to merely keep the circuit layer.

In the packaging structure of the multi-layer stacked high-bandwidth memory of the present disclosure, the first memory chip and the second memory chip may form the memory micro-module. The plurality of memory micro-modules may be insulated and stacked over the buffer chip. The number of chip layers in the packaging structure may be greatly increased, the capacity may be increased, and the packaging height may be minimized.

In the packaging method and packaging structure of the multi-layer stacked high-bandwidth memory of the present disclosure, the first memory chip and the second memory chip may be mixed-bonded to form the plurality of memory micro-modules. The plurality of memory micro-modules may be insulated and sequentially stacked over the buffer chip, and the two chips may form the memory micro-module by mixed-bonding. Therefore, super-multi-layer chip stacking may be achieved, production efficiency may be improved, the bonding height may be reduced, the number of chip layers may be greatly increased, and the capacity may be increased. In the package structure, the number of chip layers may be greatly increased, the capacity may be increased, and the packaging height may be reduced to the greatest extent.

### Embodiment 2

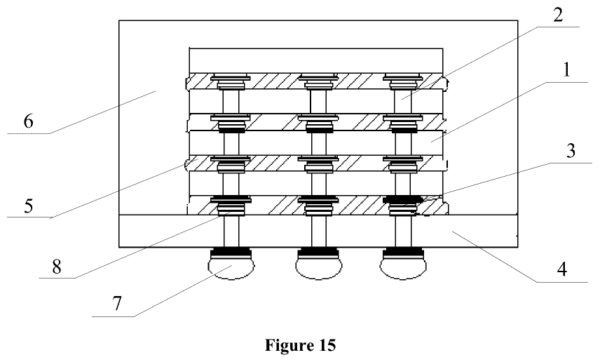

With the development of cloud computing and mobile interconnection, the demand for servers such as data centers has surged. High-end servers require high capacity, large bandwidth and low power consumption for storage devices. In response to such demand, companies have successively launched multi-layer stacked memory packaging products based on three-dimensional stacking technology. As shown in FIG. 15, the packaging stacked structure of the multi-layer stacked memory uses through-silicon vias 2 to vertically interconnect a plurality of memory chips 1. The plurality of memory chips 1 are soldered together through bumps 3, and the memory chips 1 are stacked over a substrate 4. A non-conductive glue 5 is disposed between the chips, the entire memory chip structure is protected by a plastic encapsulation layer 6, and the ultimately packaged structure is connected to external by solder balls 7. Because the through-silicon vias 2 have advantages of high density and short vertical-interconnection distance, data transfer speed is greatly improved.

At present, the multi-layer chips of the multi-layer stacked memory are stacked by a thermal compression bond (TCB) process. Through rapid heating, a bump 3 is connected to a pad 8 on the back of the chip, and the pad on the back of the chip is connected to the through-silicon via 2 of the chip. The bump is mainly made of a copper-tin structure, while the pad on the back of the chip is mainly made of a nickel-gold structure. The final stacked structure is protected by a plastic encapsulation layer 6.

In the case of using the copper-tin bump, due to the deformability of tin during reflow, to prevent short circuit between bumps, the spacing between bumps and the height of tin need to be strictly controlled. At present, the spacing is greater than 40 μm. When the spacing is reduced to less than 25 μm, due to the too small amount of tin, the tin will be fully converted into intermetallic compound under thermal load conditions, leading to reliability failure.

To increase storage capacity and data throughput speed, the number of stacked layers of the chip and the number of pins need to increase. However, in the current micro-bump structure, due to the limitations of spacing and height of the bump, there is limited room for continuous improvement.

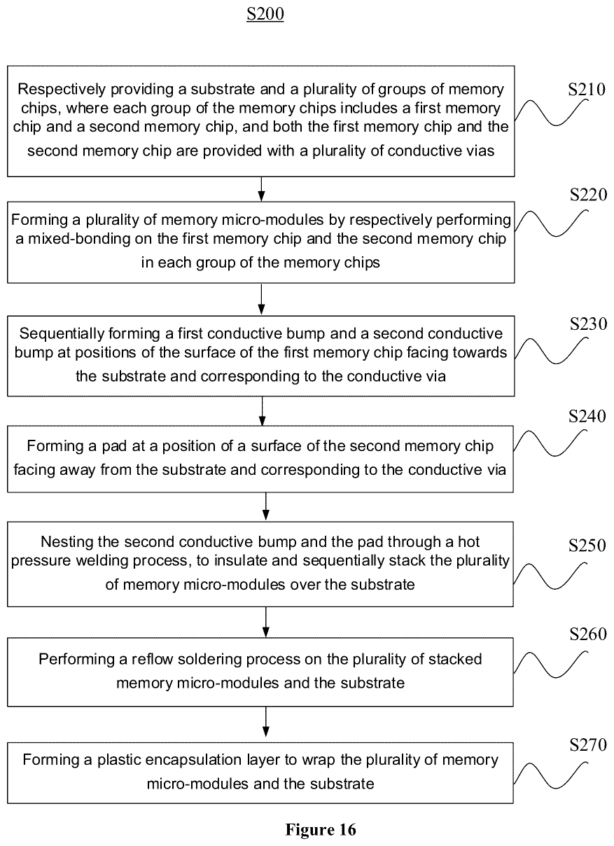

The present disclosure provides a packaging method of a multi-layer stacked high-bandwidth memory. FIG. 16 illustrates a schematic flowchart of the packaging method. Referring to FIG. 2, the packaging method S200 may include following.

S210: respectively providing a substrate and a plurality of groups of memory chips, where each group of the memory chips may include a first memory chip and a second memory chip. Both the first memory chip and the second memory chip may be provided with a plurality of conductive vias.

In one embodiment, referring to FIG. 26, the substrate 1110 and the plurality of groups of the memory chips may be provided, respectively. Each group of the memory chips may include the first memory chip 120 and the second memory chip 130. Both the first memory chip 120 and the second memory chip 130 may be provided with the plurality of conductive vias 140. In other words, the first memory chip 120 may be electrically connected to the second memory chip 130 through the plurality of conductive vias 140. Further, the plurality of conductive vias 140 may include through-silicon vias. The vertical electrical interconnection of through-silicon vias may be realized using through-silicon via technology, which may reduce the packaging height. In one embodiment, the first memory chip 120 and the second memory chip 130 may include a dynamic random access memory chip, or may include any other memory chip, which may not be limited by the present disclosure.

S220: forming a plurality of memory micro-modules by respectively performing a mixed-bonding on the first memory chip and the second memory chip in each group of the memory chips.

In one embodiment, the first memory chip 120 and the second memory chip 130 in each group of the memory chips may be mixed-bonded to form the plurality of memory micro-modules 150.

In one embodiment, referring to FIG. 17, a first passivation layer 121 and a first metal pad 122 may be disposed on a surface of the first memory chip 120 facing towards the second memory chip 130, and a second passivation layer 131 and a second metal pad 132 may be disposed on a surface of the second memory chip 130 facing towards the first memory chip 120. A chemical mechanical polishing process may be performed on the surface of the first memory chip 120 with the first passivation layer 121 and the first metal pad 122, and similarly, a chemical mechanical polishing process may be performed on the surface of the second memory chip 130 with the second passivation layer 131 and the second metal pad 132.

Forming the plurality of memory micro-modules 150 shown in FIG. 24 by respectively performing the mixed-bonding on the first memory chip 120 and the second memory chip 130 in each group of the memory chips may include following.

First, as shown in FIG. 17, the first passivation layer 121 on the first memory chip 120 may be bonded to the second passivation layer 131 on the corresponding second memory chip 130. Both the first passivation layer 121 and the second passivation layer 131 may include a silicon dioxide passivation layer, or a silicon nitride layer. The circuit layers of the first memory chip 120 and the second memory chip 130 may be stacked on each other, such that the first passivation layer 121 and the second passivation layer 131, in other words, the silicon dioxide passivation layers may be bonded. The materials of the first passivation layer 121 and the second passivation layer 131 may not be limited by the present disclosure.

Next, as shown in FIG. 17, the first metal pad 122 on the first memory chip 120 may be bonded to the corresponding second metal pad 132 on the second memory chip 130. In one embodiment, both the first metal pad 122 and the second metal pad 132 may include copper pad. After the first passivation layer 121 and the second passivation layer 131 are bonded, a high temperature pressing may be performed at a temperature greater than 200° C., such that the first metal pad 122 and the second metal pad 132 may be bonded due to thermal expansion of copper. The materials of the first metal pad 122 and the second metal pad 132 may not be limited by the present disclosure.

In one embodiment, as shown in FIG. 24, in each group of memory micro-modules, the first memory chip 120 may be disposed close to the substrate 1110, and the second memory chip 130 may be disposed away from the substrate 1110. The thickness of the first memory chip 120 may be smaller than the thickness of the second memory chip 130. Further, the thickness of the first memory chip 120 may be in a range approximately between 10 μm-20 μm, and the thickness of the second memory chip 130 may be in a range approximately between 40 μm-50 μm. The backside of the first memory chip 120 may be thinned to the limit, in other words, may be thinned to merely keep the circuit layer.

S230: sequentially forming a first conductive bump and a second conductive bump at positions of the surface of the first memory chip facing towards the substrate and corresponding to the conductive via.

It should be noted that when the thickness of the first memory chip 120 is very thin and the plurality of conductive vias 140 are capable of being exposed, the first memory chip 120 may not need to be thinned. Similarly, when the thickness of the second memory chip 130 is very thin and the plurality of conductive vias 140 are capable of being exposed, the second memory chip 130 may not need to be thinned. However, when the thickness of the first memory chip 120 is very thick and the plurality of conductive vias 140 cannot be exposed, and the thickness of the second memory chip 130 is also very thick and the plurality of conductive vias 140 cannot be exposed, the first memory chip 120 and the second memory chip 130 may need to be thinned first. In one embodiment, both the first memory chip 120 and the second memory chip 130 may need to be thinned.

In one embodiment, sequentially forming the first conductive bump and the second conductive bump at positions of the surface of the first memory chip facing towards the substrate and corresponding to the conductive via may include following.

First, a thinning process may be performed on the surface of the first memory chip facing away from the second memory chip, to expose the plurality of conductive vias. In one embodiment, as shown in FIG. 20, a thinning process may be performed on the backside of the first memory chip 120, and then an etching process may be performed to expose the plurality of conductive vias 140.

Next, a third passivation layer and a dielectric layer may be sequentially formed over the surface of the first memory chip away from the substrate. In on embodiment, as shown in FIG. 20, a back opening process may be performed on the surface of the mixed-bonded first memory chip 120 facing towards the substrate 1110, to sequentially form the third passivation layer 1123 and the dielectric layer 1124 by coating. After the third passivation layer 1123 is formed, a connection metal pad 1123a may be formed on the third passivation layer 1123, and the connection metal pad 1123a may correspond to the conductive via 140. It should be noted that the third passivation layer 1123 may be made of a material including silicon dioxide, or silicon nitride, and the dielectric layer 1124 may be made of a material including polyimide (PI), polybenzoxazole (PBO), etc. In one embodiment, the dielectric layer 1124 may be made of polyimide (PI). The coating method may often include a wafer spin coating, which may not be limited by the present disclosure.

Thirdly, a photoresist layer may be formed on the dielectric layer, and a plurality of openings may be formed by patterning the photoresist layer. The plurality of openings may correspond to the plurality of conductive vias, respectively.

In one embodiment, as shown in FIG. 19, the photoresist layer 125 may be coated on the surface of the dielectric layer 1124, and the photoresist layer 125 may be patterned by exposure and development processes to form the plurality of openings (not illustrated in the Figure). The plurality of openings may correspond to the plurality of conductive vias 140 in the first memory chip 120.

Moreover, the first conductive bumps and the second conductive bumps may be sequentially formed in the plurality of openings. In one embodiment, as shown in FIG. 19, the first conductive bumps 126 and the second conductive bumps 127 may be sequentially formed through an electroplating process in the plurality of openings. The first conductive bumps 126 and the second conductive bumps 127 may be electrically connected to the conductive vias 140. In one embodiment, the first conductive bump 126 may be made of a material including a copper metal, and the second conductive bump 127 may be made of a material including a tin metal. The second conductive bump 127 made of the tin metal may keep the packaging cost at a substantially low level.

Ultimately, the photoresist layer may be removed. As shown in FIG. 20, the photoresist layer 125 may be removed by a dry plasma etching process and a wet cleaning process. The method for removing the photoresist may not be limited by the present disclosure.

In one embodiment, the surface of the second conductive bump may be protruded from the surface of the photoresist layer. Before removing the photoresist layer, the method may further include polishing the second conductive bump, such that the surface of the second conductive bump may be coplanar with the surface of the photoresist layer.

In one embodiment, when the first conductive bump 126 and the second conductive bump 127 are sequentially formed in the plurality of openings by an electroplating process, the surface of the second conductive bump 127 may be protruded from the surface of the photoresist layer 125. In view of this, before removing the photoresist layer 125, the surface of the second conductive bump 127 may need to be polished, such that the height of the second conductive bump 127 may be the same as the height of the photoresist layer 125, as shown in FIG. 20. In other words, the second conductive bump 127 may have a columnar structure, which may include a cylindrical structure or a prismatic structure. The original shape of the second conductive bump 127 may have a columnar structure, which may be different from the spherical shape of the conventional conductive bump, such that the lateral width may be reduced under the same volume.

S240: forming a pad at a position of a surface of the second memory chip facing away from the substrate and corresponding to the conductive via.

It should be noted that when the thickness of the second memory chip 130 is very thin and the plurality of conductive vias 140 are capable of being exposed, the second memory chip 130 may not need to be thinned. In one embodiment, as shown in FIG. 22, the second memory chip 130 may need to be thinned first to expose the conductive vias 140 in the second memory chip 130.

In one embodiment, the step S240 may include following steps. First, the surface of the second memory chip facing away from the substrate may be thinned. In one embodiment, as shown in FIG. 22, the surface of the second memory chip 130 facing away from the substrate 1110, in other words, the backside of the second memory chip 130 may be thinned to expose the plurality of conductive vias 140 on the backside of the second memory chip 130. The thinning treatment may include grinding, or any other method, which may not be limited by the present disclosure.

Next, a fourth passivation layer may be formed on the surface of the second memory chip facing away from the substrate, and the fourth passivation layer may be patterned to form a plurality of first openings. The plurality of first openings may correspond to the plurality of conductive vias.

In one embodiment, as shown in FIG. 23, a backside via process may be performed on the backside of the thinned second memory chip 130, to form the fourth passivation layer 1133. A photolithography process may be performed to pattern the fourth passivation layer 1133, to form a plurality of first openings (not shown in the Figure). The plurality of first openings may be arranged corresponding to the plurality of conductive vias 140. In one embodiment, the fourth passivation layer 1133 may be made of silicon dioxide, or may be made of any other material that can play a passivation role, which may not be limited by the present disclosure.

Ultimately, the pads may be formed in the plurality of first openings. In one embodiment, as shown in FIG. 23, the pads 1134 may be formed in the plurality of first openings through an electroplating process. The shape of the pad 1134 may be shown in FIG. 27 and FIG. 28. A cross section of the pad 1134 may often have a circular shape or a square shape. In one embodiment, the pad 1134 may include a copper pad, and the pad 1134 may have a cylindrical structure. The material of the pad 1134 may be selected according to practical applications, which may not be limited by the present disclosure.

S250: nesting the second conductive bump and the pad through a thermal compression bonding process, to insulate and sequentially stack the plurality of memory micro-modules over the substrate.

In one embodiment, as shown in FIG. 27, the second conductive bump 127 of the first memory chip 120 may be nested with the pad 1134 on the second memory chip 130 through a thermal compression bonding process. Then, as shown in FIG. 24, the plurality of memory micro-modules 150 may be insulated and sequentially stacked over the substrate 1110 by a thermal compression bonding process. When stacking the plurality of memory micro-modules 150 to form a stacked module, the plurality of memory micro-modules 150 may be stacked to form a plurality of stacked modules, therefore it is necessary to first divide the plurality of stacked modules to form independent stacked module of memory micro-modules 150, and then the plurality of independent stacked modules of memory micro-modules 150 may be stacked over the substrate 1110 through a thermal compression bonding process.

Nesting the second conductive bumps and the pads through the thermal compression bonding process may include following. First, a protrusion may be formed over the pad. In one embodiment, as shown in FIG. 27 and FIG. 28, a photoresist layer may be coated on the pad 1134. The pad 1134 may be patterned by photolithography and etching processes, to form a protrusion 1134a in a central region of the pad 1134. The size of the protrusion 1134a may be in a range approximately between 3 μm-5 μm, and the height of the protrusion 1134a may be less than 5 μm. In one embodiment, the protrusion 1134a may have a square prism shape.

Next, the protrusion may be pressed into the second conductive bump through a thermal compression bonding process. In one embodiment, as shown in FIG. 13, the protrusion 1134a may be formed on the pad 1134, and the protrusion 1134a may be pressed into the second conductive bump 127 through a thermal compression bonding process.

In one embodiment, the melting point of the first conductive bump 126 may be greater than the melting point of the second conductive bump 127, and a temperature of the thermal compression bonding process may be lower than the melting point of the second conductive bump 127.

In one embodiment, the temperature of the thermal compression bonding process may be lower than the melting point of the second conductive bump 127. In one embodiment, because the second conductive bump includes a tin bump, the temperature may often be set in a range approximately between 180° C.-210° C., and such temperature may ensure low modulus of the tin bump, and the protrusion 1134a may be embedded in the tin bump. Therefore, the first memory chip 120 and the second memory chip 130 may be fixed, and the shape of the tin bump may be basically kept unchanged.

It should be noted that, as shown in FIG. 24, the thickness of the second memory chip 130 in the topmost memory micro-module 150 may be greater than the thickness of of any other second memory chip 130, which may protect the entire package structure.

S260: performing a reflow soldering process on the plurality of stacked memory micro-modules and the substrate.

In one embodiment, performing the reflow soldering process on the plurality of stacked memory micro-modules and the substrate may include: in an acidic gas environment, performing the reflow soldering process on the plurality of stacked memory micro-modules and the substrate.

In one embodiment, as shown in FIG. 24, the plurality of stacked memory micro-modules 150 and the substrate 1110 may be put into an acid reflow furnace to perform the reflow soldering process. The oxide of the second conductive bump 127 may be fully removed without melting in an acidic gas environment, in other words, the oxide of the tin bump may be removed. Because the second conductive bump 127 and the pad 1134 have been soldered, during the reflow soldering process in the acid reflow oven, the second conductive bump 127, i.e., the tin bump, may have a substantially small deformation and may not be shorten. During the whole reflow soldering process, the second conductive bump 127 may basically keep the columnar shape unchanged under the action of the upper and lower surface tension, such that the spacing between the tin bumps may be reduced, and the connection with the center-to-center distance of less than 20 μm may be realized.

It should be noted that the acid gas may include carbon dioxide, chlorine, hydrogen sulfide, hydrogen chloride, sulfur dioxide, etc., which may not be specifically limited by the present disclosure.

S270: forming a plastic encapsulation layer to wrap the plurality of memory micro-modules and the substrate.

In one embodiment, as shown in FIG. 25, the plurality of memory micro-modules 150 and the substrate 1110 may be plastic-sealed with a plastic sealing compound to form a plastic encapsulation layer 1160. The plastic encapsulation method may include vacuum lamination of film layers or traditional plastic encapsulation process, which may not be specifically limited by the present disclosure. After performing the plastic encapsulation process, a cutting process may be performed to form the final independent packaging structure of the multi-layer stacked high-bandwidth memory.

In one embodiment, plastic sealing compound may be filled between adjacent memory micro-modules and between the micro-module and the substrate.

In one embodiment, as shown in FIG. 25, when the plurality of memory micro-modules 150 and the substrate 1110 are plastic-encapsulated, the plastic sealing compound may be filled between adjacent memory micro-modules 150 and between the memory micro-module 150 and the substrate 1110. In other words, the plastic sealing compound may wrap the plurality of first conductive bumps 126 and the plurality of second conductive bumps 127 to protect the plurality of first conductive bumps 126 and the plurality of second conductive bumps 127, and to prevent the first conductive bump 126 and the second conductive bump 127 from being short-circuited. Because the price of the plastic sealing compound is lower than the price of the non-conductive glue, the present disclosure may have the advantages of low production cost.

In one embodiment, as shown in FIG. 26, after the plastic encapsulation layer 1160 is formed, a plurality of solder balls 1170 may be formed on the surface of the substrate 1110 away from the memory micro-module 150, and the packaging structure may be connected to the outside world through the plurality of solder balls 1170.

The wafer-level mixed-bonding of the first memory chip and the second memory chip may utilize the production efficiency of the wafer-level mixed-bonding, and at the same time, may reduce the problem of yield loss during multi-layer wafer-level mixed-bonding. As shown in FIG. 12 and FIG. 13, the locations of defective chips of the two wafers in the wafer may be different. As shown in FIG. 14, when the two wafers are stacked on each other, additional loss may be generated. In view of this, the greater the number of layers stacked at the wafer level, the greater the yield loss. The two-layer stacking may preferably select similar wafers, to minimize such yield loss. In one embodiment, to minimize the yield loss during the wafer-level stacking process, the first memory chip 120 and the second memory chip 130 may be of the same type.

The first memory chip and the second memory chip may be electrically connected by wafer-level mixed-bonding, which may achieve a substantially small spacing (less than 10 μm). At the same time, as a memory micro-module, the backside of the first memory chip may be thinned to the limit. Compared with the same through-silicon via chip of the current conventional high-bandwidth memory, a thickness of such a two-chip combination may be greatly reduced, the quantity and height of bumps may also be reduced, the number of chip layers may be greatly increased, and the capacity may be increased.

In the packaging method of the multi-layer stacked high-bandwidth memory of the present disclosure, the two-chip electrical connection may be achieved by using the wafer-level mixed-bonding, to form the memory micro-module. Therefore, the bonding height may be reduced, the number of chip layers may be greatly increased, the capacity may be increased, and super multi-layer chip stacking may be achieved. At the same time, production efficiency may be improved, and the yield loss of wafer-level stacking may be minimized.

The first conductive bump and the second conductive bump may be sequentially formed at the position corresponding to the conductive via on the surface of the first memory chip facing towards the substrate, and the pad may be formed at a position corresponding to the conductive via on the surface of the second memory chip facing away from the substrate. Through the thermal compression bonding process, the second conductive bump and the pad may be nested to sequentially insulate and stack the plurality of memory micro-modules over the substrate. The reflow soldering process may be performed on the plurality of stacked memory micro-modules and the substrate. In the present disclosure, the second conductive bump and the pad may be nested through a two-step soldering process, which may reduce the deformation of the second conductive bump, and thus may reduce the distance between the second conductive bumps, thereby realizing ultra-fine-pitch interconnection.

The present disclosure also provides a packaging structure of a multi-layer stacked high-bandwidth memory. As shown in FIG. 26, the packaging structure 100 may include a substrate 1110, a plurality of memory micro-modules 150, and a plastic encapsulation layer 1160. The plurality of memory micro-modules 150 may be insulated and stacked over the substrate 1110. Each memory micro-module 150 may include a first memory chip 120 and a second memory chip 130. Each first memory chip 120 may be connected to the corresponding second memory chip 130 by mixed-bonding through a mixed-bonding structure. A plurality of conductive vias 140 may be disposed on both the first memory chip 120 and the second memory chip 130.

The first conductive bump 126 and the second conductive bump 127 may be sequentially formed at the position corresponding to the conductive via 140 on the surface of the first memory chip 120 facing towards the substrate 1110, and the pad 1134 may be formed at a position corresponding to the conductive via 140 on the surface of the second memory chip 130 facing away from the substrate 1110. The second conductive bump 127 and the pad 1134 may be nested.

Referring to FIG. 27, in one embodiment, the first conductive bump 126 may include a copper bump, and the second conductive bump 127 may include a tin bump. In one embodiment, referring to FIG. 17, the second conductive bump 127 may have a columnar structure, in other words, the tin bump may have a columnar structure, which may include a cylindrical structure or a prismatic structure. The original shape of the second conductive bump 127 may have a columnar structure, which may be different from the spherical shape of the conventional conductive bump, such that the lateral width may be reduced under the same volume. The pad 1134 may include a copper pad, and the pad 1134 may have a columnar structure.

The plastic encapsulation layer 1160 may wrap the plurality of memory micro-modules 150 and the substrate 1110.

In one embodiment, as shown in FIG. 26, the mixed-bonding structure may include a first passivation layer 121 and a first metal pad 122 disposed on the surface of the first memory chip 120 facing towards the second memory chip 130, and a second passivation layer 131 and a second metal pad 132 disposed on the surface of the second memory chip 130 facing towards the first memory chip 120. In one embodiment, both the first passivation layer 121 and the second passivation layer 131 may include a silicon dioxide passivation layer, and both the first metal pad 122 and the second metal pad 132 may include a copper pad.

The first passivation layer 121 on the first memory chip 120 may be bonded to the corresponding second passivation layer 131 on the second memory chip 130, and the first metal pad 122 on the first memory chip 120 may be bonded to the corresponding second metal pad 132 on the second memory chip 130.

In one embodiment, as shown in FIG. 27, a protrusion 1134a may be formed in a central region of the pad 1134. As shown in FIG. 28, the size of the protrusion 1134a may be in a range approximately between 3 μm-5 μm, and the height of the protrusion 1134a may be less than 5 μm. In one embodiment, the protrusion 1134a may have a square prism shape.

In one embodiment, as shown in FIG. 26, the first memory chip 120 may be disposed close to the substrate 1110, and the second memory chip 130 may be disposed away from the substrate 1110. The thickness of the first memory chip 120 may be smaller than the thickness of the second memory chip 130. Further, the thickness of the first memory chip 120 may be in a range approximately between 10 μm-20 μm, and the thickness of the second memory chip 130 may be in a range approximately between 40 μm-50 μm. The backside of the first memory chip 120 may be thinned to the limit, in other words, may be thinned to merely keep the circuit layer.

In one embodiment, as shown in FIG. 26, when the plurality of memory micro-modules 150 and the substrate 1110 are plastic-encapsulated, the plastic sealing compound may be filled between adjacent memory micro-modules 150 and between the memory micro-module 150 and the substrate 1110. In other words, the plastic sealing compound may wrap the plurality of first conductive bumps 126 and the plurality of second conductive bumps 127 to protect the plurality of first conductive bumps 126 and the plurality of second conductive bumps 127, and to prevent the first conductive bump 126 and the second conductive bump 127 from being short-circuited. Because the price of the plastic sealing compound is lower than the price of the non-conductive glue, the present disclosure may have the advantages of low production cost.

Referring to FIG. 26, a third passivation layer 1123 and a dielectric layer 1124 may be sequentially formed over the surface of the first memory chip 120 facing towards the substrate 1110. The third passivation layer 1123 may be made of a material including silicon dioxide, or silicon nitride, and the dielectric layer 1124 may be made of a material including polyimide (PI), polybenzoxazole (PBO), etc. In one embodiment, the dielectric layer 1124 may be made of polyimide (PI). The coating method may often include a wafer spin coating, which may not be limited by the present disclosure.

Referring to FIG. 26, the packaging structure may also include a plurality of solder balls 1170. The packaging structure may be connected to the outside world through the plurality of solder balls 1170.

In the packaging structure of the multi-layer stacked high-bandwidth memory of the present disclosure, the first memory chip and the second memory chip may form the memory micro-module. The plurality of memory micro-modules may be insulated and stacked over the buffer chip. The number of chip layers in the packaging structure may be greatly increased, the capacity may be increased, and the packaging height may be minimized.

Further, in the disclosed packaging structure of the present disclosure, the second conductive bump on the first memory chip and the pad on the second memory chip may be nested, such connection may reduce the deformation of the second conductive bump, may reduce the spacing between adjacent second conductive bumps, such that the connection with the center-to-center distance of less than 20 μm may be realized.

In the packaging method and packaging structure of the multi-layer stacked high-bandwidth memory of the present disclosure, the first memory chip and the second memory chip may be mixed-bonded to form the plurality of memory micro-modules. The two chips may form the memory micro-module by mixed-bonding. Therefore, super-multi-layer chip stacking may be achieved, production efficiency may be improved, the bonding height may be reduced, the number of chip layers may be greatly increased, and the capacity may be increased. In the package structure, the number of chip layers may be greatly increased, the capacity may be increased, and the packaging height may be reduced to the greatest extent.

The first conductive bump and the second conductive bump may be sequentially formed at the position corresponding to the conductive via on the surface of the first memory chip facing towards the substrate, and the pad may be formed at a position corresponding to the conductive via on the surface of the second memory chip facing away from the substrate. Through the thermal compression bonding process, the second conductive bump and the pad may be nested to sequentially insulate and stack the plurality of memory micro-modules over the substrate. The reflow soldering process may be performed on the plurality of stacked memory micro-modules and the substrate. In the present disclosure, the second conductive bump and the pad may be nested through a two-step soldering process, which may reduce the deformation of the second conductive bump, and thus may reduce the distance between the second conductive bumps, thereby realizing ultra-fine-pitch interconnection.

### Embodiment 3

For enterprise-level applications such as data centers, large-capacity high-speed storage becomes a necessity. In response to such demand, high-bandwidth memory (HBM) came into being. As shown in FIG. 29, the existing HBM uses through-silicon vias 12 to vertically interconnect a plurality of memory chips 11, and exchanges data with external through a buffer chip 10 at the bottom layer. Because the through-silicon vias have advantages of high density and short vertical-interconnection distance, data transfer speed is greatly improved.

At present, the multi-layer chips of the HBM are stacked by a thermal compression bond (TCB) process. Through rapid heating, a micro-bump 14 is connected to a pad 13 on the back of the chip, and the pad on the back of the chip is connected to the through-silicon via 12 of the chip. The micro-bump 14 is mainly made of a copper-tin structure, while the pad 13 on the back of the chip is mainly made of a nickel-gold structure. The final stacked structure is protected by a plastic encapsulation layer 15.

In the case of using the copper-tin micro-bump, due to the deformability of tin during reflow, to prevent short circuit between micro-bumps, the spacing between micro-bumps and the height of tin need to be strictly controlled. At present, the spacing is greater than 40 μm. When the spacing is reduced to less than 25 μm, due to the too small amount of tin, the tin will be fully converted into intermetallic compound under thermal load conditions, leading to reliability failure.

To increase storage capacity and data throughput speed, the number of stacked layers of the chip and the number of pins need to increase. However, in the current micro-bump structure, due to the limitations of spacing and height of the micro-bump, there is limited room for continuous improvement. To solve such problem, a multi-chip stacking technology based on mixed-bonding is currently being developed, but the mixed-bonding requires a high-precision chemical-mechanical polishing process, which is costly, and the mixed-bonding requires high chip surface flatness, and the actual production yield is difficult to control.

The present disclosure provides a packaging method of a multi-layer stacked high-bandwidth memory. FIG. 30 illustrates a schematic flowchart of the packaging method. Referring to FIG. 2, the packaging method S100 may include following.

S310: respectively providing a buffer chip and a plurality of first memory chips, where both the buffer chip and the plurality of first memory chips may be provided with a plurality of conductive vias.

In one embodiment, referring to FIG. 38 and FIG. 39, the buffer chip 110 and the plurality of first memory chips 120 may be provided, respectively. Both the buffer chip 110 and the plurality of first memory chips 120 may be provided with a plurality of conductive vias 2130. Further, the plurality of conductive vias 2130 may include through-silicon vias. The vertical electrical interconnection of through-silicon vias may be realized using through-silicon via technology, which may reduce the packaging height. In one embodiment, the first memory chip 120 may include a dynamic random access memory chip, or may include any other memory chip, which may not be limited by the present disclosure.

S320: sequentially forming a first conductive bump and a second conductive bump at positions of the surface of the first memory chip facing towards the substrate and corresponding to the conductive via.

In one embodiment, sequentially forming the first conductive bump and the second conductive bump at positions of the surface of the first memory chip facing towards the substrate and corresponding to the conductive via may include following.

First, a first passivation layer and a first dielectric layer may be sequentially formed over a surface of the first memory chip facing towards the buffer chip. Referring to FIG. 33, the first passivation layer 2121 and the first dielectric layer 2122 may be sequentially coated on the surface of the first memory chip 120 facing towards the buffer chip, i.e., the frontside of the first memory chip. The first passivation layer 2121 may be made of a material including silicon dioxide, and the first dielectric layer 2122 may be made of a material including polyimide (PI), polybenzoxazole (PBO), etc. In one embodiment, the first dielectric layer 2122 may be made of polyimide (PI). The coating method may often include a wafer spin coating, which may not be limited by the present disclosure.

Next, a photoresist layer may be formed on the first dielectric layer, and a plurality of openings may be formed by patterning the photoresist layer. The plurality of openings may correspond to the plurality of conductive vias, respectively.

In one embodiment, the photoresist layer 2123 may be coated on the surface of the first dielectric layer 2122, and the photoresist layer 2123 may be patterned by exposure and development processes to form the plurality of openings (not illustrated in the Figure). The plurality of openings may correspond to the plurality of conductive vias 2130 in the first memory chip 120, respectively.

Thirdly, the first conductive bumps and the second conductive bumps may be sequentially formed in the plurality of openings. In one embodiment, as shown in FIG. 33, the first conductive bumps 2124 and the second conductive bumps 2125 may be sequentially formed through an electroplating process in the plurality of openings. The first conductive bumps 2124 and the second conductive bumps 2125 may be electrically connected to the conductive vias 2130. In one embodiment, the first conductive bump 2124 may be made of a material including a copper metal, and the second conductive bump 2125 may be made of a material including a tin metal. The second conductive bump 2125 made of the tin metal may keep the packaging cost at a substantially low level.

Ultimately, the photoresist layer may be removed. As shown in FIG. 33, the photoresist layer 2123 may be removed by a dry plasma etching process and a wet cleaning process. The method for removing the photoresist may not be limited by the present disclosure.

In one embodiment, the surface of the second conductive bump may be protruded from the surface of the photoresist layer. Before removing the photoresist layer, the method may further include polishing the second conductive bump, such that the surface of the second conductive bump may be coplanar with the surface of the photoresist layer.

In one embodiment, when the first conductive bump 2124 and the second conductive bump 2125 are sequentially formed in the plurality of openings by an electroplating process, the surface of the second conductive bump 2125 may be protruded from the surface of the photoresist layer 2123. In view of this, before removing the photoresist layer 2123, the surface of the second conductive bump 2125 may need to be polished, such that the height of the second conductive bump 2125 may be the same as the height of the photoresist layer 2123, as shown in FIG. 35. In other words, the second conductive bump 2125 may have a columnar structure, which may include a cylindrical structure or a prismatic structure. The original shape of the second conductive bump 2125 may have a columnar structure, which may be different from the spherical shape of the conventional conductive bump, such that the lateral width may be reduced under the same volume.

S330: forming a first pad at a position of a surface of the first memory chip facing away from the buffer chip and corresponding to the conductive via.

It should be noted that when the thickness of the first memory chip 120 is very thin and the plurality of conductive vias 2130 are capable of being exposed, the first memory chip 120 may not need to be thinned. In one embodiment, as shown in FIG. 36, the first memory chip 120 may need to be thinned first to expose the conductive vias 2130 in the first memory chip 120.

In one embodiment, the step S330 may include following steps. First, the surface of the first memory chip facing away from the buffer chip may be thinned. In one embodiment, as shown in FIG. 36, the surface of the first memory chip 120 facing away from the buffer chip 110, in other words, the backside of the first memory chip 120 may be thinned to expose the plurality of conductive vias 2130 on the backside of the first memory chip 120. The thinning treatment may include grinding, or any other method, which may not be limited by the present disclosure.

Next, a second passivation layer may be formed on the surface of the first memory chip facing away from the buffer chip, and the second passivation layer may be patterned to form a plurality of second openings. The plurality of second openings may correspond to the plurality of conductive vias.

In one embodiment, as shown in FIG. 37, a backside via process may be performed on the backside of the thinned first memory chip 120, to form the second passivation layer 2126. A photolithography process may be performed to pattern the second passivation layer 2126, to form a plurality of second openings (not shown in the Figure). The plurality of second openings may be arranged corresponding to the plurality of conductive vias 2130. In one embodiment, the second passivation layer 2126 may be made of silicon dioxide, or may be made of any other material that can play a passivation role, which may not be limited by the present disclosure.

Ultimately, the first pads may be formed in the plurality of second openings. In one embodiment, as shown in FIG. 37, the first pads 2127 may be formed in the plurality of first openings through an electroplating process. The shape of the first pad 2127 may be shown in FIG. 31 and FIG. 32. A cross section of the first pad 2127 may often have a circular shape or a square shape. In one embodiment, the first pad 2127 may include a copper pad, and the first pad 2127 may have a cylindrical structure. The material of the first pad 2127 may be selected according to practical applications, which may not be limited by the present disclosure.

It should be noted that the topmost chip may be the first memory chip 120 or any other chip. In one embodiment, the topmost chip may include the first memory chip 120. The thickness of the first memory chip 120 on the topmost layer may be greater than the thickness of the first memory chip 120 on any other layer, which may protect the multiple first memory chips 120 on other layers. Therefore, the first memory chip 120 on the topmost layer may not be provided with conductive vias, and the first conductive bump 2124 and the second conductive bump 2125 may merely be disposed on the surface of the topmost first memory chip 120 facing towards the buffer chip 110. The first conductive bump 2124 and the second conductive bump 2125 on the topmost first memory chip 120 may be nested with the first pad 2127 on the first memory chip 120 on the adjacent layer.

S340: nesting the second conductive bump and the first pad on adjacent two first memory chips through a thermal compression bonding process, to insulate and sequentially stack the plurality of first memory chips over the buffer chip.

In one embodiment, as shown in FIG. 31, the second conductive bump 2125 and the first pad 2127 on the adjacent two first memory chips 120 may be nested through a thermal compression bonding process. Then, as shown in FIG. 38, the plurality of first memory chips 120 may be insulated and sequentially stacked over the buffer chip 110 by a thermal compression bonding process. When stacking the plurality of first memory chips 120 to form a stacked module, the plurality of first memory chips 120 may be stacked to form a plurality of stacked modules, therefore it is necessary to first divide the plurality of stacked modules to form independent stacked module of first memory chip 120, and then the plurality of independent stacked modules of the first memory chip 120 may be stacked over the buffer chip 110 through a thermal compression bonding process.

It should be noted that the second conductive bump 2125 and the first pad 2127 on the adjacent two first memory chips 120 may be nested through a thermal compression bonding process, and then the plurality of first memory chips 120 may be insulated and sequentially stacked over the buffer chip.

Nesting the second conductive bump and the first pad on the adjacent two first memory chips through the thermal compression bonding process may include following. First, a protrusion may be formed over the first pad. In one embodiment, a photoresist layer may be coated on the first pad 2127. The first pad 2127 may be patterned by photolithography and etching processes, to form a protrusion 2127a in a central region of the first pad 2127. The size of the protrusion 2127a may be in a range approximately between 3 μm-5 μm, and the height of the protrusion 2127a may be less than 5 μm. In one embodiment, the protrusion 2127a may have a square prism shape.

Next, the protrusion may be pressed into the second conductive bump through a thermal compression bonding process. In one embodiment, as shown in FIG. 31, the protrusion 2127a may be formed on the first pad 2127, and the protrusion 2127a may be pressed into the second conductive bump 2125 on the adjacent two first memory chips 120 through a thermal compression bonding process.

In one embodiment, the melting point of the first conductive bump 2124 may be greater than the melting point of the second conductive bump 2125, and a temperature of the thermal compression bonding process may be lower than the melting point of the second conductive bump 2125.

In one embodiment, the temperature of the thermal compression bonding process may be lower than the melting point of the second conductive bump 2125. In one embodiment, because the second conductive bump includes a tin bump, the temperature may often be set in a range approximately between 180° C.-210° C., and such temperature may ensure low modulus of the tin bump, and the protrusion 2127a may be embedded in the tin bump. Therefore, the adjacent two first memory chips 120 may be fixed, and the shape of the tin bump may be basically kept unchanged.

In one embodiment, as shown in FIG. 38 and FIG. 39, a third passivation layer 2111 and a second dielectric layer 2112 may be formed on the surface of the buffer chip 110 facing away from the first memory chip 120. The third passivation layer 2111 and the second dielectric layer 2112 may be patterned to form a plurality of openings, and a plurality of conductive protrusions 2113 may be formed in the plurality of openings. The plurality of conductive protrusions 2113 may correspond to and be electrically connected to the plurality of conductive vias 2130. The plurality of conductive protrusions 2113 may be electrically connected to the external world.

A fourth passivation layer 2114 and a second pad 2115 may be formed on the surface of the buffer chip 110 facing towards the first memory chip 120. The second pad 2115 may be nested with the second conductive bump 2125 on the first memory chip 120 close to the buffer chip 110. In one embodiment, the second pad 2115 on the buffer chip 110 may be the same pad as the first pad 2127 on the first memory chip 120, and both the first pad and the second pad may include the protrusion 2127a. The second pad 2125 may be different from the first pad 2127, which may not be limited by the present disclosure.

The materials of the third passivation layer 2111 and the fourth passivation layer 21114 may not be limited by the present disclosure, and may include a material that can play a passivation function. The second dielectric layer 2112 may be made of a material including polyimide (PI), polybenzoxazole (PBO), etc. In one embodiment, the second dielectric layer 2112 may be made of polyimide (PI). The coating method may often include a wafer spin coating, which may not be limited by the present disclosure.

S350: performing a reflow soldering process on the plurality of stacked first memory chips and the buffer chip.

In one embodiment, performing the reflow soldering process on the plurality of stacked first memory chips and the buffer chip may include: in an acidic gas environment, performing the reflow soldering process on the plurality of stacked first memory chips and the buffer chip.

In one embodiment, as shown in FIG. 38, the plurality of stacked first memory chips 120 and the buffer chip 110 may be put into an acid reflow furnace to perform the reflow soldering process. The oxide of the second conductive bump 2125 may be fully removed without melting in an acidic gas environment, in other words, the oxide of the tin bump may be removed. Because the second conductive bump 2125 and the first pad 2127 have been soldered, during the reflow soldering process in the acid reflow oven, the second conductive bump 127, i.e., the tin bump, may have a substantially small deformation and may not be shorten. During the whole reflow soldering process, the second conductive bump 2125 may basically keep the columnar shape unchanged under the action of the upper and lower surface tension, such that the spacing between the tin bumps may be reduced, and the connection with the center-to-center distance of less than 20 μm may be realized.

It should be noted that the acid gas may include carbon dioxide, chlorine, hydrogen sulfide, hydrogen chloride, sulfur dioxide, etc., which may not be specifically limited by the present disclosure.

S360: forming a plastic encapsulation layer to wrap the plurality of first memory chips and the buffer chip.

In one embodiment, as shown in FIG. 39, the plurality of first memory chips 120 and the buffer chip 110 may be plastic-sealed with a plastic sealing compound to form a plastic encapsulation layer 2140. Therefore, the package body of the memory chip may be obtained, and the package body may be cut to form a high-bandwidth memory package body. The plastic encapsulation method may include vacuum lamination of film layers or traditional plastic encapsulation process, which may not be specifically limited by the present disclosure. After performing the plastic encapsulation process, a cutting process may be performed to form the final independent packaging structure of the multi-layer stacked high-bandwidth memory.

In one embodiment, when forming the plastic encapsulation layer 2140, the plastic sealing compound may be filled between adjacent first memory chips 120 and between the first memory chip 120 and the buffer chip 110. The plastic sealing compound may wrap the first pads 2127, the second pads 2115, the plurality of first conductive bumps 2124 and the plurality of second conductive bumps 2125. By using the plastic sealing compound instead of the existing non-conductive glue to fill between the buffer chip and the first memory chip, and between the upper and lower adjacent first memory chips, the short circuit between the pad and the second conductive bump may be prevented. Because the price of the plastic sealing compound is lower than the price of the non-conductive glue, the present disclosure may have the advantages of low production cost.

In the packaging method of the multi-layer stacked high-bandwidth memory of the present disclosure, the buffer chip and the plurality of first memory chips may be provided. Both the buffer chip and the plurality of first memory chips may be provided with a plurality of conductive vias. Through the thermal compression bonding process, the second conductive bump and the first pad on the adjacent two first memory chips may be nested, to insulate and sequentially stack the first memory chips over the buffer chip. Through the reflow soldering process, the plurality of stacked first memory chips and the buffer chip may be soldered. In the present disclosure, through the two-step welding process, the second conductive bump and the first pad may be nested, which may reduce the deformation of the second conductive bump, may reduce the spacing between adjacent second conductive bumps, such that the connection with the center-to-center distance of less than 20 μm may be realized.

The present disclosure also provides a packaging structure of a multi-layer stacked high-bandwidth memory. As shown in FIG. 39, the packaging structure 100 of the multi-layer stacked high-bandwidth memory may include a buffer chip 110, a plurality of first memory chips 150, and a plastic encapsulation layer 2140. A plurality of conductive vias 2130 may be disposed on both the plurality of first memory chips 120 and the buffer chip 110. The plurality of conductive vias may include through-silicon vias.

Referring to FIG. 31, the first conductive bump 2124 and the second conductive bump 2125 may be sequentially formed at the position corresponding to the conductive via 2130 on the first surface of the first memory chip 120. In one embodiment, the first conductive bump 2124 may include a copper bump, and the second conductive bump 2125 may include a tin bump. In one embodiment, referring to FIG. 31, the second conductive bump 2125 may have a columnar structure, in other words, the tin bump may have a columnar structure, which may include a cylindrical structure or a prismatic structure. The original shape of the second conductive bump 2125 may have a columnar structure, which may be different from the spherical shape of the conventional conductive bump, such that the lateral width may be reduced under the same volume. The first pad 2127 may be formed at a position corresponding to the conductive via 2130 on the second surface of the first memory chip 120. The first pad 2127 may include a copper pad, and the first pad 2127 may have a columnar structure.

Referring to FIG. 39, the second conductive bump 2125 and the first pad 2127 on the adjacent two first memory chips 120 may be nested, such that the plurality of first memory chips 120 may be insulated and sequentially stacked over the buffer chip 110.

In should be noted that through the thermal compression bonding process, the second conductive bump 2125 and the first pad 2127 on the adjacent two first memory chips may be nested, to insulate and sequentially stack the first memory chips 120 over the buffer chip 110. Through the reflow soldering process, the plurality of stacked first memory chips 120 and the buffer chip 110 may be soldered. The oxide of the second conductive bump 2125 may be fully removed without melting in an acidic gas environment, in other words, the oxide of the tin bump may be removed. Because the second conductive bump 2125 and the pad 2127 have been soldered, during the reflow soldering process, the second conductive bump 2125, i.e., the tin bump, may have a substantially small deformation and may not be shorten. During the whole reflow soldering process, the second conductive bump 2125 may basically keep the columnar shape unchanged under the action of the upper and lower surface tension, such that the spacing between the tin bumps may be reduced, thereby achieving the connection with the center-to-center distance of less than 20 μm.

Referring to FIG. 39, the plastic encapsulation layer 2140 may warp the plurality of first memory chips 120 and the buffer chip 110. The plastic encapsulation method may include vacuum lamination of film layers or traditional plastic encapsulation process, which may not be specifically limited by the present disclosure. After performing the plastic encapsulation process, a cutting process may be performed to form the final independent packaging structure of the multi-layer stacked high-bandwidth memory.

In one embodiment, referring to FIG. 31, a protrusion 2127a may be formed on a side of the first pad 2127 facing towards the second conductive bump 2125, and a trench 2125a may be formed on a side of the second conductive bump 2125 facing towards the first pad 2127. The protrusion 2127a may be inserted into the trench 2125a. Referring to FIG. 32, the size of the protrusion 2127a may be in a range approximately between 3 μm-5 μm, and the height of the protrusion 2127a may be less than 5 μm. In one embodiment, the protrusion 2127a may have a square prism shape, in other words, the cross-section of the protrusion 2127a may have a square shape.

In the packaging structure of the multi-layer stacked high-bandwidth memory of the present disclosure, the second conductive bump and the first pad of every two adjacent first memory chips may be nested, and the second pad of the buffer chip and the second conductive bump on the first memory chip may be nested. The nested connection between the pads and the second conductive bumps may reduce the deformation of the second conductive bump, may reduce the spacing between adjacent second conductive bumps, such that the connection with the center-to-center distance of less than 20 μm may be realized.

### Embodiment 4

With the development of cloud computing and mobile interconnection, the demand for servers such as data centers has surged. High-end servers require high capacity, large bandwidth and low power consumption for storage devices. In response to such demand, companies have successively launched multi-layer stacked memory packaging products based on three-dimensional stacking technology. As shown in FIG. 40, the packaging stacked structure of the multi-layer stacked memory uses through-silicon vias 2 to vertically interconnect a plurality of memory chips 1. The plurality of memory chips 1 are soldered together through bumps 3, and the memory chips 1 are stacked over a substrate 4. A non-conductive glue 5 is disposed between the chips, the entire memory chip structure is protected by a plastic encapsulation layer 6, and the ultimately packaged structure is connected to external by solder balls 7. Because the through-silicon vias 2 have advantages of high density and short vertical-interconnection distance, data transfer speed is greatly improved.

At present, the multi-layer chips of the multi-layer stacked memory are stacked by a thermal compression bond (TCB) process. Through rapid heating, a bump 3 is connected to a pad 8 on the back of the chip, and the pad on the back of the chip is connected to the through-silicon via 2 of the chip. The bump is mainly made of a copper-tin structure, while the pad on the back of the chip is mainly made of a nickel-gold structure. The final stacked structure is protected by a plastic encapsulation layer 6.

In the case of using the copper-tin bump, due to the deformability of tin during reflow, to prevent short circuit between bumps, the spacing between bumps and the height of tin need to be strictly controlled. At present, the spacing is greater than 40 μm. When the spacing is reduced to less than 25 μm, due to the too small amount of tin, the tin will be fully converted into intermetallic compound under thermal load conditions, leading to reliability failure.

To increase storage capacity and data throughput speed, the number of stacked layers of the chip and the number of pins need to increase. However, in the current micro-bump structure, due to the limitations of spacing and height of the bump, there is limited room for continuous improvement. To solve such problem, a multi-chip stacking technology based on mixed-bonding is currently being developed, but the mixed-bonding requires a high-precision chemical-mechanical polishing process, which is costly, and the mixed-bonding requires high chip surface flatness, and the actual production yield is difficult to control.

The present disclosure provides a packaging structure of a multi-layer stacked high-bandwidth memory. As shown in FIG. 41, the packaging structure 100 may include a substrate 3110, a plurality of first memory chips 120, and a plastic encapsulation layer 3140. The substrate 3110 may be provided with a plurality of first conductive vias 3111. The first memory chip may be provided with a plurality of second conductive vias 3130. Both the first conductive vias 3111 and the second conductive vias 3130 may include through-silicon vias. The vertical electrical interconnection of through-silicon vias may be realized using through-silicon via technology, which may reduce the packaging height. In one embodiment, the size of the cross-section of the plurality of first conductive vias 3111 on the buffer chip 110 may be greater than the size of the cross-section of the plurality of second conductive vias 3130 on the first memory chip. In one embodiment, the first memory chip 120 may include a dynamic random access memory chip, or may include any other memory chip, which may not be limited by the present disclosure.

The first conductive bump 3124 and the second conductive bump 3125 may be sequentially formed at the position corresponding to the second conductive vias 3130 on the surface of the first memory chip 120 facing towards the substrate 3110, and the first pad 3127 may be formed at a position corresponding to the second conductive vias 3130 on the surface of the first memory chip 120 facing away from the substrate 3110. In one embodiment, the first conductive bump 3124 may include a copper bump, and the second conductive bump 3125 may include a tin bump. The second conductive bump 3125 including the tin bump may reduce the packaging cost.

In one embodiment, referring to FIG. 42, the second conductive bump 3125 may have a columnar structure, in other words, the tin bump may have a columnar structure, which may include a cylindrical structure or a prismatic structure. The original shape of the second conductive bump 3125 may have a columnar structure, which may be different from the spherical shape of the conventional conductive bump, such that the lateral width may be reduced under the same volume. Therefore, when being nested with the first pad 3127, the second conductive bump 3125 may basically keep the columnar shape unchanged, such that the spacing between the second conductive bumps 3125 may be reduced, and the connection with the center-to-center distance of less than 20 μm may be realized.

The second conductive bump 3125 and the first pad 3127 on the adjacent two first memory chips 120 may be nested, such that the plurality of first memory chips 120 may be insulated and sequentially stacked over the substrate 3110.

In should be noted that through the thermal compression bonding process, the second conductive bump 3125 and the first pad 3127 on the adjacent two first memory chips 120 may be nested, to insulate and sequentially stack the first memory chips 120 over the substrate 3110. The plurality of stacked first memory chips 120 and the substrate 3110 may be put into an acid reflow furnace to perform the reflow soldering process. The oxide of the second conductive bump 3125 may be fully removed without melting in an acidic gas environment, in other words, the oxide of the tin bump may be removed. Because the second conductive bump 3125 and the first pad 3127 have been soldered, during the reflow soldering process, the second conductive bump 3125, i.e., the tin bump, may have a substantially small deformation and may not be shorten. During the whole reflow soldering process, the second conductive bump 3125 may basically keep the columnar shape unchanged under the action of the upper and lower surface tension, such that the spacing between the tin bumps may be reduced, thereby achieving the connection with the center-to-center distance of less than 20 μm.

The plastic encapsulation layer 3140 may warp the plurality of first memory chips 120 and the substrate 3110. The plastic encapsulation method may include vacuum lamination of film layers or traditional plastic encapsulation process, which may not be specifically limited by the present disclosure. After performing the plastic encapsulation process, a cutting process may be performed to form the final independent packaging structure of the multi-layer stacked high-bandwidth memory.

In one embodiment, referring to FIG. 42 and FIG. 43, a protrusion 3127a may be formed on a side of the first pad 3127 facing towards the second conductive bump 3125, and a trench 3125a may be formed on a side of the second conductive bump 3125 facing towards the first pad 3127. The protrusion 3127a may be inserted into the trench 3125a. The protrusion 3127a of the second conductive bump 3125 and the trench 3125a of the first pad 3127 may be nested. Referring to FIG. 43, the size of the protrusion 3127a may be in a range approximately between 3 μm-5 μm, and the height of the protrusion 3127a may be less than 5 μm. In one embodiment, the protrusion 3127a may have a square prism shape, in other words, the cross-section of the protrusion 3127a may have a square shape. The cross-section of the protrusion 3127a may include any other shape, which may be determined according to practical applications.

In one embodiment, referring to FIG. 41, the first passivation layer 3121 and the first dielectric layer 3122 may be sequentially formed over a surface of the first memory chip 120 facing towards the substrate 3110. The first conductive bump 3124 may be disposed over the first passivation layer 3121 and the first dielectric layer 3122. The second passivation layer 3126 may be disposed on the side of the first memory chip 120 facing away from the substrate 3110. The first pad 3127 may be disposed over the second passivation layer 3126.

In one embodiment, the first passivation layer 3121 and the first dielectric layer 3122 may be sequentially disposed on the surface of the first memory chip 120 facing towards the substrate 3110, and then the first passivation layer 3121 and the first dielectric layer 3122 may be patterned to form a plurality of openings. The first conductive bump 3124 may be disposed in the opening, and the second conductive bump 3125 may be disposed over the first conductive bump 3124. Similarly, the second passivation layer 3126 may be patterned to form a plurality of openings, and the first pads 3127 may be disposed in the plurality of openings.

It should be noted that the materials of the first passivation layer 3121 and the second passivation layer 3126 may include silicon dioxide, and may include a material that can play a passivation function, which may not be limited by the present disclosure. In one embodiment, the first pad 3127 may be made of metallic copper, and the first conductive bump 3124 may be made of metallic copper.

In one embodiment, referring to FIG. 41, a second pad 3112 may be disposed on the surface of the substrate 3110 facing towards the first memory chip 120, and the second pad 3112 may be nested with the second conductive bump 3127 on the first memory chip 120 close to the substrate 3110. In one embodiment, the second pad 3112 and the first pad 3127 may have a same structure. Similarly, the second pad may be provided with a protrusion, and the protrusion may be nested with the second conductive bump 3127. The substrate 3110 and the first memory chip 120 may be connected by nesting the second pad 3112 and the second conductive bump 3127. The nested connection between the pad and the second conductive bump may reduce the deformation of the second conductive bump, may reduce the spacing between adjacent second conductive bumps 3127, in other words, the spacing between the substrate 3110 and the first memory chip 120 may be reduced, such that the connection with the center-to-center distance of less than 20 μm may be realized.

It should be noted that the topmost chip may be the first memory chip 120 or any other chip. In one embodiment, the topmost chip may include the first memory chip 120. The thickness of the first memory chip 120 on the topmost layer may be greater than the thickness of the first memory chip 120 on any other layer, which may protect the multiple first memory chips 120 on other layers. Therefore, the first memory chip 120 on the topmost layer may not be provided with conductive vias, and the first conductive bump 3124 and the second conductive bump 3125 may merely be disposed on the surface of the topmost first memory chip 120 facing towards the substrate 3110. The first conductive bump 3124 and the second conductive bump 3125 on the topmost first memory chip 120 may be nested with the first pad 3127 on the first memory chip 120 on the adjacent layer.

In one embodiment, as shown in FIG. 41, a plastic sealing compound may be filled between adjacent first memory chips 120 and between the first memory chip 120 and the substrate 3110. The plastic sealing compound may wrap the first pads 3127, the second pads 3112, the plurality of first conductive bumps 3124, and the plurality of second conductive bumps 3125. By using the plastic sealing compound instead of the existing non-conductive glue to fill between the substrate and the first memory chip, and between the upper and lower adjacent first memory chips, the short circuit between the pad and the second conductive bump may be prevented. Because the price of the plastic sealing compound is lower than the price of the non-conductive glue, the present disclosure may have the advantages of low production cost.

In one embodiment, referring to FIG. 41, the packaging structure 100 may also include a plurality of solder balls 3150. The plurality of solder balls 3150 may be formed on the surface of the substrate 3110 away from the first memory chip 120, and the solder ball 3150 may be electrically connected with the first conductive via 3111. The packaging structure may be connected to the outside world through the plurality of solder balls 3150.

The present disclosure also provides a packaging method of a multi-layer stacked high-bandwidth memory. FIG. 44 illustrates a schematic flowchart of the packaging method. Referring to FIG. 44, the packaging method S100 may include following.

S410: respectively providing a substrate and a plurality of first memory chips, where the substrate may be provided with a plurality of first conductive vias, and the plurality of first memory chips may be provided with a plurality of second conductive vias electrically connected with the plurality of first conductive vias.

In one embodiment, referring to FIG. 50 and FIG. 52, the substrate 3110 and the plurality of first memory chips 120 may be provided, respectively. The substrate 3110 may be provided with a plurality of first conductive vias 3111, and the plurality of first memory chips 120 may be provided with a plurality of second conductive vias 3130. Further, the first conductive vias 3111 and the second conductive vias 3130 may include through-silicon vias. The vertical electrical interconnection of through-silicon vias may be realized using through-silicon via technology, which may reduce the packaging height. In one embodiment, the size of the cross-section of the plurality of first conductive vias 3111 on the substrate 3110 may be greater than the size of the cross-section of the plurality of second conductive vias 3130 on the first memory chip 120. In one embodiment, the first memory chip 120 may include a dynamic random access memory chip, or may include any other memory chip, which may not be limited by the present disclosure.

S420: sequentially forming a first conductive bump and a second conductive bump at positions of the surface of the first memory chip facing towards the substrate and corresponding to the second conductive vias.

In one embodiment, the step S420 may include following. First, a first passivation layer and a first dielectric layer may be sequentially formed over a surface of the first memory chip facing towards the substrate. Referring to FIG. 45, the first passivation layer 3121 and the first dielectric layer 3122 may be sequentially formed over a surface of the first memory chip 120 facing towards the substrate 3110, i.e., the frontside of the first memory chip 120. The first passivation layer 3121 may be made of a material including silicon dioxide, and the first dielectric layer 3122 may be made of a material including polyimide (PI), polybenzoxazole (PBO), etc. In one embodiment, the first dielectric layer 3122 may be made of polyimide (PI). The coating method may often include a wafer spin coating, which may not be limited by the present disclosure.

Next, a photoresist layer may be formed on the first dielectric layer, and a plurality of openings may be formed by patterning the photoresist layer. The plurality of openings may correspond to the plurality of conductive vias, respectively.

In one embodiment, the photoresist layer 3123 may be coated on the surface of the first dielectric layer 3122, and the photoresist layer 3123 may be patterned by exposure and development processes to form the plurality of first openings (not illustrated in the Figure). The plurality of first openings may correspond to the plurality of second conductive vias 3130 in the first memory chip 120, respectively.

Thirdly, the first conductive bumps and the second conductive bumps may be sequentially formed in the plurality of first openings. In one embodiment, as shown in FIG. 45, the first conductive bumps 3124 and the second conductive bumps 3125 may be sequentially formed through an electroplating process in the plurality of first openings. The first conductive bumps 3124 and the second conductive bumps 3125 may be electrically connected to the second conductive vias 3130. In one embodiment, the first conductive bump 3124 may be made of a material including a copper metal, and the second conductive bump 3125 may be made of a material including a tin metal. The second conductive bump 3125 made of the tin metal may keep the packaging cost at a substantially low level.

Ultimately, the photoresist layer may be removed. In one embodiment, the surface of the second conductive bump may be protruded from the surface of the photoresist layer. Before removing the photoresist layer, the method may further include polishing the second conductive bump, such that the surface of the second conductive bump may be coplanar with the surface of the photoresist layer.

In one embodiment, when the first conductive bump 3124 and the second conductive bump 3125 are sequentially formed in the plurality of openings by an electroplating process, the surface of the second conductive bump 3125 may be protruded from the surface of the photoresist layer 3123. In view of this, before removing the photoresist layer 3123, the surface of the second conductive bump 3125 may need to be polished, such that the height of the second conductive bump 3125 may be the same as the height of the photoresist layer 3123, as shown in FIG. 46. In other words, the second conductive bump 3125 may have a columnar structure, which may include a cylindrical structure or a prismatic structure. The original shape of the second conductive bump 3125 may have a columnar structure, which may be different from the spherical shape of the conventional conductive bump, such that the lateral width may be reduced under the same volume. Referring to FIG. 46, the surface of the second conductive bump 3125 may be polished, such that after the height of the second conductive bump 3125 is the same as the height of the photoresist layer 3123, the photoresist layer 3123 may be removed.

S430: forming a first pad at a position of a surface of the first memory chip facing away from the substrate and corresponding to the second conductive via.

It should be noted that when the thickness of the first memory chip 120 is very thin and the plurality of second conductive vias 3130 are capable of being exposed, the first memory chip 120 may not need to be thinned. In one embodiment, as shown in FIG. 46, the first memory chip 120 may need to be thinned first to expose the second conductive vias 3130 in the first memory chip 120.

In one embodiment, the step S430 may include following steps. First, the surface of the first memory chip facing away from the substrate may be thinned. In one embodiment, as shown in FIG. 48, the surface of the first memory chip 120 facing away from the substrate 3110, in other words, the backside of the first memory chip 120 may be thinned to expose the plurality of second conductive vias 3130 on the backside of the first memory chip 120. The thinning treatment may include grinding, or any other method, which may not be limited by the present disclosure.

Next, a second passivation layer may be formed on the surface of the first memory chip facing away from the substrate, and the second passivation layer may be patterned to form a plurality of second openings. The plurality of second openings may correspond to the plurality of conductive vias.

In one embodiment, as shown in FIG. 49, a backside via process may be performed on the backside of the thinned first memory chip 120, to form the second passivation layer 3126. A photolithography process may be performed to pattern the second passivation layer 3126, to form a plurality of second openings (not shown in the Figure). The plurality of second openings may be arranged corresponding to the plurality of second conductive vias 3130. In one embodiment, the second passivation layer 3126 may be made of silicon dioxide, or may be made of any other material that can play a passivation role, which may not be limited by the present disclosure.

Ultimately, the first pads may be formed in the plurality of second openings. In one embodiment, as shown in FIG. 49, the first pads 3127 may be formed in the plurality of second openings through an electroplating process. The shape of the first pad 3127 may be shown in FIG. 31 and FIG. 32. A cross section of the first pad 3127 may often have a circular shape or a square shape. In one embodiment, the first pad 3127 may include a copper pad, and the first pad 3127 may have a cylindrical structure. The material of the first pad 3127 may be selected according to practical applications, which may not be limited by the present disclosure.

S440: nesting the second conductive bump and the first pad on adjacent two first memory chips through a thermal compression bonding process, to insulate and sequentially stack the plurality of first memory chips over the substrate.

In one embodiment, as shown in FIG. 42 and FIG. 50, the second conductive bump 3125 and the first pad 3127 on the adjacent two first memory chips 120 may be nested through a thermal compression bonding process. Then, as shown in FIG. 50, the plurality of first memory chips 120 may be insulated and sequentially stacked over the substrate 3110 by a thermal compression bonding process. When stacking the plurality of first memory chips 120 to form a stacked module, the plurality of first memory chips 120 may be stacked to form a plurality of stacked modules, therefore it is necessary to first divide the plurality of stacked modules to form independent stacked module of first memory chip 120, and then the plurality of independent stacked modules of the first memory chip 120 may be stacked over the substrate 3110 through a thermal compression bonding process.

In one embodiment, nesting the second conductive bump and the first pad on the adjacent two first memory chips through the thermal compression bonding process may include following. First, a photoresist layer may be coated on the first pad 3127. The first pad 3127 may be patterned by photolithography and etching processes, to form a protrusion 3127a in a central region of the first pad 3127. The size of the protrusion 3127a may be in a range approximately between 3 μm-5 μm, and the height of the protrusion 3127a may be less than 5 μm. In one embodiment, the protrusion 3127a may have a square prism shape.

Next, the protrusion may be pressed into the second conductive bump through a thermal compression bonding process. In one embodiment, as shown in FIG. 42, the protrusion 3127a may be formed on the first pad 3127, and the protrusion 3127a may be pressed into the second conductive bump 3125 on the adjacent two first memory chips 120 through a thermal compression bonding process.

In one embodiment, the melting point of the first conductive bump 3124 may be greater than the melting point of the second conductive bump 3125, and a temperature of the thermal compression bonding process may be lower than the melting point of the second conductive bump 3125.

In one embodiment, the temperature of the thermal compression bonding process may be lower than the melting point of the second conductive bump 3125. In one embodiment, because the second conductive bump includes a tin bump, the temperature may often be set in a range approximately between 180° C.-210° C., and such temperature may ensure low modulus of the tin bump, and the protrusion 3127a may be embedded in the tin bump. Therefore, the adjacent two first memory chips 120 may be fixed, and the shape of the tin bump may be basically kept unchanged.

It should be noted that in one embodiment, a second pad 3112 may be disposed on the surface of the substrate 3110 facing towards the first memory chip 120, and the second pad 3112 may be nested with the second conductive bump 3127 on the first memory chip 120 close to the substrate 3110. In one embodiment, the second pad 3112 and the first pad 3127 may have a same structure. Similarly, the second pad may be provided with a protrusion, and the protrusion may be nested with the second conductive bump 3127. The substrate 3110 and the first memory chip 120 may be connected by nesting the second pad 3112 and the second conductive bump 3127. The nested connection between the pad and the second conductive bump may reduce the deformation of the second conductive bump 3127, may reduce the spacing between adjacent second conductive bumps 3127, in other words, the spacing between the substrate 3110 and the first memory chip 120 may be reduced, such that the connection with the center-to-center distance of less than 20 μm may be realized.

S450: performing a reflow soldering process on the plurality of stacked first memory chips and the substrate.

In one embodiment, performing the reflow soldering process on the plurality of stacked first memory chips and the substrate may include: in an acidic gas environment, performing the reflow soldering process on the plurality of stacked first memory chips and the substrate.

In one embodiment, the plurality of stacked first memory chips 120 and the substrate 3110 may be put into an acid reflow furnace to perform the reflow soldering process. The oxide of the second conductive bump 3125 may be fully removed without melting in an acidic gas environment, in other words, the oxide of the tin bump may be removed. Because the second conductive bump 3125 and the first pad 3127 have been soldered, during the reflow soldering process in the acid reflow oven, the second conductive bump 3125, i.e., the tin bump, may have a substantially small deformation and may not be shorten. During the whole reflow soldering process, the second conductive bump 3125 may basically keep the columnar shape unchanged under the action of the upper and lower surface tension, such that the spacing between the tin bumps may be reduced, and the connection with the center-to-center distance of less than 20 μm may be realized.

It should be noted that the acid gas may include carbon dioxide, chlorine, hydrogen sulfide, hydrogen chloride, sulfur dioxide, etc., which may not be specifically limited by the present disclosure.

S460: forming a plastic encapsulation layer to wrap the plurality of first memory chips and the substrate.

In one embodiment, as shown in FIG. 51, the plurality of first memory chips 120 and the substrate 3110 may be plastic-sealed with a plastic sealing compound to form a plastic encapsulation layer 3140. Therefore, the package body of the memory chip may be obtained, and the package body may be cut to form a high-bandwidth memory package body. The plastic encapsulation method may include vacuum lamination of film layers or traditional plastic encapsulation process, which may not be specifically limited by the present disclosure.

In one embodiment, when forming the plastic encapsulation layer 3140, the plastic sealing compound may be filled between adjacent first memory chips 120 and between the first memory chip 120 and the substrate 3110. The plastic sealing compound may wrap the first pads 3127, the second pads 3115, the plurality of first conductive bumps 3124 and the plurality of second conductive bumps 3125. By using the plastic sealing compound instead of the existing non-conductive glue to fill between the substrate and the first memory chip, and between the upper and lower adjacent first memory chips, the short circuit between the pad and the second conductive bump may be prevented. Because the price of the plastic sealing compound is lower than the price of the non-conductive glue, the present disclosure may have the advantages of low production cost.

In one embodiment, referring to FIG. 52, after forming the plastic encapsulation layer 3140, a plurality of solder balls 3150 may be formed on the surface of the substrate 3110 away from the first memory chip 120, and the solder ball 3150 may be electrically connected with the first conductive via 3111. The packaging structure 100 may be connected to the outside world through the plurality of solder balls 3150. After forming the solder balls 3150, a cutting process may be performed to form the final independent packaging structure of the multi-layer stacked high-bandwidth memory.

In the packaging method of the multi-layer stacked high-bandwidth memory of the present disclosure, through the thermal compression bonding process, the second conductive bump and the first pad on the adjacent two first memory chips may be nested, to insulate and sequentially stack the first memory chips over the substrate. Through the reflow soldering process, the plurality of stacked first memory chips and the substrate may be soldered. In the present disclosure, through the two-step welding process, the second conductive bump and the first pad may be nested, which may reduce the deformation of the second conductive bump, may reduce the spacing between adjacent second conductive bumps, and may reduce the distance between adjacent first memory chips, such that the connection with the center-to-center distance of less than 20 μm may be realized.

### Embodiment 5

For enterprise-level applications such as data centers, large-capacity high-speed storage becomes a necessity. In response to such demand, high-bandwidth memory (HBM) came into being. As shown in FIG. 1, the existing HBM uses through-silicon vias 12 to vertically interconnect a plurality of memory chips 11, and exchanges data with external through a buffer chip 10 at the bottom layer. Because the through-silicon vias have advantages of high density and short vertical-interconnection distance, data transfer speed is greatly improved.

At present, the multi-layer chips of the HBM are stacked by a thermal compression bond (TCB) process. Through rapid heating, a micro-bump 14 is connected to a pad 13 on the back of the chip, and the pad on the back of the chip is connected to the through-silicon via 12 of the chip. The micro-bump is mainly made of a copper-tin structure, while the pad on the back of the chip is mainly made of a nickel-gold structure. The final stacked structure is protected by a plastic encapsulation layer 15.

In the case of using the copper-tin micro-bump, due to the deformability of tin during reflow, to prevent short circuit between micro-bumps, the spacing between micro-bumps and the height of tin need to be strictly controlled. At present, the spacing is greater than 40 μm. When the spacing is reduced to less than 25 μm, due to the too small amount of tin, the tin will be fully converted into intermetallic compound under thermal load conditions, leading to reliability failure.

To increase storage capacity and data throughput speed, the number of stacked layers of the chip and the number of pins need to increase. However, in the current micro-bump structure, due to the limitations of spacing and height of the micro-bump, there is limited room for continuous improvement.

The present disclosure provides a packaging method of a multi-layer stacked high-bandwidth memory. FIG. 54 illustrates a schematic flowchart of the packaging method. Referring to FIG. 54, the packaging method S100 may include following.

S510: forming a plurality of cutting marks at preset positions in the first memory chip.

In one embodiment, as shown in FIG. 55, a plurality of cutting marks 4111 may be formed in preset positions of the first memory chip 4110 by laser stealth cutting. The cutting mark 4111 may include the laser damage layer in the first memory chip 4110. As shown in FIG. 55 and FIG. 56, in one embodiment, the laser stealth dicing may be performed on the surface of the first memory chip 4110 away from the second memory chip 4120. On the one hand, the laser stealth dicing method may avoid the debris generated by cutting with blade; and on the other hand, when stealth dicing is used, the width of the cutting mark may almost be zero, which may reduce the width of the dicing line and further reduce the interval between the first memory chips.

S520: between two adjacent cutting marks, sequentially stacking and arranging a plurality of second memory chips including first conductive vias over the first memory chip by mixed-bonding.

In one embodiment, as shown in FIG. 55 and FIG. 56, between two adjacent cutting marks 4111, a plurality of second memory chips 4120 including the first conductive vias 4121 may be sequentially stacked over the first memory chip 4110 by mixed-bonding.

In one embodiment, as shown in FIG. 56, the second memory chip 4120 may be provided with a plurality of first conductive vias 4121, and the first conductive vias 4121 may be further optimized as through-silicon vias. The vertical electrical interconnection of through-silicon vias may be realized using through-silicon via technology, which may reduce the packaging height.

As shown in FIG. 56, a first passivation layer 4122 and a first metal pad 4123 may be disposed on a surface of the second memory chip 4120 facing towards the first memory chip 4110, and a second passivation layer 4124 and a second metal pad 4125 may be disposed on a surface of the second memory chip 4120 facing away from the first memory chip 4110. A third passivation layer 4112 and a third metal pad 4113 may be disposed on a surface of the first memory chip 4110 facing towards the second memory chip 4120.

It should be noted that in one embodiment, the material of the first passivation layer 4122, the second passivation layer 4124 and the third passivation layer 4112 may include silicon dioxide, and the first metal pad 4123, the second metal pad 4125 and the third metal pad 4113 may include a copper pad. In one embodiment, the first memory chip 4110 and the second memory chip 4120 may include a dynamic random access memory chip, or may include any other memory chip, which may not be limited by the present disclosure.

Sequentially stacking and arranging a plurality of second memory chips including first conductive vias over the first memory chip by mixed-bonding may include following.

First, as shown in FIG. 56, between two adjacent cutting marks 4111, in other words, along both sides of the two adjacent cutting marks 4111, the first passivation layer 4122 of the second memory chip at the bottom layer may be boned with the third passivation layer 4112 of the first memory chip 4110, and then may be baked at a temperature above 200° C. The first metal pad 4123 of the second memory chip at the bottom layer may be bonded with the third metal pad 4113 of the first memory chip 4110. In other words, the first copper pad of the second memory chip 4120 at the bottom layer and the third copper pad of the first memory chip 4110 may be bonded by thermal expansion of copper.

Next, as shown in FIG. 57, the second memory chips 4120 at the remaining layers may be sequentially stacked over the second memory chip 4120 at the bottom layer by mixed bonding. The first passivation layer 4122 and the second passivation layer 4124 on every two adjacent layers of the second memory chips 4120 may be bonded; and the first metal pad 4123 and the second metal pad 4125 on every two adjacent layers of the second memory chips 4120 may be bonded.

In one embodiment, as shown in FIG. 57, on both sides of the plurality of cutting marks 4111, the bottom second memory chip 4120 may be connected with the first memory chip 4110 by mixed-bonding. The second memory chip 4120 at the second layer may be disposed on the second memory chip 4120 at bottom layer, and may be connected with the second memory chip 4120 at bottom layer by mixed-bonding. The second memory chip 4120 at the third layer may be disposed on the second memory chip 4120 at the second layer, and may be connected with the second memory chip 4120 at the second layer by mixed-bonding. Similarly, the second memory chips 4120 at remaining layers may be sequentially stacked over the second memory chip 4120 at the bottom layer.

S530: plastic-encapsulating the first memory chip and the plurality of second memory chips to form a first plastic-encapsulation layer.

In one embodiment, as shown in FIG. 58, the first memory chip 4110 and the plurality of second memory chips 4120 stacked over the first memory chip 4110 may be plastic-encapsulated, to form a first plastic-encapsulation layer 4140. The first plastic encapsulation layer 4140 may wrap the first memory chip 4110 and the plurality of second memory chips 4120 stacked over the first memory chip 4110. Then, the surface of the first plastic encapsulation layer 4140 may be polished to expose the second passivation layer 4124 and the second metal pad 4125 on the surface of the second memory chip 4120 away from the first memory chip 4110. The plastic sealing method may include film vacuum lamination or traditional plastic sealing process, which may not be specifically limited by the present disclosure.

S540: attaching the plastic-encapsulated first memory chip on a patch film, and cutting the first plastic-encapsulation layer at positions corresponding to the plurality of cutting marks to form a plurality of independent second memory chip groups.

In one embodiment, before attaching the plastic-encapsulated first memory chip on the patch film, the method may further include following.

A first bump may be formed on the surfaces of the second memory chip at the top layer and the first plastic encapsulation layer away from the first memory chip, and the first bump may be electrically connected to the second conductive via.

In one embodiment, before forming the first bump, a dielectric layer may be formed on the surfaces of the second memory chip at the top layer and the first plastic encapsulation layer away from the first memory chip.

In one embodiment, as shown in FIG. 59, the dielectric layer 4170 may be coated on the surfaces of the second memory chip at the top layer and the first plastic encapsulation layer 4140 away from the first memory chip 4110. The dielectric layer 4170 may be made of a material including polyimide (PI), polybenzoxazole (PBO), etc. The coating method may often include a wafer spin coating, which may not be limited by the present disclosure.

Next, a rewiring layer may be formed on the dielectric layer. In one embodiment, as shown in FIG. 7, the dielectric layer 4170 may be patterned by a photolithography process to form a plurality of first openings (not shown in the Figure), and the rewiring layer 4180 may be formed by deposition at the plurality of first openings. The deposition method may include sputtering, and electroplating, etc. The rewiring layer 4180 may often be made of a material including titanium and copper, and the deposition method and metal material may not be specifically limited by the present disclosure. The formation of the rewiring layer 4180 on the dielectric layer 4170 may well meet the requirements of high-density interconnection and may improve the production yield.

Thirdly, the first bump may be formed on the rewiring layer, and the first bump may correspond to the second conductive via. In one embodiment, as shown in FIG. 59, the rewiring layer 4180 may be patterned by photolithography, and a plurality of second openings (not shown in the Figure) may be formed on the rewiring layer 4180. A plurality of first bumps 4190 may be formed in the plurality of second openings. The plurality of first bumps 4190 may be electrically connected to the plurality of second conductive vias 4131 on the buffer chip 4130. In one embodiment, the first bump 4190 may include a copper-tin bump.

It should be noted that in one embodiment, the thickness of the first memory chip 4110 may be very thick, therefore after forming the plurality of first bumps 4190, as shown in FIG. 60, a thinning treatment may be performed on the side of the first memory chip 4110 facing away from the second memory chip 4120.

Ultimately, a non-conductive adhesive film may be formed over the first bumps. In one embodiment, as shown in FIG. 61, after thinning the side of the first memory chip 4110 away from the second memory chip 4120, the non-conductive adhesive film 4200 may be formed over the plurality of first bumps 4190. The non-conductive adhesive film 4200 may wrap the plurality of first bumps 4190 to protect the plurality of first bumps 4190.

It should be noted that in step S540, it is optional to sequentially form the dielectric layer 4170 and the rewiring layer 4180 over the surface of the second memory chip at the top layer and the surface of the first plastic encapsulation layer 4140 away from the first memory chip 4110. In another embodiment, a plurality of first bumps 4190 may be directly formed over the surface of the second memory chip at the top layer and the surface of the first plastic encapsulation layer 4140 away from the first memory chip 4110, which may not be specifically limited by the present disclosure.

After completing the above steps, as shown in FIG. 62, the plastic-encapsulated first memory chip 4110 may be attached onto the patch film 4150, and the first plastic-encapsulation layer 4140 may be cut at positions corresponding to the plurality of cutting marks 4111, to form scribe lines 4161. Therefore, the plurality of second memory chips 4120 that are sequentially stacked may form a plurality of independent second memory chip groups 4160. When cutting the first plastic encapsulation layer 4140, the scribe line 4161 may stop when reaching the surface of the first memory chip 4110 facing towards the second memory chip 4120.

S550: cutting the first memory chip along the plurality of cutting marks to form a plurality of independent memory stack modules.

In one embodiment, as shown in FIG. 63, the patch film 4150 may be stretched under a preset low temperature condition, and under the action of the stretching force, a plurality of cutting marks 4111 (i.e., laser damage layer) in the first memory chip 4110 may expand, and may ultimately achieve the separation of the first memory chip 4110, to form a plurality of independent memory stack modules 4210 as shown in FIG. 64. Each independent memory stack module 4210 may include the first memory chip 4110 and a plurality of second memory chips 4120. It should be noted that stretching the patch film may be actually feasible at room temperature or within a certain range lower than normal temperature, as long as the temperature is not too high and does not affect the state strength of the patch film.

S560: performing a thermal compression bonding process on the plurality of memory stack modules and the buffer chip, where the buffer chip may be provided with a plurality of second conductive vias.

In one embodiment, as shown in FIG. 65, the buffer chip 4130 may be provided with a plurality of second conductive vias 4131. The fourth passivation layer 4132 and the fourth metal pad 4133 may be disposed on the surface of the buffer chip 4130 facing towards the memory stack module 4210. The thermal compression bonding process may be performed on the plurality of memory stack modules 4210 and the buffer chip 4130. In one embodiment, the first bumps 4190 may be thermo-compressively bonded to the fourth metal pads 4133. In other words, the plurality of memory stack modules 4210 may be pasted on the buffer chip 4130 through a thermal compression bonding process. The plurality of first bumps 4190 may be electrically connected to the plurality of second conductive vias 4131 through the plurality of fourth pads 4133 on the buffer chip 4130, to implement signal transmission between the memory stack module 4210 and the buffer chip 4130.

It should be noted that when performing the thermal compression bonding process on the memory stack modules 4210 and the fourth metal pad 4132, a pre-soldering process may be performed to stack the memory stack modules 4210 on the relative positions of the buffer chip 4130 in advance, to facilitate subsequent packaging process. Solder may be coated on the first bumps 4190 or the fourth pads 4133, and the memory stack modules 4210 may be stacked on the relative positions of the buffer chip 4130 in advance by thermocompression of the thermocompression bonding process. The pre-soldering may also be performed by melting the solder on the first bump 4190 and the fourth pad 4132 with a soldering pen, to perform the pre-soldering process and fix the memory stack modules 4210 on the relative positions of the buffer chip 4130 in advance. The pre-soldering process may include but may not be limited to the above-disclosed methods, and the pre-soldering method that is capable of pre-fixing the memory stack modules 4210 on the relative positions of the buffer chip 4130 through a simple and fast soldering operation may be adopted, which may not be limited by the present disclosure.

It should be further explained that the solder may include copper-zinc alloy material, silver-copper alloy material, tin-lead alloy material, etc., which may be melted in a protective gas atmosphere at a preset temperature, and may be convenient for the first bump 4190 or the fourth pad 4133 to dip, which may not be limited by the present disclosure.

It should be noted that in one embodiment, the position of the fourth pad 4133 may correspond to the position of the first bump 4190, and the quantity of the fourth pads 4133 may be the same as the quantity of the first bumps 4190. If the buffer chip 4130 is not adapted to the second memory chip 4120 and the first memory chip 4110, and the buffer chip in the chip package preparation process may be a general-purpose buffer chip, the quantity of the fourth pads 4133 on the buffer chip 4130 may be greater than the quantity of the first bumps 4190 on the second memory chip 4120, as long as it may be ensured that the first bumps 4190 on the second memory chip 4120 may match and be connected with corresponding fourth pads 4133, the information transmission channels between the second memory chip 4120 and the buffer chip 4130 may be sufficient. The quantity of first bumps 4190 may be determined according to the quantity of information transmission channels between the second memory chip 4120 and the buffer chip 4130, to ensure that there may be sufficient information transmission channels between the second memory chip 4120 and the buffer chip 4130, and to ensure the working efficiency of the second memory chip 4120. In one embodiment, the fourth metal pad 4133 may be made of a material including metal copper, and the first bump 4190 may be made of a material including copper-tin material, which may not be specifically limited by the present disclosure.

It should be noted that the thermal compression bonding process may be performed on the plurality of memory stack modules and the substrate. In other words, the plurality of memory stack modules may be stacked over the substrate.

S570: plastic-encapsulating the buffer chip and the memory stack modules to form a second plastic-encapsulation layer.

In one embodiment, as shown in FIG. 65, the buffer chip 4130 and the memory stack modules 4210 may be plastic-encapsulated to form the second plastic-encapsulation layer 4220. The second plastic-encapsulation layer 4220 may wrap the buffer chip 4130 and the memory stack modules 4210. The plastic encapsulation method may include film vacuum lamination or traditional plastic sealing process, which may not be specifically limited by the present disclosure.

S580: cutting the second plastic encapsulation layer and the buffer chip to form a plurality of independent memory packaging structures.

In one embodiment, before cutting the second plastic encapsulation layer and the buffer chip, the method may further include following.

As shown in FIG. 66, the second bumps 4134 may be formed on the surface of the buffer chip 4130 away from the memory stack module 4210. The second bumps 4134 may correspond to the second conductive vias 4131. In one embodiment, the second bump 4134 may include a copper-tin bump.

After forming the second bump 4134, the second plastic encapsulation layer 4220 and the buffer chip 4130 may be cut to form a plurality of independent memory packaging structures as shown in FIG. 67.

The present disclosure also provides a packaging structure of a multi-layer stacked high-bandwidth memory. As shown in FIG. 67, the packaging structure 100 may be packaged by the above-disclosed packaging method S100. The packaging structure 100 may include a buffer chip 4130, a first memory chip 4110, a plurality of second memory chips 4120, a first plastic encapsulation layer 4140 and a second plastic encapsulation layer 4220.

A plurality of second memory chips 4120 may be sequentially stacked over the buffer chip 4130. Every adjacent two layers of second memory chips 4120 may be connected by mixed-bonding, and the buffer chip 4130 may be bonded to the second memory chip at the bottom layer by a thermal compression bonding process.

The first memory chip 4110 may be disposed on a side of the plurality of second memory chips 4120 facing away from the buffer chip 4130. The first memory chip 4110 may be connected to the second memory chip at the top layer by mixed-bonding.

The first plastic encapsulation layer 4140 may be disposed on the first memory chip 4110, and may be sheathed on the outside of the plurality of second memory chips 4120. In other words, the first plastic encapsulation layer 4140 may merely enclose the both sides of the plurality of stacked second memory chips 4120. The second plastic encapsulation layer 4220 may be disposed over the buffer chip 4130 and may be sheathed on the outside of the first plastic encapsulation layer 4140 and the first memory chip 4110. The second memory chip 4120 may be provided with the first conductive vias 4121, and the buffer chip 4130 may be provided with the second conductive vias 4131 corresponding to and electrically connected to the first conductive vias 4121.

In one embodiment, as shown in FIG. 67, a first passivation layer 4122 and a first metal pad 4123 may be disposed on a surface of the second memory chip 4120 facing towards the first memory chip 4110, and a second passivation layer 4124 and a second metal pad 4125 may be disposed on a surface of the second memory chip 4120 facing away from the first memory chip 4110. A third passivation layer 4112 and a third metal pad 4113 may be disposed on a surface of the first memory chip 4110 facing towards the second memory chip 4120.

It should be noted that in one embodiment, the material of the first passivation layer 4122, the second passivation layer 4124 and the third passivation layer 4112 may include silicon dioxide, and the first metal pad 4123, the second metal pad 4125 and the third metal pad 4113 may include a copper pad.

The first passivation layer 4122 of one of the second memory chips 4120 in every adjacent two layers may be bonded to the second passivation layer 4124 of the other one of the second memory chips 4120 in every adjacent two layers, and the first metal pad 4123 of one of the second memory chips 4120 in every two adjacent layers may be bonded to the second metal pad 4125 of the other one of the second memory chips 4120 in every adjacent two layers.

The third passivation layer 4112 of the first memory chip 4110 may be bonded to the first passivation layer 4122 of the second memory chip 4120, and the third metal pad 4113 of the first memory chip 4110 may be bonded to the first metal pad 4123 of the second memory chip 4120.

In one embodiment, as shown in FIG. 67, the fourth passivation layer 4132 and the fourth metal pad 4133 may be disposed on the surface of the buffer chip 4130 facing towards the second memory chip 4120. The first bumps 4190 and the non-conductive adhesive film 4200 may be formed over the second passivation layer 4124 of the second memory chip 4120 facing towards the buffer chip 4130. In one embodiment, the dielectric layer 4170 may be disposed on the second passivation layer 4124 of the second memory chip 4120 facing towards the buffer chip 4130. A rewiring layer 4180 may be disposed on the dielectric layer 4170, and the rewiring layer 4180 may be provided with the first bumps 4190 and the non-conductive adhesive film 4200. In other words, the dielectric layer 4170 and the rewiring layer 4180 disposed on the second passivation layer 4124 of the second memory chip 4120 facing towards the buffer chip 4130 may be optional, which may not be specifically limited by the present disclosure. The fourth metal pad 4133 may be connected to the first bump 4190 of the buffer chip 4130 by thermal compression bonding.

It should be noted that in one embodiment, the dielectric layer 4170 may be made of a material including polyimide (PI), polybenzoxazole (PBO), etc. The fourth passivation layer 4132 may be made of a material including silicon dioxide, and the fourth metal pad 4133 may include a copper pad. The rewiring layer 4180 may often be made of a material including titanium and copper. The first bump 190 may include a copper-tin bump.

In one embodiment, as shown in FIG. 15, the second bumps 4134 may be disposed on the surface of the buffer chip 4130 away from the second memory chip 4120. The second bump 4134 may correspond to and be electrically connected to the second conductive vias 4131. In one embodiment, the second bump 4134 may include a copper-tin bump.

In the disclosed high-bandwidth memory packaging structure of the present disclosure, a plurality of second memory chips may be sequentially stacked and arranged over the buffer chip.

Every two adjacent layers of second memory chips may be connected by mixed-bonding, and the buffer chip may be connected to the bottom second memory chip by thermal compression bonding. The first memory chip may be disposed on a side of the plurality of second memory chips away from the buffer chip, and the first memory chip may be connected to the second memory chip at the top layer by mixed-bonding. The second memory chip may be provided with a plurality of first conductive vias, and the buffer chip may be provided with a plurality of second conductive vias corresponding to and electrically connected to the plurality of first conductive vias. The packaging structure of the present disclosure may achieve a substantially small spacing (below 10 μm), may increase the number of vertical interconnections, and may increase the number of data channels to improve data throughput. At the same time, because the two memory chips are connected by mixed-bonding, and the first memory chip is connected to the second memory chip by mixed-bonding, the bonding height may be reduced, and the number of memory chip layers may increase, thereby increasing the capacity of the packaging structure.

### Embodiment 6

With the development of cloud computing and mobile interconnection, the demand for servers such as data centers has surged. High-end servers require high capacity, large bandwidth and low power consumption for storage devices. In response to such demand, companies have successively launched multi-layer stacked memory packaging products based on three-dimensional stacking technology. As shown in FIG. 68, the packaging stacked structure of the multi-layer stacked memory uses through-silicon vias 2 to vertically interconnect a plurality of memory chips 1. The plurality of memory chips 1 are soldered together through bumps 3, and the memory chips 1 are stacked over a substrate 4. A non-conductive glue 5 is disposed between the chips, the entire memory chip structure is protected by a plastic encapsulation layer 6, and the ultimately packaged structure is connected to external by solder balls 7. Because the through-silicon vias 2 have advantages of high density and short vertical-interconnection distance, data transfer speed is greatly improved.

At present, the multi-layer chips of the multi-layer stacked memory are stacked by a thermal compression bond (TCB) process. Through rapid heating, a bump 3 is connected to a pad 8 on the back of the chip, and the pad on the back of the chip is connected to the through-silicon via 2 of the chip. The bump is mainly made of a copper-tin structure, while the pad on the back of the chip is mainly made of a nickel-gold structure. The final stacked structure is protected by a plastic encapsulation layer 6.

In the case of using the copper-tin bump, due to the deformability of tin during reflow, to prevent short circuit between bumps, the spacing between bumps and the height of tin need to be strictly controlled. At present, the spacing is greater than 40 μm. When the spacing is reduced to less than 25 μm, due to the too small amount of tin, the tin will be fully converted into intermetallic compound under thermal load conditions, leading to reliability failure.

To increase storage capacity and data throughput speed, the number of stacked layers of the chip and the number of pins need to increase. However, in the current micro-bump structure, due to the limitations of spacing and height of the bump, there is limited room for continuous improvement.

The present disclosure also provides a packaging structure of a multi-layer stacked high-bandwidth memory. As shown in FIG. 69, the packaging structure 100 may include a first memory chip 5110, a plurality of second memory chips 5120, a substrate 5130, and a plastic encapsulation layer. In one embodiment, the first memory chip 5110 and the second memory chip 5120 may include a dynamic random access memory chip, or may include any other memory chip, which may not be limited by the present disclosure.

The second memory chip 5120 may be provided with a plurality of first conductive vias 5121. The substrate 5130 may be provided with a plurality of second conductive vias 5131 electrically connected to the plurality of first conductive vias 5121. In one embodiment, the size of the cross-section of the second conductive via 5131 may be greater than the size of the cross-section of the first conductive via 5121. Both the first conductive via 5121 and the second conductive via 5131 may use through-silicon via. Because the through-silicon vias have advantages of high density and short vertical-interconnection distance, data transfer speed may be greatly improved.

The plurality of second memory chips 5120 may be sequentially stacked over the substrate 5130. Every adjacent two layers of second memory chips 5120 may be connected by mixed-bonding, and the substrate 5130 may be bonded to the second memory chip by a thermal compression bonding process.

The first memory chip 5110 may be disposed on a side of the plurality of second memory chips 5120 facing away from the substrate 5130. The first memory chip 5110 may be connected to the second memory chip 5120 by mixed-bonding.

The plastic encapsulation layer may warp the first memory chip 5110, the plurality of second memory chips 5120, and the substrate 5130. The plastic encapsulation layer may include a first plastic encapsulation layer 5140 and a second plastic encapsulation layer 5220. The first plastic encapsulation layer 5140 may be disposed on the first memory chip 5110, and may be sheathed on the outside of the plurality of second memory chips 5120. In other words, the first plastic encapsulation layer 5140 may merely enclose the both sides of the plurality of stacked second memory chips 5120. The second plastic encapsulation layer 5220 may be disposed over the substrate 5130, and may be sheathed on the outside of the first plastic encapsulation layer 5140 and the first memory chip 5110. It should be noted that both the first plastic encapsulation layer 5140 and the second plastic encapsulation layer 5220 may be made of epoxy resin, which may protect the packaging structure 100.

The disclosed packaging structure of the multi-layer stacked high-bandwidth memory may achieve ultra-fine-pitch interconnection, may increase the number of vertical interconnections, and may increase the number of data channels to improve data throughput. At the same time, because the connection between the plurality of second memory chips and between the first memory chip and the second memory chip are achieved by mixed-bonding, and the connection between the first memory chip and the second memory chip is achieved by mixed-bonding, the bonding height may be reduced, and the number of memory chip layers may increase, thereby increasing the capacity of the packaging structure.

In one embodiment, as shown in FIG. 69, a first passivation layer 5122 and a first metal pad 5123 may be disposed on a surface of the second memory chip 5120 facing towards the first memory chip 5110, and a second passivation layer 5124 and a second metal pad 5125 may be disposed on a surface of the second memory chip 5120 facing away from the first memory chip 5110. The first passivation layer 5122 of one of the second memory chips 5120 in every adjacent two layers may be bonded to the second passivation layer 5124 of the other one of the second memory chips 5120 in every adjacent two layers, and the first metal pad 5123 of one of the second memory chips 5120 in every two adjacent layers may be bonded to the second metal pad 5125 of the other one of the second memory chips 5120 in every adjacent two layers. The plurality of second memory chips 5120 may be connected by mixed-bonding, which may reduce the bonding height of the packaging structure, may increase the number of chip layers, and may increase the capacity of the packaging structure.

It should be noted that in one embodiment, the material of the first passivation layer 5122 and the second passivation layer 5124 may include silicon dioxide, and the material of the first metal pad 5123 and the second metal pad 5125 may include a metal copper. The materials of the first passivation layer 5122, the second passivation layer 5124, the first metal pad 5123 and the second metal pad 5125 may not be limited by the present disclosure, and may be determined according to practical applications.

In one embodiment, as shown in FIG. 69, a third passivation layer 5112 and a third metal pad 5113 may be disposed on a surface of the first memory chip 5110 facing towards the second memory chip 5120. The first passivation layer 5122 and the first metal pad 5123 may be disposed on the surface of the second memory chip 5120 facing towards the first memory chip 5110. The third passivation layer 5112 of the first memory chip 5110 may be bonded to the first passivation layer 5122 of the second memory chip 5120, and the third metal pad 5113 of the first memory chip 5110 may be bonded to the first metal pad 5123 of the second memory chip 5120. The first memory chip 5110 may be connected to the second memory chip 5120 by mixed-bonding, which may achieve a substantially small spacing (below 10 μm), may increase the number of vertical interconnections, and may increase the number of data channels to improve data throughput.

It should be noted that the material of the third passivation layer 5112 may include silicon dioxide, and the material of the third metal pad 5113 may include a metal copper, which may not be limited by the present disclosure, and may be determined according to practical applications.

In one embodiment, as shown in FIG. 69, the fourth metal pad 5132 may be disposed on the surface of the substrate 5130 facing towards the second memory chip 5120. The first bumps 5190 may be disposed on a side of the second memory chip 5120 close to the substrate 5130 and facing towards the substrate 5130. In other words, the first bumps may merely be disposed on the side of the second memory chip 5120 close to the substrate 5130 and facing towards the substrate 5130, and may not be disposed on the other second memory chips 5120. In one embodiment, the first bump 5190 may be connected to the fourth metal pad 5132 through a thermal compression bonding.

It should be noted that in one embodiment, the position of the fourth metal pad 5132 may correspond to the position of the first bump 5190, and the quantity of the fourth metal pads 5132 may be the same as the first bumps 5190. If the substrate 5130 is not adapted to the second memory chip 5120 and the first memory chip 5110, and the substrate in the chip package preparation process may be a general-purpose substrate, the quantity of the fourth metal pads 5132 on the substrate 5130 may be greater than the quantity of the first bumps 5190 on the second memory chip 5120, as long as it may be ensured that the first bumps 5190 on the second memory chip 5120 may match and be connected with corresponding fourth metal pads 5132, the information transmission channels between the second memory chip 5120 and the substrate 5130 may be sufficient. The quantity of first bumps 5190 may be determined according to the quantity of information transmission channels between the second memory chip 5120 and the substrate 5130, to ensure that there may be sufficient information transmission channels between the second memory chip 5120 and the substrate 5130, and to ensure the working efficiency of the second memory chip 5120. In one embodiment, the fourth metal pad 5132 may be made of a material including metal copper, and the first bump 5190 may be made of a material including copper-tin material, which may not be specifically limited by the present disclosure.

In one embodiment, the packaging structure may further include a dielectric layer 5170 and a rewiring layer 5180. The dielectric layer 5170 and the rewiring layer 5180 may be sequentially disposed over the second passivation layer 5124 of the second memory chip 5120 close to the substrate 5130. The rewiring layer 5180 may be electrically connected to the first bump 5190. It should be noted that in one embodiment, the dielectric layer 5170 may be made of a material including polyimide (PI), polybenzoxazole (PBO), etc. The rewiring layer 5180 may often be made of a material including titanium and copper. The dielectric layer 5170 and the rewiring layer 5180 sequentially disposed over the second passivation layer 5124 of the second memory chip 5120 close to the substrate 5130 may well meet the requirements of high-density interconnection and may improve the production yield.

In one embodiment, referring to FIG. 69, the packaging structure may further include a plurality of solder balls 5133. The plurality of solder balls 5133 may be formed on the surface of the substrate 5130 away from the second memory chip 5120. The solder balls 5133 may one-to-one correspond to and may be electrically connected to the second conductive vias 5131, and the packaging structure may be connected to the outside world through the plurality of solder balls 5133.

The present disclosure also provides a packaging method of a multi-layer stacked high-bandwidth memory. FIG. 70 illustrates a schematic flowchart of the packaging method. Referring to FIG. 70, the packaging method S100 may include following.

S610: forming a plurality of cutting marks at preset positions in the first memory chip.

In one embodiment, as shown in FIG. 71, a plurality of cutting marks 5111 may be formed in preset positions of the first memory chip 5110 by laser stealth cutting. The cutting mark 5111 may include the laser damage layer in the first memory chip 5110. As shown in FIG. 71 and FIG. 72, in one embodiment, the laser stealth dicing may be performed on the surface of the first memory chip 5110 away from the second memory chip 5120. On the one hand, the laser stealth dicing method may avoid the debris generated by cutting with blade; and on the other hand, when stealth dicing is used, the width of the cutting mark may almost be zero, which may reduce the width of the dicing line and further reduce the interval between the first memory chips.

S620: between two adjacent cutting marks, sequentially stacking and arranging the plurality of second memory chips including first conductive vias over the first memory chip by mixed-bonding.

In one embodiment, as shown in FIG. 71 and FIG. 72, between two adjacent cutting marks 5111, a plurality of second memory chips 5120 including the first conductive vias 5121 may be sequentially stacked over the first memory chip 5110 by mixed-bonding.

In one embodiment, as shown in FIG. 72, the second memory chip 5120 may be provided with a plurality of first conductive vias 5121, and the first conductive vias 5121 may be further optimized as through-silicon vias. The vertical electrical interconnection of through-silicon vias may be realized using through-silicon via technology, which may reduce the packaging height.

As shown in FIG. 72, the first passivation layer 5122 and the first metal pad 5123 may be disposed on a surface of the second memory chip 5120 facing towards the first memory chip 5110. The second passivation layer 5124 and the second metal pad 5125 may be disposed on a surface of the second memory chip 5120 facing away from the first memory chip 5110. The third passivation layer 5112 and the third metal pad 5113 may be disposed on a surface of the first memory chip 5110 facing towards the second memory chip 5120.

It should be noted that in one embodiment, the material of the first passivation layer 5122, the second passivation layer 5124 and the third passivation layer 5112 may include silicon dioxide, and the material of the first metal pad 5123, the second metal pad 5125 and the third metal pad 5113 may include metal copper.

Sequentially stacking and arranging the plurality of second memory chips including the first conductive vias over the first memory chip by mixed-bonding may include following.

First, as shown in FIG. 72, between two adjacent cutting marks 5111, in other words, along both sides of the two adjacent cutting marks 5111, the first passivation layer 5122 of the second memory chip at the bottom layer may be boned with the third passivation layer 5112 of the first memory chip 5110, and then may be baked at a temperature above 200° C. The first metal pad 5123 of the second memory chip at the bottom layer may be bonded with the third metal pad 5113 of the first memory chip 5110. In other words, the first copper pad of the second memory chip 5120 at the bottom layer and the third copper pad of the first memory chip 5110 may be bonded by thermal expansion of copper.

Next, as shown in FIG. 73, the second memory chips 5120 at the remaining layers may be sequentially stacked over the second memory chip 5120 at the bottom layer by mixed bonding. The first passivation layer 5122 and the second passivation layer 5124 on every two adjacent layers of the second memory chips 5120 may be bonded; and the first metal pad 5123 and the second metal pad 5125 on every two adjacent layers of the second memory chips 5120 may be bonded.

In one embodiment, as shown in FIG. 73, on both sides of the plurality of cutting marks 5111, the bottom second memory chip 5120 may be connected with the first memory chip 5110 by mixed-bonding. The second memory chip 5120 at the second layer may be disposed on the second memory chip 5120 at bottom layer, and may be connected with the second memory chip 5120 at bottom layer by mixed-bonding. The second memory chip 5120 at the third layer may be disposed on the second memory chip 5120 at the second layer, and may be connected with the second memory chip 5120 at the second layer by mixed-bonding. Similarly, the second memory chips 5120 at remaining layers may be sequentially stacked over the second memory chip 5120 at the bottom layer.

S630: plastic-encapsulating the first memory chip and the plurality of second memory chips to form a first plastic-encapsulation layer.

In one embodiment, as shown in FIG. 74, the first memory chip 5110 and the plurality of second memory chips 5120 stacked over the first memory chip 5110 may be plastic-encapsulated, to form a first plastic-encapsulation layer 5140. The first plastic encapsulation layer 5140 may wrap the first memory chip 5110 and the plurality of second memory chips 5120 stacked over the first memory chip 5110. Then, the surface of the first plastic encapsulation layer 5140 may be polished to expose the second passivation layer 5124 and the second metal pad 5125 on the surface of the second memory chip 5120 away from the first memory chip 5110. The plastic sealing method may include film vacuum lamination or traditional plastic sealing process, which may not be specifically limited by the present disclosure.

S640: attaching the plastic-encapsulated first memory chip on a patch film, and cutting the first plastic-encapsulation layer at positions corresponding to the plurality of cutting marks to form a plurality of independent second memory chip groups.

In one embodiment, before attaching the plastic-encapsulated first memory chip on the patch film, the method may further include following.

First bumps may be formed on the surfaces of the second memory chip at the top layer and the first plastic encapsulation layer away from the first memory chip, and the first bump may be electrically connected to the second conductive via.

In one embodiment, before forming the first bump, a dielectric layer may be formed on the surfaces of the second memory chip at the top layer and the first plastic encapsulation layer away from the first memory chip.

In one embodiment, as shown in FIG. 75, the dielectric layer 5170 may be coated on the surfaces of the second memory chip at the top layer and the first plastic encapsulation layer 5140 away from the first memory chip 5110. The dielectric layer 5170 may be made of a material including polyimide (PI), polybenzoxazole (PBO), etc. The coating method may often include a wafer spin coating, which may not be limited by the present disclosure.

Next, a rewiring layer may be formed on the dielectric layer. In one embodiment, as shown in FIG. 75, the dielectric layer 5170 may be patterned by a photolithography process to form a plurality of first openings (not shown in the Figure), and the rewiring layer 5180 may be formed by deposition at the plurality of first openings. The deposition method may include sputtering, and electroplating, etc. The rewiring layer 5180 may often be made of a material including titanium and copper, and the deposition method and metal material may not be specifically limited by the present disclosure. The formation of the rewiring layer 5180 on the dielectric layer 5170 may well meet the requirements of high-density interconnection and may improve the production yield.

Thirdly, the first bumps may be formed on the rewiring layer. In one embodiment, as shown in FIG. 75, the rewiring layer 5180 may be patterned by photolithography, and a plurality of second openings (not shown in the Figure) may be formed on the rewiring layer 5180. A plurality of first bumps 5190 may be formed in the plurality of second openings. The plurality of first bumps 5190 may be electrically connected to the plurality of second conductive vias 5131 on the substrate 5130.

It should be noted that in one embodiment, the thickness of the first memory chip 5110 may be very thick, therefore after forming the plurality of first bumps 5190, as shown in FIG. 76, a thinning treatment may be performed on the side of the first memory chip 5110 facing away from the second memory chip 5120.

Ultimately, a non-conductive adhesive film may be formed over the first bumps. In one embodiment, as shown in FIG. 77, after thinning the side of the first memory chip 5110 away from the second memory chip 5120, the non-conductive adhesive film 5200 may be formed over the plurality of first bumps 5190. The non-conductive adhesive film 5200 may wrap the plurality of first bumps 5190 to protect the plurality of first bumps 5190. The non-conductive adhesive film 5200 may use any other underfill adhesives, which may be selected according to practical applications, and may not be specifically limited by the present disclosure.

It should be noted that in step S640, it is optional to sequentially form the dielectric layer 5170 and the rewiring layer 5180 over the surface of the second memory chip at the top layer and the surface of the first plastic encapsulation layer 5140 away from the first memory chip 5110. In another embodiment, a plurality of first bumps 5190 may be directly formed over the surface of the second memory chip at the top layer and the surface of the first plastic encapsulation layer 5140 away from the first memory chip 5110, which may not be specifically limited by the present disclosure.

After completing the above steps, as shown in FIG. 78, the plastic-encapsulated first memory chip 5110 may be attached onto the patch film 5150, and the first plastic-encapsulation layer 5140 may be cut at positions corresponding to the plurality of cutting marks 5111, to form scribe lines 5161. Therefore, the plurality of second memory chips 5120 that are sequentially stacked may form a plurality of independent second memory chip groups 5160. When cutting the first plastic encapsulation layer 5140, the scribe line 5161 may stop when reaching the surface of the first memory chip 5110 facing towards the second memory chip 5120.

S650: cutting the first memory chip along the plurality of cutting marks to form a plurality of independent memory stack modules.

In one embodiment, as shown in FIG. 79, the patch film 5150 may be stretched under a preset low temperature condition, and under the action of the stretching force, a plurality of cutting marks 5111 (i.e., laser damage layer) in the first memory chip 5110 may expand, and may ultimately achieve the separation of the first memory chip 5110, to form a plurality of independent memory stack modules 5210 as shown in FIG. 80. Each independent memory stack module 5210 may include the first memory chip 5110 and a plurality of second memory chips 5120.

S660: performing a thermal compression bonding process on the plurality of memory stack modules and the substrate, where the substrate may be provided with a plurality of second conductive vias.

In one embodiment, as shown in FIG. 81, the substrate 5130 may be provided with a plurality of second conductive vias 5131. The fourth metal pad 5132 may be disposed on the surface of the substrate 5130 facing towards the memory stack module 5210. The thermal compression bonding process may be performed on the plurality of memory stack modules 5210 and the substrate 5130. In one embodiment, the first bumps 5190 may be thermo-compressively bonded to the fourth metal pads 5132. In other words, the plurality of memory stack modules 5210 may be pasted on the substrate 5130 through a thermal compression bonding process. The plurality of first bumps 5190 may be electrically connected to the plurality of second conductive vias 5131 through the plurality of fourth metal pads 5132 on the substrate 5130, to implement signal transmission between the memory stack module 5210 and the substrate 5130.

It should be noted that when performing the thermal compression bonding process on the memory stack modules 5210 and the fourth metal pad 5132, a pre-soldering process may be performed to stack the memory stack modules 5210 on the relative positions of the substrate 5130 in advance, to facilitate subsequent packaging process. Solder may be coated on the first bumps 5190 or the fourth metal pads 5132, and the memory stack modules 5210 may be stacked on the relative positions of the substrate 5130 in advance by thermal compression of the thermal compression bonding process. The pre-soldering may also be performed by melting the solder on the first bump 5190 and the fourth metal pad 5132 with a soldering pen, to perform the pre-soldering process and fix the memory stack modules 5210 on the relative positions of the substrate 5130 in advance. The pre-soldering process may include but may not be limited to the above-disclosed methods, and the pre-soldering method that is capable of pre-fixing the memory stack modules 5210 on the relative positions of the substrate 5130 through a simple and fast soldering operation may be adopted, which may not be limited by the present disclosure.

It should be further explained that the solder may include copper-zinc alloy material, silver-copper alloy material, tin-lead alloy material, etc., which may be melted in a protective gas atmosphere at a preset temperature, and may be convenient for the first bump 5190 or the fourth metal pad 5132 to dip, which may not be limited by the present disclosure.

It should be noted that in one embodiment, the position of the fourth metal pad 5132 may correspond to the position of the first bump 5190, and the quantity of the fourth metal pads 5132 may be the same as the quantity of the first bumps 5190. If the substrate 5130 is not adapted to the second memory chip 5120 and the first memory chip 5110, and the substrate in the chip package preparation process may be a general-purpose substrate, the quantity of the fourth metal pads 5132 on the substrate 5130 may be greater than the quantity of the first bumps 5190 on the second memory chip 5120, as long as it may be ensured that the first bumps 5190 on the second memory chip 5120 may match and be connected with corresponding fourth metal pads 5132, the information transmission channels between the second memory chip 5120 and the substrate 5130 may be sufficient. The quantity of first bumps 5190 may be determined according to the quantity of information transmission channels between the second memory chip 5120 and the substrate 5130, to ensure that there may be sufficient information transmission channels between the second memory chip 5120 and the substrate 5130, and to ensure the working efficiency of the second memory chip 5120. In one embodiment, the fourth metal pad 5132 may be made of a material including metal copper, and the first bump 5190 may be made of a material including copper-tin material, which may not be specifically limited by the present disclosure.

S670: plastic-encapsulating the substrate and the memory stack modules to form a second plastic-encapsulation layer.

In one embodiment, as shown in FIG. 81, the substrate 5130 and the memory stack modules 5210 may be plastic-encapsulated to form the second plastic-encapsulation layer 5220. The second plastic-encapsulation layer 5220 may wrap the substrate 5130 and the memory stack modules 5210. The plastic encapsulation method may include film vacuum lamination or traditional plastic sealing process, which may not be specifically limited by the present disclosure.

S680: cutting the second plastic encapsulation layer and the substrate to form a plurality of independent memory packaging structures.

In one embodiment, before cutting the second plastic encapsulation layer and the substrate, the method may further include following.

As shown in FIG. 82, the plurality of solder balls 5133 may be formed on the surface of the substrate 5130 away from the memory stack modules 5210. The solder balls 5133 may correspond to the second conductive vias 5131. In one embodiment, the first bump 5133 may be made of a material including a copper-tin material.

After forming the solder balls 5133, the second plastic-encapsulation layer 5220 and the substrate 5130 may be cut, to form a plurality of independent memory packaging structures as shown in FIG. 83.

In the disclosed packaging method of the multi-layer stacked high-bandwidth memory, the plurality of second memory chips including the first conductive vias may be sequentially stacked over the first memory chip by mixed-bonding. The plurality of memory stack modules may be thermo-compressively bonded to the substrate, which may achieve the ultra-fine-pitch interconnection, may increase the number of vertical interconnections, and may increase the number of data channels to improve data throughput. At the same time, because the connection between the plurality of second memory chips and between the first memory chip and the second memory chip are achieved by mixed-bonding, the bonding height may be reduced, and the number of memory chip layers may increase, thereby increasing the capacity of the packaging structure.

The description of the disclosed embodiments is provided to illustrate the present disclosure to those skilled in the art. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments illustrated herein but is to be accorded the widest scope consistent with the principles and novel features disclosed herein.

What is claimed is:

1. A packaging method of a multi-layer stacked high-bandwidth memory, comprising:
respectively providing a substrate and a plurality of memory chips, wherein both the substrate and a memory chip of the plurality of first memory chips are provided with a plurality of conductive vias;
sequentially forming a plurality of first conductive bumps and a plurality of second conductive bumps at positions corresponding to the plurality of conductive vias of a surface of the memory chip facing towards the substrate;
forming a plurality of pads at positions corresponding to the plurality of conductive vias of a surface of the memory chip facing away from the substrate;
nesting a second conductive bump of the plurality of second conductive bumps and a pad of the plurality of pads on every adjacent two memory chips through a thermal compression bonding process, to insulate and sequentially stack the plurality of memory chips over the substrate;
performing a reflow soldering process on the plurality of stacked memory chips and the substrate; and
forming a plastic encapsulation layer to wrap the plurality of memory chips and the substrate.

2. The packaging method according to claim 1, wherein:
the plurality of memory chips include a plurality of groups of memory chips, wherein each group of the memory chips includes a first memory chip and a second memory chip;
the plurality of first conductive bumps and the plurality of second conductive bumps are formed at positions corresponding to the plurality of conductive vias of a surface of the first memory chip facing towards the substrate; and
the plurality of pads are formed at positions corresponding to the plurality of conductive vias of a surface of the second memory chip facing away from the substrate.

3. The packaging method according to claim 1, wherein nesting the second conductive bump and the pad on every adjacent two memory chips through the thermal compression bonding process includes:
forming a protrusion on the pad; and
pressing the protrusion into the second conductive bump on every adjacent two memory chips through the thermal compression bonding process.

4. The packaging method according to claim 3, wherein:
a melting point of the first conductive bump is greater than a melting point of the second conductive bump, and a temperature of the thermal compression bonding process is smaller than the melting point of the second conductive bump.

5. The packaging method according to claim 1, wherein performing the reflow soldering process on the plurality of stacked memory chips and the substrate includes:
performing the reflow soldering process on the plurality of stacked memory chips and the substrate in an acid gas environment.

6. The packaging method according to claim 1, wherein sequentially forming the plurality of first conductive bumps and the plurality of second conductive bumps at the positions corresponding to the plurality of conductive vias of the surface of the memory chip facing towards the substrate includes:
sequentially forming a first passivation layer and a first dielectric layer over the surface of the memory chip facing towards the substrate;
forming a photoresist layer on the first dielectric layer, and forming a plurality of openings by patterning the photoresist layer, wherein the plurality of openings correspond to the plurality of conductive vias;
sequentially forming the plurality of first conductive bumps and the plurality of second conductive bumps in the plurality of openings; and
removing the photoresist layer.

7. The packaging method according to claim 6, before removing the photoresist layer, further including:
polishing the second conductive bump, to make a surface of the second conductive bump be coplanar with a surface of the photoresist layer.

8. The packaging method according to claim 1, wherein forming the plurality of pads at positions corresponding to the plurality of conductive vias of the surface of the memory chip facing away from the substrate includes:
forming a second passivation layer on the surface of the memory chip facing away from the substrate;
patterning the second passivation layer to form a plurality of second openings, wherein the plurality of second openings correspond to the plurality of conductive vias; and
forming the plurality of pads in the plurality of second openings.

9. The packaging method according to claim 1, wherein forming the plastic encapsulation layer to wrap the plurality of memory chips and the substrate includes:
filling a plastic sealing compound between the plurality of memory chips and between the memory chip and the substrate, wherein the plastic sealing compound wraps the plurality of pads, the plurality of first bumps and the plurality of second bumps.

10. The packaging method according to claim 1, wherein:
a conductive via of the plurality of conductive vias includes a through-silicon via.

11. A packaging structure of a multi-layer stacked high-bandwidth memory, comprising:
a substrate, a plurality of memory chips, and a plastic encapsulation layer, wherein:
the substrate is provided with a plurality of first conductive vias, and a memory chip of the plurality of memory chips is provided with a plurality of second conductive vias electrically connected with the plurality of first conductive vias;
a plurality of first conductive bumps and a plurality of second conductive bumps sequentially disposed at positions corresponding to the plurality of second conductive vias of a surface of the memory chip facing towards the substrate;
a plurality of pads disposed at positions corresponding to the plurality of second conductive vias of a surface of the memory chip facing away from the substrate, wherein a second conductive bump of the plurality of second conductive bumps and a pad of the plurality of pads on every adjacent two memory chips are nested, such that the plurality of memory chips are insulated and sequentially stacked over the substrate; and
a plastic encapsulation layer wrapping the plurality of memory chips and the substrate.

12. The packaging structure according to claim 11, wherein:
a protrusion is formed on a side of the pad facing towards the second conductive bump, and a trench is formed on a side of the second conductive bump facing towards the pad, wherein the protrusion is inserted into the trench.

13. The packaging structure according to claim 12, wherein:
the second conductive bump has a columnar structure.

14. The packaging structure according to claim 11, wherein:
the plastic encapsulation layer is formed by filling a plastic sealing compound between the plurality of memory chips and between the memory chip and the substrate.

15. The packaging structure according to claim 11, wherein:
both a first conductive via of the plurality of conductive vias and a second conductive vias of the plurality of second conductive vias include a through-silicon via.

16. The packaging structure according to claim 11, wherein:
the second conductive bump is made of a material including tin.

17. The packaging structure according to claim 11, wherein:
the plurality of memory chips include a plurality of groups of memory chips, wherein each group of the memory chips includes a first memory chip and a second memory chip;
the plurality of first conductive bumps and the plurality of second conductive bumps are formed at positions corresponding to the plurality of conductive vias of a surface of the first memory chip facing towards the substrate; and
the plurality of pads are formed at positions corresponding to the plurality of conductive vias of a surface of the second memory chip facing away from the substrate.

18. The packaging structure according to claim 11, wherein:
a melting point of the first conductive bump is greater than a melting point of the second conductive bump.

19. The packaging structure according to claim 11, further including:
a plurality of solder balls, wherein the plurality of solder balls are formed on a surface of the substrate facing away from the memory chip, and the solder balls are electrically connected with the plurality of first conductive vias.

20. The packaging structure according to claim 11, further including:
a plurality of second pads disposed on a surface of the substrate facing towards the memory chip, wherein the plurality of second pads are nested with the plurality of second conductive bumps on the memory chip close to the substrate.
